(19) United States
(12) Patent Application Publication
(10) Pub. No.: US 2016/0260481 A1
(43) Pub. Date: Sep. 8, 2016

(54) Semiconductor Device

(71) Applicant: HITACHI, LTD., Tokyo (JP)

(72) Inventors: Seiji MIURA, Tokyo (JP); Kenzo KUROTSUCHI, Tokyo (JP)

(21) Appl. No.: 15/029,415

(22) PCT Filed: Oct. 25, 2013
(86) PCT No.: PCT/JP2013/078925

§ 371 Date: Apr. 14, 2016

(51) Int. Cl. G11C 13/00

(52) U.S. Cl. CPC G11C 13/0069; G11C 13/0004; G11C 13/004; G11C 13/0023; G11C 13/003

(57) ABSTRACT

A semiconductor device includes a non-volatile memory unit including a plurality of chain memory arrays CY, and a control circuit that controls an access to the non-volatile memory unit. The control circuit sets, as a write area, a plurality of chain memory arrays CY arranged in a manner adjacent to each other and sets, as a dummy chain memory array DCY, a chain memory array arranged in an adjacent manner in an outer periphery of the write area. The control circuit does not perform an erasing operation on the dummy chain memory array DCY during batch-erasure of the write area. In the batch-erasure of the write area, the dummy chain memory array DCY functions to reduce an influence of heat disturbance.

### TECHNICAL FIELD

The present invention relates to a semiconductor device and specifically relates to a technology of a semiconductor device including a non-volatile memory device.

### BACKGROUND ART

Recently, a phase-change memory using a chalcogenide material as a recording material has been researched actively as a non-volatile memory device. The phase-change memory is a kind of a resistive random access memory that stores information by using different resistive states of a recording material between electrodes.

In the phase-change memory, information is stored by utilization of a resistance value of a phase change material, such as Ge₂Sb₂Te₅, being different in an amorphous state and a crystalline state. Resistance is high in the amorphous state (high resistive state) and resistance is low in the crystalline state (low resistive state). Thus, reading of information from the phase-change memory is realized by application of a potential difference to both ends of an element, measurement of a current flowing in the element, and determination of the high resistive state/low resistive state of the element.

In the phase-change memory, electric resistance of a phase-change film including a phase-change material is changed into a different state by Joule heat generated by current, whereby data is rewritten.

FIG. 30 is a view illustrating a relationship between a pulse width and a temperature necessary for a phase change of a resistive storage element using a phase change material. In this drawing, a vertical axis indicates a temperature and a horizontal axis indicates time. In a case of writing storage information “0” into this storage element, a reset pulse with which the storage element is heated to a temperature equal to or higher than a melting point Ta of a chalcogenide material by application of a large current and cooled instantly is applied, as illustrated in FIG. 30. In this case, by reducing cooling time t1 (for example, by setting time to about 1 ns), the chalcogenide material becomes an amorphous state with high resistance. On the other hand, in a case of writing storage information “1,” a set pulse is applied for a long period in such a manner that current enough for keeping the storage element in a temperature region that is lower than the melting point Ta and higher than a crystallization temperature Tx (equal to or higher than glass transition point) flows. Accordingly, the chalcogenide material becomes a low resistive polycrystalline state.

When a resistive element structure is made small, current necessary for a change in a state of a phase-change film is decreased in this phase-change memory. Thus, phase-change memory is suitable for downsizing in principle and is researched actively. In PTL 1 and PTL 2, a non-volatile memory having a three-dimensional structure is disclosed.

In PTL 1, a configuration in which memory cells each of which includes a variable resistive element and a transistor connected thereto in parallel are connected in series in a lamination direction is disclosed. Also, in PTL 2, a configuration in which memory cells each of which includes a variable resistive element and a diode connected thereto in series are connected, with a leading line therebetween, in series in a lamination direction is disclosed. In this configuration, for example, by application of a potential difference to a leading line between two memory cells and two leading lines on an outer side of the two memory cells, a batch writing operation is performed with respect to the two memory cells.

Also, in PTL 3, it is disclosed to read data and to verify whether writing is successful when the data is written into a phase-change memory. When the read data is different from the write data, the data is written again. A writing method of repeating this operation until writing is performed successfully is disclosed in PTL 3.

### CITATION LIST

### Patent Literature

PTL 1: WO2011/074545A

PTL 2: Japanese Patent Application Laid-Open No. 2011-142186

PTL 3: Japanese Patent Application Laid-Open No. 2008-084518

### SUMMARY OF INVENTION

### Technical Problem

Before submission of the present application, inventors performed verification of a control method of a non-volatile resistive random access memory. As illustrated in FIG. 30, in a phase-change memory, electric resistance of a phase-change film is changed into a different state by Joule heat generated by current, whereby data is rewritten. A phase change material is melted by application of a large current for a short period and is cooled rapidly by sudden reduction of current, whereby a reset operation, that is, an operation of changing a phase-change film into an amorphous state with high resistance is performed. On the other hand, a setting operation, that is, an operation of changing a phase-change film into a low resistive crystalline state is performed by application of current, which is enough for keeping a phase-change material in a crystallization temperature, for a long period.

This means that the reset operation can be performed at high speed but the setting operation is performed at low speed compared thereto in the phase-change memory. Also, there is a possibility that Joule heat generated in a case of performing a writing operation on a memory cell influences a crystalline state of a memory cell in periphery thereof, a resistance value of the peripheral memory cell varies, and data disappears. Specifically, in a setting operation on a memory cell, that is, an operation of changing a state into the low resistive crystalline state, current enough for keeping a phase change material at a crystallization temperature is applied for a long period. Thus, there may be a large influence on a crystalline state of a memory cell in a periphery.

The present invention has been provided in view of the forgoing. A first purpose of the present invention is to provide a semiconductor device that can increase speed of making a memory cell into a set state in unit time (increase speed of data erasing rate). A second purpose of the present invention is to provide a semiconductor device that can control a decrease in reliability due to heat disturbance in a setting operation, that is, to provide a semiconductor device including a highly reliable non-volatile memory.

The above purposes, the other purposes, and a new characteristic of the present invention will become obvious in a description and attached drawings of the present description.

### Solution to Problem

Representative embodiments of the invention disclosed in the present application are described briefly as follows.

That is, a semiconductor device includes a non-volatile memory unit including a plurality of memory cells, and a control circuit configured to assign a physical address to a logical address input from the outside and to access the non-volatile memory unit according to the assigned physical address. Here, the non-volatile memory unit includes a plurality of first signal lines, a plurality of second signal lines that intersect with the plurality of first signal lines, and a plurality of memory cell groups arranged in intersection points of the plurality of first signal lines and the plurality of second signal lines. Moreover, each of the memory cell groups includes first to Nth (N is integer number equal to or larger than 2) memory cells and memory-cell selection lines that respectively select the first to Nth memory cells. The control circuit divides the plurality of memory cell groups included in the non-volatile memory unit into a first area including a plurality of memory cell groups arranged in a manner adjacent to each other and a second area arranged in a manner adjacent to one side of an outer periphery of the first area. The control circuit simultaneously writes a first logical level into each of the plurality of memory cell groups included in the first area but does not write the first logical level into the memory cell groups included in the second area.

In one embodiment, the first logical level is a set state of a memory cell.

Accordingly, since it is possible to simultaneously perform a setting operation (erasing operation) with respect to adjacent memory cell groups, it becomes possible to improve a throughput of the setting operation, that is, a data erasing rate. Also, in a case of performing a batch setting operation, the second area can function as a heat-shielding area and prevent an influence of heat disturbance on a different memory cell group and disappearance of data in the different memory cell group.

### Advantageous Effects of Invention

An effect acquired by representative embodiments of the invention disclosed in the present application is described briefly as follows.

That is, it is possible to provide a semiconductor device including a highly reliable non-volatile memory.

### BRIEF DESCRIPTION OF DRAWINGS

FIG. 1 is a block diagram illustrating a schematic configuration example of an information processing system to which a semiconductor device of one embodiment of the present invention is applied.

FIG. 2 is a block diagram illustrating a configuration example of a control circuit in FIG. 1.

FIG. 3A is a block diagram illustrating a configuration example of a non-volatile memory device in FIG. 1.

FIG. 3B is a circuit diagram illustrating a configuration example of a chain memory array in FIG. 3A.

FIG. 4 is a view for describing an operation example of the chain memory array in FIG. 3B.

FIG. 5A is a view for describing a different operation example of the chain memory array in FIG. 3B.

FIG. 5B is a view for describing a different operation example of the chain memory array in FIG. 3B.

FIG. 5C is a view for describing a different operation example of the chain memory array in FIG. 3B.

FIG. 6A is a view illustrating an example of an initial sequence in power activation in the information processing system in FIG. 1.

FIG. 6B is a view illustrating a different example of an initial sequence in power activation in the information processing system in FIG. 1.

FIG. 7 is a view illustrating a configuration example of a physical address table stored in a random access memory in FIG. 1.

FIG. 8A is a view illustrating a configuration example of a physical segment table stored in the random access memory in FIG. 1.

FIG. 8B is a view illustrating a different configuration example of a physical segment table stored in the random access memory in FIG. 1.

FIG. 9A is a view illustrating a configuration example of a write physical address table stored in the control circuit in FIG. 2 or the random access memory in FIG. 1.

FIG. 9B is a view illustrating a configuration example of the write physical address table stored in the control circuit in FIG. 2 or the random access memory in FIG. 1.

FIG. 10A is a view illustrating a configuration example of an address conversion table stored in the random access memory in FIG. 1 and an example of a state thereof after initial setting.

FIG. 10 B is a view illustrating an example of a state in the non-volatile memory device in FIG. 1 after the initial setting.

FIG. 11A is a view illustrating an example of SSD configuration information stored in the non-volatile memory device in FIG. 1.

FIG. 11B is a view illustrating a different example of SSD configuration information stored in the non-volatile memory device in FIG. 1.

FIG. 11C is a view illustrating a different example of SSD configuration information stored in the non-volatile memory device in FIG. 1.

FIG. 12A is a view illustrating a configuration example of data written by a control circuit into a non-volatile memory device in a memory module in FIG. 1.

FIG. 12B is a view illustrating a configuration example of data write layer information in FIG. 14A.

FIG. 12C is a view illustrating a configuration example of data write layer information in FIG. 14A.

FIG. 13 is a view illustrating an example of an address map range stored in the random access memory in FIG. 1.

FIG. 14 is a view for describing a different example of a writing system for a chain memory array in the non-volatile memory device in FIG. 3A and FIG. 3B.

FIG. 15 is a flowchart illustrating an example of a detail writing processing procedure performed in a memory module in a case where a writing request is input into the memory module by the information processing device in FIG. 1.

FIG. 16 is a flowchart illustrating an example of an updating method of the write physical address table in FIG. 9A and FIG. 9B.

FIG. 17A is a view illustrating an example of a correspondence relationship between a logical address, a physical address, and an in-chip address in a non-volatile memory device assigned to a first physical address area.

FIG. 17B is a view illustrating an example of a correspondence relationship between a logical address, a physical address, and an in-chip address in a non-volatile memory device assigned to a second physical address area.

FIG. 17C is a flowchart illustrating an example of a change in a physical address PAD and a physical address CPAD in a case of writing/reading data into/from a non-volatile memory device.

FIG. 18A is a view illustrating an example of an updating method of an address conversion table and a data updating method of a non-volatile memory device in a case where the control circuit in FIG. 1 writes data into a first physical address area of the non-volatile memory device.

FIG. 18B is a view illustrating an example of an updating method of the address conversion table and a data updating method of the non-volatile memory device, these methods being subsequent to those in FIG. 18A.

FIG. 19A is a view illustrating an example of an updating method of the address conversion table and a data updating method of the non-volatile memory device in a case where the control circuit in FIG. 1 writes data into a second physical address area of the non-volatile memory device.

FIG. 19B is a view illustrating an example of an updating method of the address conversion table and a data updating method of the non-volatile memory device, these methods being subsequent to those in FIG. 19A.

FIG. 20A is a flowchart illustrating an example of a data reading operation performed by a memory module in a case where a reading request is input into the memory module by the information processing device in FIG. 1.

FIG. 20B is a flowchart illustrating an example of a data reading operation performed by a memory module in a case where a reading request is input into the memory module by the information processing device in FIG. 1.

FIG. 21A is a flowchart illustrating, with the SSD configuration information illustrated in each of FIG. 11A to FIG. 11C as an example, an example of a writing operation of a memory module which operation is performed according to writing method selection information.

FIG. 21B is a flowchart illustrating, with the SSD configuration information illustrated in each of FIG. 11A to FIG. 11C as an example, an example of a writing operation of a memory module which operation is performed according to writing method selection information.

FIG. 22 is a flowchart illustrating an example of a wear leveling method.

FIG. 23A is a view illustrating an example of a data-writing operation executed in a pipeline manner in an inner part of a memory module in a case where a writing request is successively generated for the memory module by the information processing device in FIG. 1.

FIG. 23B is a view illustrating a different example of a data-writing operation executed in a pipeline manner in an inner part of a memory module in a case where a writing request is successively generated for the memory module by the information processing device in FIG. 1.

FIG. 24 is a schematic plan view illustrating an arrangement example of a memory array ARY in a non-volatile memory device.

FIG. 25 is a schematic plan view illustrating a different arrangement example of a memory array ARY in a non-volatile memory device.

FIG. 26A is a flowchart illustrating writing processing on a write area.

FIG. 26B is a schematic plan view illustrating a different arrangement example of a memory array ARY in a non-volatile memory device.

FIG. 27 is a schematic plan view illustrating a different arrangement example of a memory array ARY in a non-volatile memory device.

FIG. 28 is schematic plan view illustrating a different arrangement example of a memory array ARY in a non-volatile memory device.

FIG. 29A is a flowchart illustrating writing processing on a write area.

FIG. 29B is a schematic plan view illustrating a different arrangement example of a memory array ARY in a non-volatile memory device.

FIG. 29C is a flowchart illustrating writing processing on a write area.

FIG. 30 is a view illustrating a relationship between a pulse width and a temperature necessary for a phase change of a resistive storage element using a phase-change material.

FIG. 31 is a schematic plan view illustrating a different arrangement example of a memory array ARY in a non-volatile memory device.

FIG. 32A is a schematic plan view illustrating a different arrangement example of a memory array ARY in a non-volatile memory device.

FIG. 32B is a schematic plan view illustrating a different arrangement example of a memory array ARY in a non-volatile memory device.

FIG. 33A is a schematic plan view illustrating a different arrangement example of a memory array ARY in a non-volatile memory device.

FIG. 33B is a schematic plan view illustrating a different arrangement example of a memory array ARY in anon-volatile memory device.

FIG. 34 is a flowchart illustrating writing processing on a write area.

### DESCRIPTION OF EMBODIMENTS

In the following embodiments, each of the embodiments will be divided into a plurality of sections or embodiments in a description when necessary for convenience. Except for a case with specification, these are related to each other. One is a modification example, an application example, a detail description, a supplemental description, or the like of a part or a whole the other. Also, in the following embodiments, in a case of referring to the number of elements (including number, value, amount, range, and the like), the specific number is not a limitation and the number may be the specific number or more/less except for a case where there is a specification and a case where the specific number is obviously a limitation in principle.

Moreover, in the following embodiments, a configuration element (including element step and the like) is not necessarily included except for a case where there is a specification and a case where the element is obviously necessary in principle. Similarly, in the following embodiments, in a case of referring to a shape, a positional relationship, and the like of a configuration element or the like, what is substantially approximate or similar to the shape and the like is included except for a case where there is a specification or a case where it is obviously not so in principle. Similarly, this can be applied to the above number and the like (including number, value, amount, range, and the like).

In the following, embodiments of the present invention will be described in detail with reference to the drawings. Note that in all of the drawings for describing the embodiments, the same or related sign is assigned to members with the same function and a repetitious description thereof is omitted. Also, in the following embodiments, a description of the same or similar parts is not repeated in principle except for a case where the description is necessary.

Although it is not specifically limited, a circuit element included in each block in the embodiment is formed on one semiconductor substrate such as single-crystal silicon by an integrated-circuit technology such as a known complementary MOS transistor (CMOS). Also, as a memory cell described in the embodiments, a resistive storage element such as a phase-change memory or a resistive random access memory (ReRAM) is used.

### First Embodiment

### Outline of Information Processing System

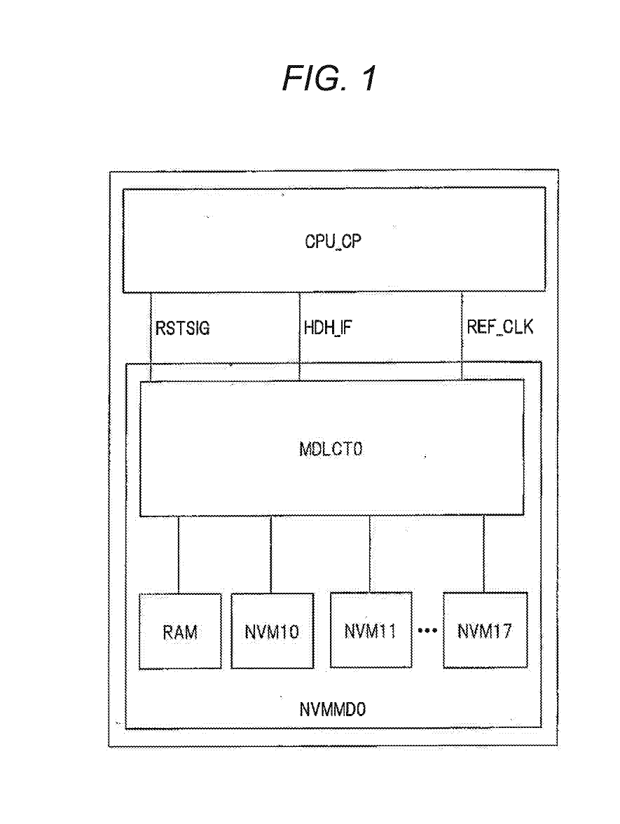

FIG. 1 is a block diagram illustrating a schematic configuration example of an information processing system to which a semiconductor device of an embodiment of the present invention is applied. The information processing system illustrated in FIG. 1 includes an information processing device (processor) CPU_CP and a memory module (semiconductor device) NVMMD0. Although it is not specifically limited, the information processing device CPU_CP is a host controller that manages data, which is stored in the memory module NVMMD0, in a logical address (LAD) in a minimum 512-byte unit. The information processing device CPU_CP reads/writes data from/into the memory module NVMMD0 through an interface signal HDH_IF. Although it is not specifically limited, the memory module NVMMD0 corresponds, for example, to a solid state drive (SSD).

As a signal system that connects the information processing device CPU_CP and the memory module (semiconductor device) NVMMD0, there are a serial interface signal system, a parallel interface signal system, an optical interface signal system, and the like. Obviously, all systems can be used. As a clock system that operates the information processing device CPU_CP and the memory module NVMMD0, there are a common clock system and a source synchronous clock system using a reference clock signal REF_CLK, an embedded clock system in which clock information is embedded to a data signal, and the like. Obviously, all clock systems can be used. In the present embodiment, it is assumed that the serial interface signal system and the embedded clock system are used as an example and an operation will be described in the following.

A reading request (RQ) or a writing request (WQ) into which clock information is embedded and which is converted into serial data is input into the memory module NVMMD0 by the information processing device CPU_CP through the interface signal HDH_IF. The reading request (RQ) includes a logical address (LAD), a data-reading instruction (RD), a sector count (SEC), and the like. The writing request (WQ) includes a logical address (LAD), a data writing instruction (WRT), a sector count (SEC), write data (WDATA), and the like.

The memory module (semiconductor device) NVMMD0 includes non-volatile memory devices NVM10 to NVM17, a random access memory RAM, a control circuit MDLCT0 that controls these non-volatile memory devices and the random access memory. The non-volatile memory devices NVM10 to NVM17 include, for example, the same configuration and performance. Each of the non-volatile memory devices NVM10 to NVM17 stores data, an OS, an application program, and SSD configuration information (SDCFG). A boot program or the like of the information processing device CPU_CP is further included. Although it is not specifically limited, the random access memory RAM is, for example, a DRAM.

Immediately after power activation, the memory module NVMMD0 performs an operation of initializing the non-volatile memory devices NVM10 to NVM17, the random access memory RAM, and the control circuit MDLCT0 in an inner part thereof (that is, power on reset). Moreover, the memory module NVMMD0 performs initialization of the non-volatile memory devices NVM10 to NVM17, the random access memory RAM, and the control circuit MDLCT0 in the inner part thereof when a reset signal RSTSIG is received from the information processing device CPU_CP.

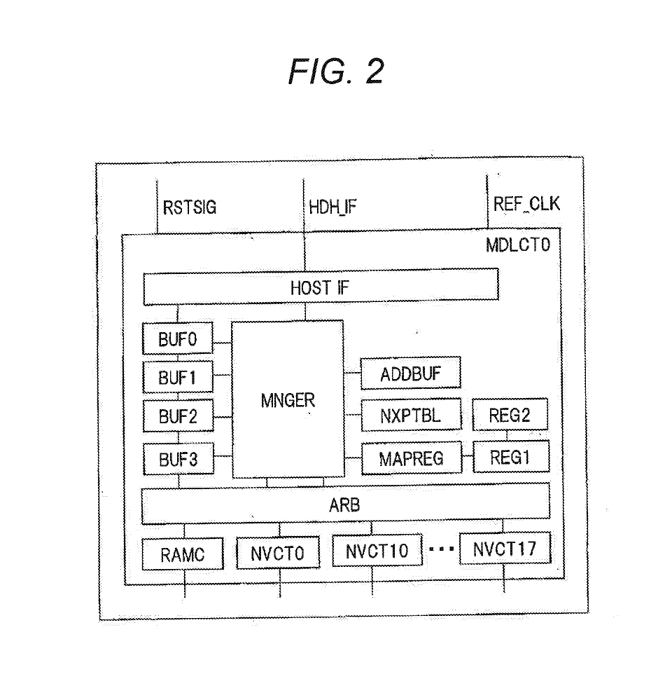

FIG. 2 is a block diagram illustrating configuration example of the control circuit in FIG. 1. The control circuit MDLCT0 illustrated in FIG. 2 includes an interface circuit HOST_IF, buffers BUF0 to BUF3, an address buffer ADDBUF, write physical address tables NXPTBL (NXPTBL1 and NXPTBL2), an arbitration circuit ARB, an information processing circuit MNGER, memory control circuits RAMC, NVCT0, and NVCT10 to NVCT7, a map register MAPREG, and registers REG1 and REG2. The memory control circuit RAMC directly controls the random access memory RAM in FIG. 1. The memory control circuits NVCT0 and NVCT10 to NVCT7 directly and respectively control the non-volatile memory devices NVM0, and NVM10 to NVM17 in FIG. 1.

The buffers BUF0 to BUF3 temporality store write data or read data in the non-volatile memory devices NVM10 to NVM17. The address buffer ADDBUF temporarily stores an address LAD that is input into the control circuit MDLCT0 by the information processing device (processor) CPU_CP.

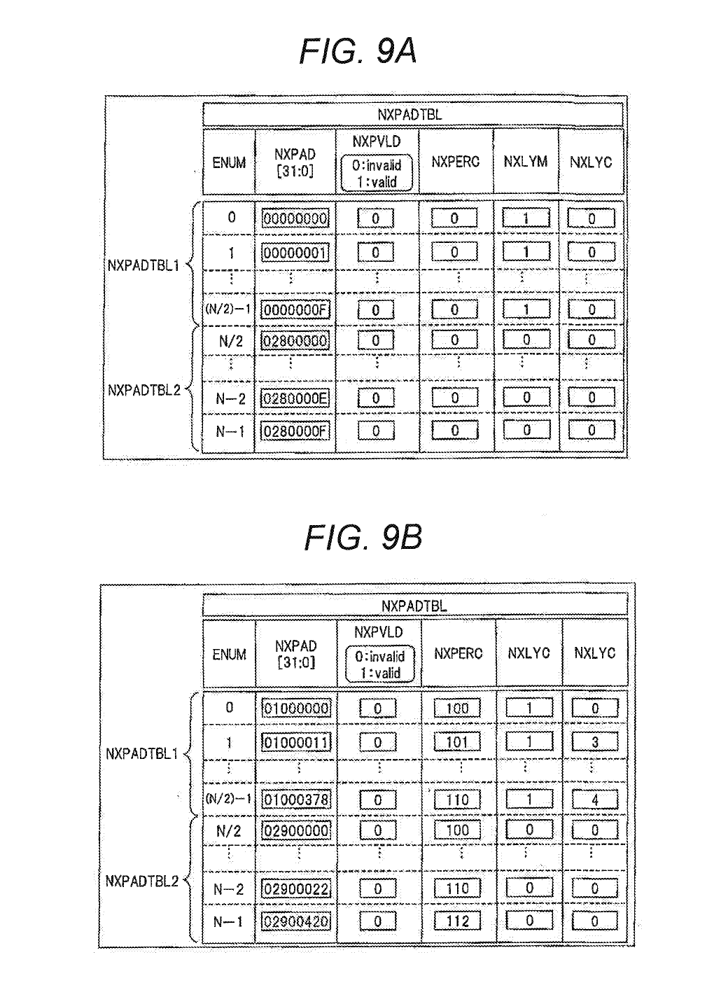

A detail of the write physical address table NXPTBL will be described later with reference to FIG. 9A, FIG. 9B, and the like. The write physical address table NXPTBL is a table that stores a physical address assigned, in next reception of a writing instruction including a logical address from the information processing device CPU_CP, to the logical address. Although it is not specifically limited, the table is realized by an SRAM, a register, or the like. A detail of each of the map register MAPREG and the registers REG1 and REG 2 will be described later. Each of these registers is a register that holds information related to a whole area of a memory space. Note that the SSD configuration information (SDCFG) or the boot program can be arranged in the control circuit MDLCT0, for example, in a manner directly connected to the information processing circuit MNGER in FIG. 2 in order to increase speed of initial setting of the memory module NVMMD0.

### <Whole Configuration and Operation of Non-Volatile Memory Device>

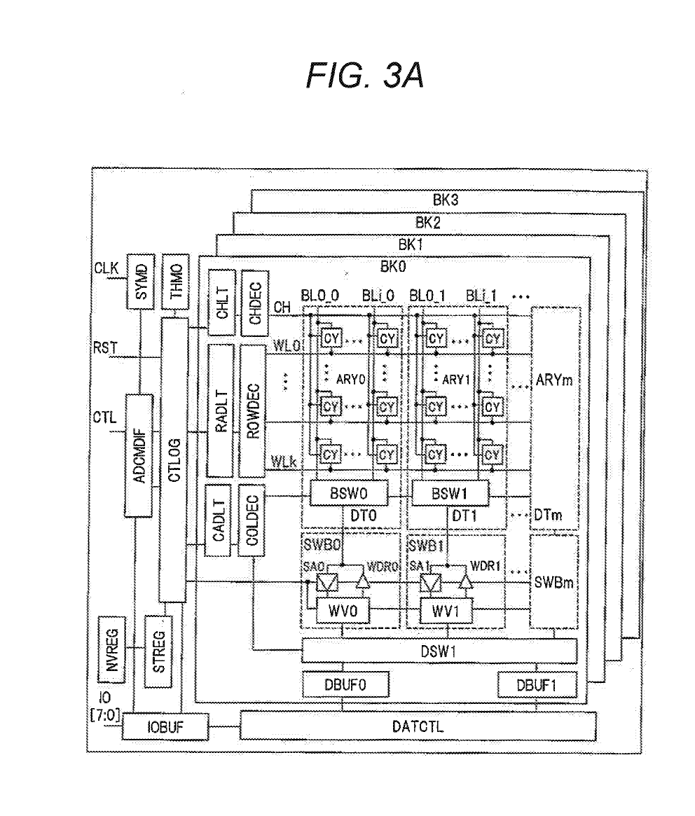

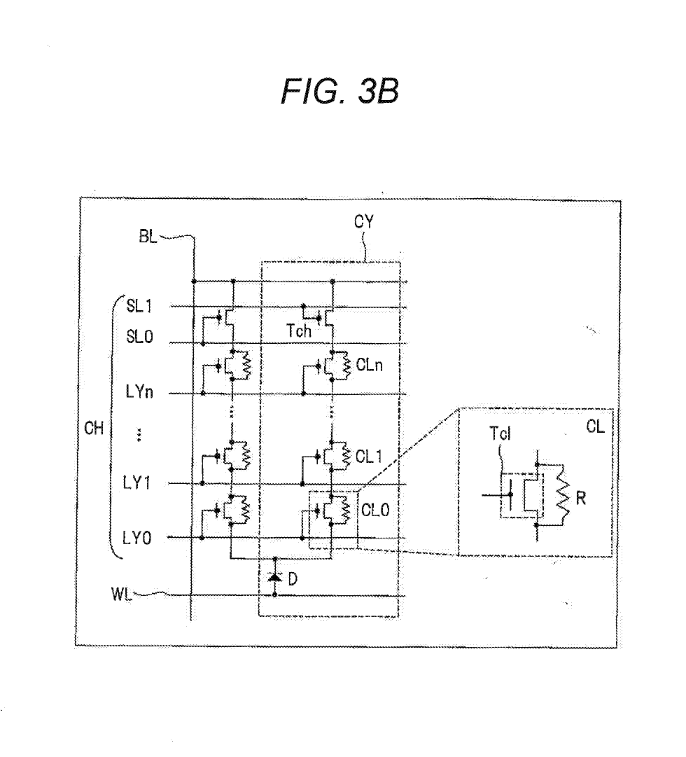

FIG. 3A is a block diagram illustrating a configuration example of the non-volatile memory device in FIG. 1 and FIG. 3B is a circuit diagram illustrating a configuration example of a chain memory array in FIG. 3A. The non-volatile memory device in FIG. 3A corresponds to each of the non-volatile memory devices NVM10 to NVM17 in FIG. 1. Here, as an example, a non-volatile phase-change memory (phase-change memory) is used. The non-volatile memory device includes a clock generating circuit SYMD, a status register STREG, an erasure-size designation register NVREG, an address-command interface circuit ADCMDIF, an IO buffer IOBUF, a control circuit CTLOG, a temperature sensor THMO, a data control circuit DATCTL, and memory banks BK0 to BK3.

Each of the memory banks BK0 to BK3 includes a memory array ARYx (x=0 to m), a reading/writing control block SWBx (x=0 to m) provided in a manner corresponding to each memory array, and various peripheral circuits to control these. The various peripheral circuits include a row address latch RADLT, a column address latch CADLT, a row decoder ROWDEC, a column decoder COLDEC, a chain selection address latch CHLT, a chain decoder CHDEC, a data selection circuit DSW1, and data buffers DBUF0 and DBUF1.

Each memory array ARYx (x=0 to m) includes a plurality of chain memory arrays CY arranged in intersection points of a plurality of word lines WL0 to WLk and a plurality of bit lines BL0_x to BLi_x, and a bit line selection circuit BSWx that selects one of the plurality of bit lines BL0_x to BLi_x and connects the selected line to a data line DTx. Each reading/writing control block SWBx (x=0 to m) includes a sense amplifier SAx and a writing driver WDRx connected to the data line DTx, and a write data verification circuit WVx that performs verification of data by using these during a writing operation.

As illustrated in FIG. 3B, each chain memory array CY includes a configuration in which a plurality of phase-change memory cells CL0 to CLn is connected in series. One end of the chain memory array CY is connected to a word line WL via a diode D and the other end is connected to a bit line BL via a chain selection transistor Tch. Although not illustrated, the plurality of phase-change memory cells CL0 to CLn is serially arranged in a laminated manner in a height direction with respect to a semiconductor substrate and is connected to each other in series. Also, each of the phase-change memory cells CL includes a variable resistive-type storage element R and a memory-cell selection transistor Tcl connected thereto in parallel. The storage element R includes, for example, a chalcogenide material.

In an example of FIG. 3B, two chain memory arrays CY share the diode D. The chain selection transistor Tch in each of the chain memory arrays is controlled by chain memory array selection lines SL0 and SL1. Accordingly, either one of the chain memory arrays is selected. Also, each of the memory-cell selection lines LY (LY0 to LYn) is connected to a gate electrode of a corresponding phase-change memory cell. By the memory-cell selection lines LY, memory-cell selection transistors Tcl in the phase-change memory cells CL0 to CLn are respectively controlled. Accordingly, each of the phase-change memory cells is arbitrarily selected. Note that each of the chain memory array selection lines SL0 and SL1 and memory-cell selection lines LY0 to LYn is arbitrarily driven as a chain control line CH through the chain selection address latch CHLT and the chain decoder CHDEC in FIG. 1.

Next, an operation of the non-volatile memory device in FIG. 3A will be described briefly. In FIG. 3A, first, the control circuit CTLOG receives a control signal CTL through the address-command interface circuit ADCMDIF. Although it is not specifically limited, the control signal CTL includes, for example, a command-latch enabling signal (CLE), a chip enabling signal (CEB), an address-latch signal (ALE), a writing enabling signal (WEB), a reading enabling signal (REB), and a ready/busy signal (RBB). By a combination of these signals, a writing instruction or a reading instruction is issued. Also, the control circuit CTLOG receives an input/output signal IO through the IO buffer IOBUF along with the control signal CTL. The input/output signal IO includes an address signal and the control circuit CTLOG extracts a row address and a column address from the address signal. The control circuit CTLOG arbitrarily generates an inner address based on the row address, the column address, a predetermined writing/reading unit, and the like and transmits the generated address to the row address latch RADLT, the column address latch CADLT, and the chain selection address latch CHLT.

The row decoder ROWDEC receives an output from the row address latch RADLT and selects one of the word lines WL0 to WLk. The column decoder COLDEC receives an output from the column address latch CADLT and selects one of the bit lines BL0 to BLi. Also, the chain decoder CHDEC receives an output from the chain selection address latch CHLT and selects one of the chain control lines CH. When a reading instruction is input by the control signal CTL, data is read through bit line selection circuits BSW0 to BSWm from the chain memory array CY selected by a combination of the word line, the bit line, and the chain control line. The read data is amplified by sense amplifiers SA0 to SAm and is transmitted to the data buffer DBUF0 (or DBUF1) through the data selection circuit DSW1. Then, the data on the buffer DBUF0 (or DBUF1) is serially transmitted to the input/output signal IO through the data control circuit DATCTL and the IO buffer IOBUF.

On the other hand, when a writing instruction is input by the control signal CTL, a data signal is transmitted to the input/output signal IO after the address signal. The data signal is input into the data buffer DBUF0 (or DBUF1) through the data control circuit DATCTL. The data signal on the data buffer DBUF0 (or DBUF1) is written into the chain memory array CY selected by a combination of the word line, bit line, and the chain control line through the data selection circuit DSW1, the writing drivers WDR0 to WDRm, and the bit line selection circuits BSW0 to BSWm. Here, the write data verification circuits WVO to WVm arbitrarily read the written data through the sense amplifiers SA0 to SAm, verifies whether a write level reaches an adequate level, and repeatedly perform the writing operation with the writing drivers WDR0 to WDRm until the write level reaches the adequate level.

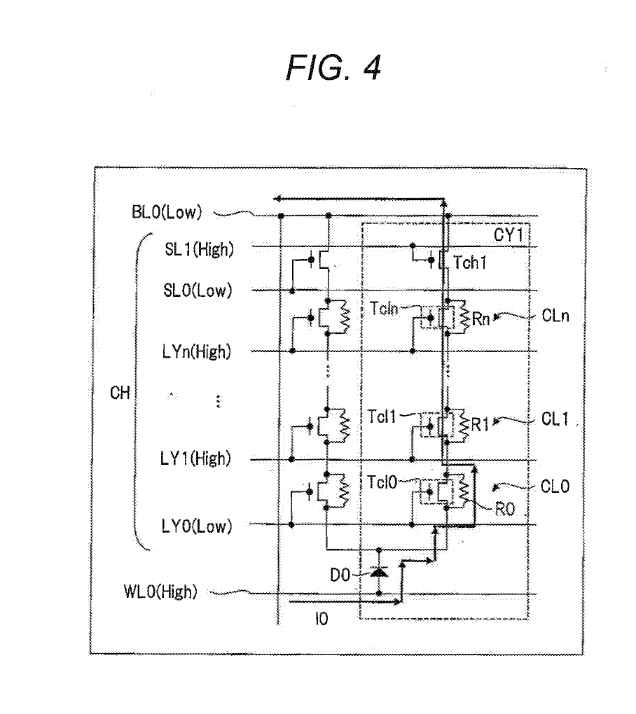

FIG. 4 is a view for describing an operation example of the chain memory array in FIG. 3B. With reference to FIG. 4, for example, an operation in a case of making a variable resistive-type storage element R0 in a phase-change memory cell CL0 in the chain memory array CY1 high resistive or low resistive will be described. Only the chain memory array selection line SL1 is activated (SL0=Low and SL1=High) by the chain decoder CHDEC and a chain selection transistor Tch1 becomes conductive. Then, only the memory-cell selection line LY0 is deactivated (LY0=Low and LY1 to LYn=High) and a memory-cell selection transistor Tcl0 of the phase-change memory cell CL0 is brought into a cut-off state. Memory cell selection transistor Tcl1 to Tcln of the remaining memory cells CL1 to CLn become conductive.

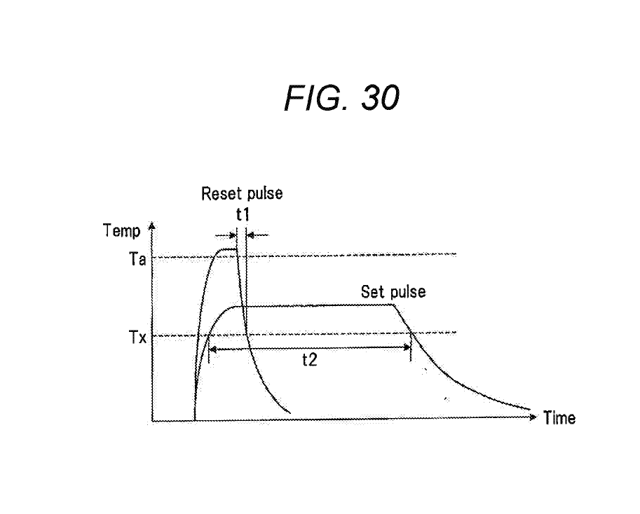

Then, when the word line WL0 becomes High and the bit line BL0 becomes Low, current I0 flows from the word line WL0 to the bit line BL0 through the diode D0, the variable resistive-type storage element R0, the memory-cell selection transistors Tcl1 to Tcln, and the chain selection transistor Tch1. When the current I0 is controlled to a shape of a Reset current pulse illustrated in FIG. 30, the variable resistive-type storage element R0 becomes high resistive. Also, when the current I0 is controlled to a shape of a Set current pulse illustrated in FIG. 30, the variable resistive-type storage element R0 becomes low resistive. With a difference between resistance values of the variable resistive-type storage elements R0 to Rn, data “1” and data “0” are distinguished from each other. Although it is not specifically limited, it is assumed that the data “1” is recorded when the variable resistive-type storage element becomes low resistive and that the data “0” is recorded when the variable resistive-type storage element becomes high resistive.

Note that in a case of reading the data recorded in the variable resistive-type storage element R0, current is applied in a degree, in which a resistance value of the variable resistive-type storage element R0 is not varied, in a path similar to that of data writing. In this case, a voltage value corresponding to the resistance value of the variable resistive-type storage element R0 is detected by the sense amplifier (SA0 in FIG. 3A, in this example) and it is determined whether the data is “0” or “1.”

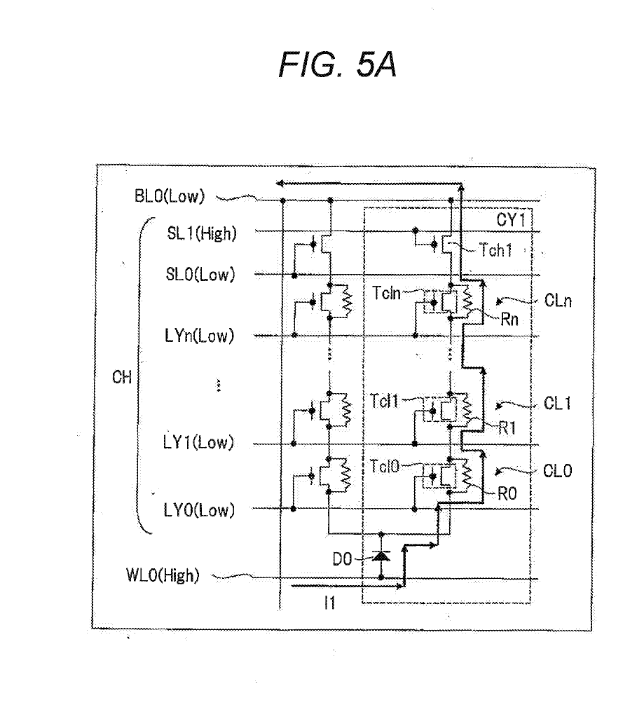

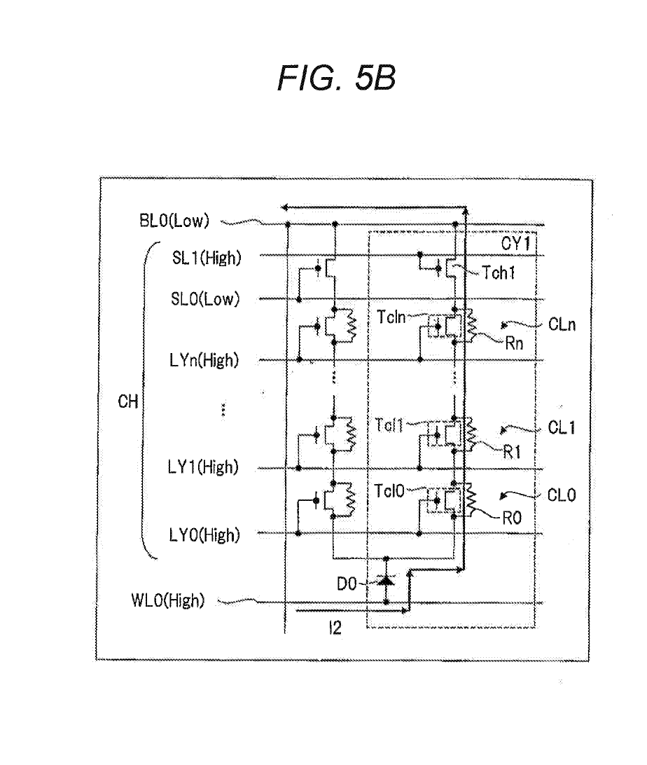

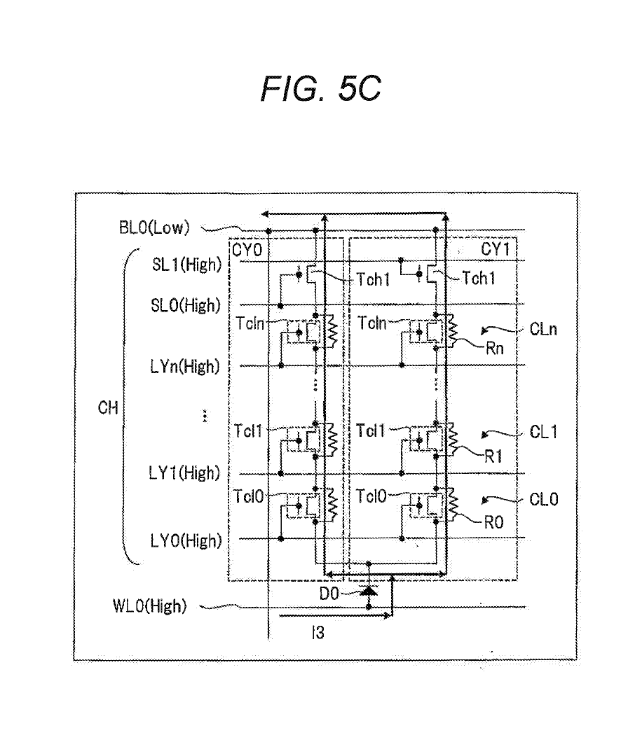

Each of FIG. 5A, FIG. 5B, and FIG. 5C is a view for describing a different operation example of the chain memory array in FIG. 3B. First, with reference to FIG. 5A, an operation of simultaneously making all variable resistive-type storage elements R0 to Rn in one chain memory array CY1 low resistive will be described. Only the chain memory array selection line SL1 is activated (SL0=Low and SL1=High) by the chain decoder CHDEC and the chain selection transistor Tch1 becomes conductive. Then, the memory-cell selection lines LY0 to LYn are deactivated (LY0 to Lyn=Low) and the memory-cell selection transistors Tcl0 to Tcln of the memory cells CL0 to CLn are brought into a cut-off state. Then, when the word line WL0 becomes High and the bit line BL0 becomes Low, current I1 flows from the word line WL0 to the bit line BL0 through the diode D0, the variable resistive-type storage elements R0 to Rn, and the chain selection transistor Tch1. When the current I1 is controlled to the shape of the Set current pulse illustrated in FIG. 30, the variable resistive-type storage elements R0 to Rn become low resistive simultaneously.

Next, with reference to FIG. 5B, an operation of simultaneously making all variable resistive-type storage elements R0 to Rn in the one chain memory array CY1 low resistive will be described. Only the chain memory array selection line SL1 is activated (SL0=Low and SL1=High) by the chain decoder CHDEC and the chain selection transistor Tch1 becomes conductive. Then, the memory-cell selection lines LY0 to LYn are activated (LY0 to LYn=High) and the memory-cell selection transistors Tcl0 to Tcln of the memory cells CL0 to CLn become conductive. Then, when the word line WL0 becomes High and the bit line BL0 becomes Low, current I2 flows from the word line WL0 to the bit line BL0 through the diode D0, the memory-cell selection transistors Tcl0 to Tcln, and the chain selection transistor Tch1. Joule heat due to this current I2 is conducted to the variable resistive-type storage elements R0 to Rn and the variable resistive-type storage elements R0 to Rn become low resistive simultaneously. The current I2 is controlled to a value with which it is possible to make the variable resistive-type storage elements R0 to Rn low resistive simultaneously.

Next, with reference to FIG. 5C, an operation of simultaneously making all variable resistive-type storage elements R0 to Rn in the chain memory arrays CY0 and CY1 low resistive will be described. The chain memory array selection lines SL0 and 1 are activated (SL0 and SL1=High) by the chain decoder CHDEC and the chain selection transistor Tch1 of each of the chain memory arrays CY0 and CY1 becomes conductive. Then, the memory-cell selection lines LY0 to LYn are activated (LY0 to LYn=High) and memory-cell selection transistors Tcl0 to Tcln of the memory cells CL0 to CLn of each of the chain memory arrays CY0 and CY1 become conductive. Then, when the word line WL0 becomes High and the bit line BL0 becomes Low, current I3 flows from the word line WL0 to the bit line BL0 through the diode D0, the memory-cell selection transistor Tcl0 to Tcln and the chain selection transistor Tch1 of each of the chain memory arrays CY0 and CY1. Joule heat due to this current I3 is conducted to the variable resistive-type storage elements R0 to Rn of each of the chain memory arrays CY0 and CY1 and the variable resistive-type storage elements R0 to Rn become low resistive simultaneously. A value of the current I3 is controlled to a value with which it is possible to simultaneously make the variable resistive-type storage elements R0 to Rn of each of the chain memory arrays CY0 and CY1 low resistive.

As described above, it is possible to simultaneously make memory cells in a plurality of chain memory arrays low resistive when necessary and to improve a data erasing rate.

### <Derailed Operation System of Chain Memory Array>

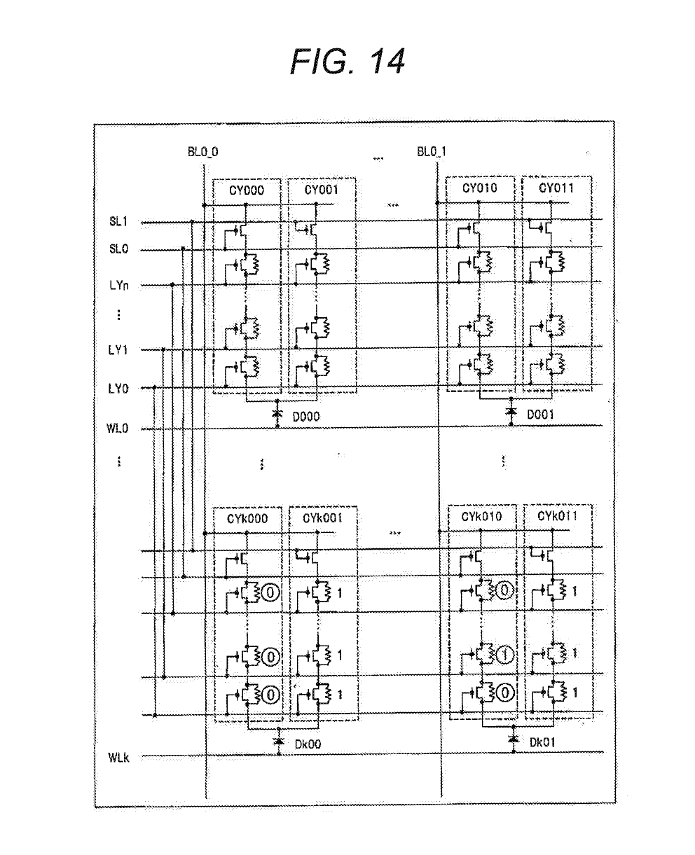

Here, an operation system of a chain memory array which system is one of major characteristics of the present embodiment will be described. FIG. 14 is a view for describing an example of a writing system with respect to a chain memory array in the non-volatile memory device in FIG. 3A and FIG. 3B. Although it is not specifically limited, the non-volatile memory device according to the present embodiment includes two operation modes (first operation mode and second operation mode). For example, the second operation mode is an operation mode of performing writing of (n+1) bits with respect to an (n+1)-bit phase-change memory cell, which is included in the chain memory array, according to one writing instruction from a side of a host (CPU_CP in FIG. 1). On the other hand, the first operation mode is an operation mode of performing writing of j bits (j<(n+1)). An address area of the non-volatile memory device is divided, for example, to an address area where writing can be performed in the first operation mode and an address area where writing can be performed in the second operation mode. In the following, a case of performing writing in the second operation mode will be described as an example.

That is, for example, a writing operation of (n+1) bits which operation is performed with respect to the (n+1)-bit phase-change memory cell included in the chain memory array according to one writing instruction from the side of the host (CPU_CP in FIG. 1) will be described. Note that a detailed control method of the word line, the bit line, the chain control line, and the like along with the writing operation is similar to the case in FIG. 4 and FIG. 5A to FIG. 5C.

Here, a case where the writing operation is performed, with the memory-cell selection line LY0 as an object, with respect to the chain memory arrays CYk000 and CYk010 will be described as an example. It is assumed that the same physical address [1] is assigned to the chain memory arrays CYk000 and CYk010 in FIG. 14. Note that in FIG. 14, an example of a change in the chain memory array along with the writing operation is also illustrated.

First, a writing instruction [1] an object of which is the physical address [1] is input. When the instruction is input, first, “1” (set state) is once written (initial writing/block erasure) into all phase-change memory cells in each of the chain memory arrays CYk000, CYk001, CYk010, and CYk011 in the writing operation illustrated in FIG. 5C.

Then, predetermined data associated with the writing instruction [1] is written into all phase-change memory cells in each of the chain memory arrays CYk000, CYk001, CYk010, and CYk011.

In this example, as the data associated with the writing instruction [1], bit data is “0 . . . 00” with respect to (n+1) bits for the chain memory array CYk000. Also, written bit data is “0 . . . 10” with respect to (n+1) bits for the chain memory array CYk010. Here, data of all phase-change memory cells in each of the chain memory arrays CYk000 and CYk010 is previously set to “1” in the initial writing (erasure). Thus, in a phase-change memory cell corresponding to a bit of data associated with the writing instruction [1] being “1” (here, phase-change memory cell corresponding to LY1 in CYk010), the writing operation is not specifically performed and “0” (reset state) is written into the other phase-change memory cells. More specifically, for example, while a deactivated memory-cell selection line is serially shifted from LY0 to LY1 . . . and to LYn, it is selected, at each time, whether to apply a Reset current pulse in FIG. 30 between the word line WLk and the bit line BL0_0 and between the word line WLk and the bit line BL0_1. In this example, the Reset current pulse is applied except for a case where the memory-cell selection line LY1 is deactivated, in which case the pulse is not applied between the word line WLk and the bit line BL0_1.

Then, when a writing instruction [2] an object of which is the physical address [1] is input again, the initial writing (erasure) is performed first similarly to the case of the writing instruction [1]. Then, “0” (reset state) is arbitrarily written based on each piece of (n+1)-bit data for the chain memory arrays CYk000 and CYk010 which data is associated with the writing instruction [2]. Note that here, “0” (reset state) is written while a deactivated memory-cell selection line is serially shifted. However, in some cases, it is possible to perform writing simultaneously without shifting the memory-cell selection line. That is, for example, the Reset current pulse may be applied between the word line WLk and the bit line BL0_0 in a state in which all of the memory-cell selection lines LY0 to LYn are deactivated and the Reset current pulse may be applied between the word line WLk and the bit line BL0_1 in a state in which the memory-cell selection lines LY0 to LYn except for the memory-cell selection line LY1 are deactivated.

By utilization of the operation system of the memory array which system is described above with reference to FIG. 14, for example, the following effects can be acquired.

(1) It is possible to make memory cells in a plurality of chain memory arrays low resistive simultaneously and to improve a data erasing rate.

(2) Writing speed is increased since only data “0” is written into a memory cell after erasure in a chain memory array.

(3) A stable writing operation can be realized since a system of writing, after one of a set state and a reset state is simultaneously written into all memory cells in a chain memory array once (after erasure), the other state into a specific memory cell is used. That is, it is possible to keep states (resistance value) of memory cells in the chain memory array in a substantially uniform manner by writing one state simultaneously. When the other state is subsequently written into a specific memory cell, each memory cell arranged in a periphery of the specific memory cell receives a similar influence in a similar initial state due to heat generated by the writing. As a result, it is possible to decrease a variation amount among resistance values of memory cells in the chain memory array. Accordingly, it becomes possible to realize a stable writing operation.

Specifically, the chain memory array illustrated in FIG. 14 and the like is a chain memory array having a laminated structure in which memory cells are laminated on a semiconductor substrate. In the chain memory array having the laminated structure, memory cells are likely to be arranged in an adjacent manner compared to a case where the laminated structure is not used. Thus, it becomes useful to decrease a variation amount by such a system.

Also, here, the set state is used in the initial writing (erasure) and the reset state is used in the subsequent writing into a specific memory cell. Accordingly, a more stable writing operation can be realized. For example, in a phase-change memory cell, the set state is usually more stable than the reset state. Also, as illustrated in FIG. 30, a pulse width in a case of writing the set state is wider than a pulse width in a case of writing the reset state. Thus, in a case of writing the set state, heat generated by the writing operation is easily spread to a periphery and it is more likely that there is an influence on a storing state of a peripheral phase-change memory cell. In view of the forgoing, it becomes useful to use a system, in which the set state is not written into a specific phase-change memory cell, such as the writing system of the present embodiment. When the writing system of the present embodiment is used, in a case of writing a reset state into a specific phase-change memory cell, a peripheral phase-change memory cell is stable in the set state because of the initial writing (erasure). In addition, since a pulse width in the writing of the reset state is narrow, the spread of heat due to the writing is also controlled.

### <Initial Sequence in Power Activation>

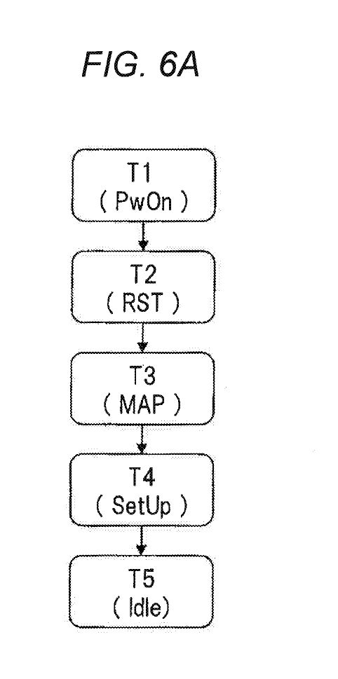

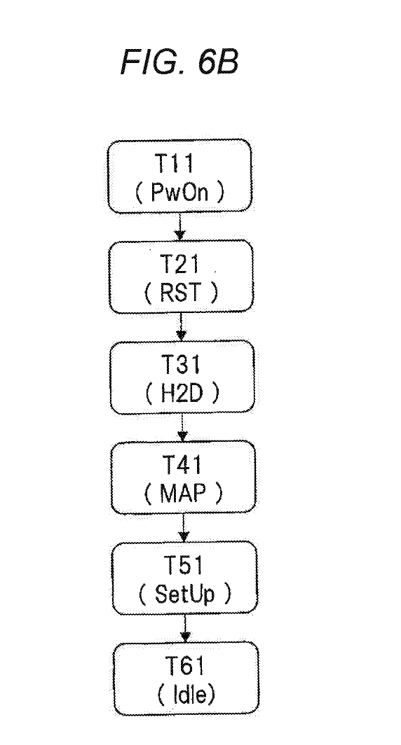

FIG. 6A and FIG. 6B are views illustrating different examples of an initial sequence in power activation in the information processing system in FIG. 1. FIG. 6A is a view illustrating an initial sequence in power activation in a case where SSD configuration information (SDCFG) stored in the non-volatile memory devices NVM10 to 17 in the memory module (semiconductor device) NVMMD0 in FIG. 1 is used. FIG. 6B is a view illustrating an initial sequence in power activation in a case where the SSD configuration information (SDCFG) transmitted from the information processing device CPU_CP in FIG. 1 is used.

First, the initial sequence illustrated in FIG. 6A will be described. In a period of T1 (PwOn), power is activated in the information processing device CPU_CP, the non-volatile memory devices NVM10 to NVM17 in the memory module NVMMD0, the random access memory RAM, and the control circuit MDLCT0 and reset is performed in a period of T2 (RST). A method of the reset is not specifically limited but may be, for example, a method of automatically performing reset in each built-in circuit or a method of including an external reset terminal (reset signal RSTSIG) and performing a reset operation with the reset signal. Also, for example, a method of inputting a reset instruction into the control circuit MDLCT0 from the information processing device CPU_CP through the interface signal HDH_IF and performing the reset may be used.

In the reset period of T2 (RST), an internal state of each of the information processing device CPU_CP, the control circuit MDLCT0, the non-volatile memory devices NVM10 to NVM17, and the random access memory RAM is initialized. Here, the control circuit MDLCT0 initializes an address map range (ADMAP) and various tables stored in the random access memory RAM. The various tables include an address conversion table (LPTBL), physical segment tables (PSEGTBL1 and PSEGTBL2), a physical address table (PADTBL), and a write physical address table (NXPADTBL).

Note that details of the address map range (ADMAP) and the various tables will be described later but brief descriptions thereof are as follows. The address map range (ADMAP) indicates a division of an address area used in the first operation mode and an address area used in the second operation mode. The address conversion table (LPTBL) indicates a correspondence relationship between a current logical address and physical address. The physical segment tables (PSEGTBL1 and PSEGTBL2) manage the number of times of erasure in each physical address in a segment unit and are used in wear leveling and the like. The physical address table (PADTBL) manages a state of current each physical address in detail. The write physical address table (NXPADTBL) is a table in which a physical address that is to be subsequently assigned to a logical address is determined based on wear leveling. Here, a part or a whole of the information in the write physical address table (NXPADTBL) is copied to the write physical address tables NXPTBL1 and NXPTBL2 illustrated in FIG. 2 in order to increase writing speed.

In a period of T3 (MAP) after the period of T2 is over, the control circuit MDLCT0 reads the SSD configuration information (SDCFG) stored in the non-volatile memories NVM10 to 17 and transfers the read information to the map register MAPREG in FIG. 2. Then, the SSD configuration information (SDCFG) in the map register MAPREG is read. By utilization of the SSD configuration information (SDCFG), the address map range (ADMAP) is generated and stored into the random access memory RAM.

Moreover, two logical address areas (LRNG1 and LRNG2) are set in the SSD configuration information (SDCFG) in the map register MAPREG and the control circuit MDLCT0 constructs a write physical address table (NXPADTBL) corresponding thereto. More specifically, for example, the write physical address table (NXPADTBL) is divided into a write physical address table (NXPADTBL1) for the logical address area (LRNG1) and a write physical address table (NXPADTBL2) for the logical address area (LRNG2). For example, the logical address area (LRNG1) corresponds to the area for the first operation mode and the logical address area (LRNG2) corresponds to the area for the second operation mode.

Although it is not specifically limited, N/2 entries from the zeroth entry to the (N/2−1)th entry can be set as the write physical address table NXPADTBL1 when the write physical address table (NXPADTBL) includes N entries from the zeroth entry to the (N−1)th entry. Then, the remaining N/2 entries from N/2th entry to the Nth entry can be set as the write physical address table (NXPADTBL2).

In a period of T4 (SetUp) after the period of T3 is over, the information processing device CPU_CP reads a boot program stored in the non-volatile memory device NVM0 in the memory module NVMMD0 and sets up the information processing device CPU_CP. In and after a period of T5 (Idle) after the period of T4 is over, the memory module NVMMD0 becomes an idle state and waits for a request from the information processing device CPU_CP.

Next, the initial sequence illustrated in FIG. 6B will be described. In a period of T11 (PwOn) and a period of T21 (RST), operations similar to those in the period of T1 and the period of T2 in FIG. 6A are respectively performed. In a period of T31 (H2D) after the period of T21 is over, the information processing device CPU_CP transmits the SSD configuration information (SDCFG) to the memory module NVMMD0. The control circuit MDLCT0, which receives this, stores the SSD configuration information (SDCFG) into the non-volatile memory device NVM0. In a period of T41 (MAP), a period of T51 (SetUp), and a period of T61 (Idle) after the period of T31 is over, operations similar to those in the periods of T3, T4, and T5 in FIG. 6A are respectively performed.

In such an initial sequence, when the SSD configuration information (SDCFG) is previously stored in the memory module NVMMD0 (non-volatile memory device NVM10 to 17) as illustrated in FIG. 6A, it is possible to execute the initial sequence at high speed in power activation. On the other hand, as illustrated in FIG. 6B, in a case of transmitting the SSD configuration information (SDCFG) from the information processing device CPU_CP to the memory module NVMMD0, it is possible to arbitrarily customize a configuration (usage) of the memory module NVMMD0 according to an operation purpose or the like of the information processing system.

### <Detail of Physical Address Table>

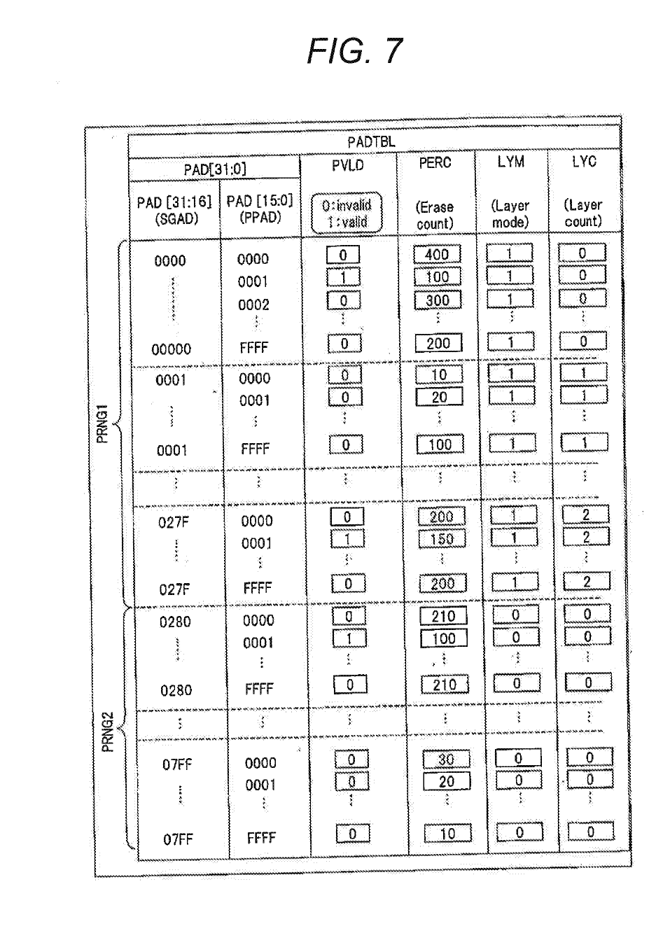

FIG. 7 is a view illustrating a configuration example of a physical address table stored in the random access memory in FIG. 1. The physical address table PADTBL includes a physical address PAD (PAD [31:0]), and a validity flag PVLD, the number of times of erasure PERC, a layer mode number LYM, and a layer number LYC corresponding to each physical address PAD. The physical address table PADTBL is stored in the random access memory RAM in FIG. 1. When a value of the validity flag PVLD is 1, it is indicated that a corresponding physical address PAD is valid. When the value is 0, it is indicated that a corresponding physical address PAD is invalid. For example, when a physical address assigned to a logical address is changed based on the write physical address table (NXPADTBL), a value of the validity flag PVLD of a physical address PAD assigned after the change becomes 1 and a value of the validity flag PVLD of a physical address PAD assigned before the change becomes 0.

The number of times of erasure PERC indicates the number of times the initial writing (erasure) is performed. Here, for example, when a physical address PAD in which a value of the validity flag PVLD is 0 and the number of times of the initial writing (erasure) is small is preferentially assigned to a logical address, it is possible to perform leveling (wear leveling) of values of the number of times of erasure PERC. Also, in the example in FIG. 7, the information processing circuit MNGER in FIG. 2 recognizes physical addresses PAD of “00000000” to “027FFFFF” as a first physical address area PRNG1 and physical addresses PAD of “02800000” to “07FFFFFF” as a second physical address area PRNG2 and manages the physical address table PADTBL. Also, although it is not specifically limited, the physical address PAD (PAD [31:0]) includes a physical segment address SGAD (PAD [31:16]) and a physical offset address PPAD (PAD [15:0]) for each segment.

Also, when the layer mode number LYM is “0,” it is indicated that writing is performed on all phase-change memory cells CL0 to CLn in the chain memory array CY (that is, it is indicated that mode is second operation mode). Also, when the layer mode number LYM is “1,” it is indicated that writing is performed on one phase-change memory cell in the chain memory array CY (that is, it is indicated that mode is first operation mode).

Also, a value x of a layer number LYC corresponds to a memory-cell selection line LYx in the chain memory array CY illustrated in FIG. 4 and the like. For example, when the layer number LYC is “1,” it is indicated that data corresponding to the physical address PAD is held in a phase-change memory cell CL1 selected by a memory-cell selection line LY1 in the chain memory array CY illustrated in FIG. 4 and the like and is valid.

### <Detail of Physical Segment Table>

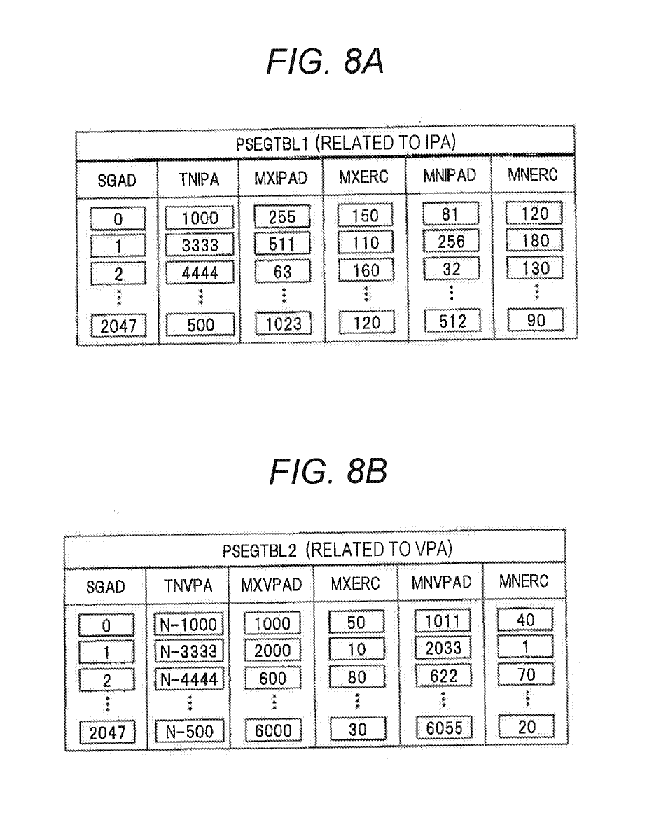

Each of FIG. 8A and FIG. 8B is a view illustrating a configuration example of a physical segment table stored in the random access memory in FIG. 1. FIG. 8A is a view illustrating a physical segment table PSEGTBL1 related to an invalid physical address and FIG. 8B is a view illustrating a physical segment table PSEGTBL2 related to a valid physical address. Although it is not specifically limited, PAD [31:16] in a high order of the physical address PAD (PAD [31:0]) indicates a physical segment address SGAD. Also, although it is not specifically limited, a main data size of one physical address is 512 bytes and a main data size of one segment is 32 MB including 65536 physical addresses.

First, FIG. 8A will be described. The physical segment table PSEGTBL1 includes, for each physical segment address SGAD (PAD [31:16]), the total number of invalid physical addresses TNIPA, the maximum number of times of erasure MXERC and an invalid physical offset address MXIPAD corresponding thereto, and the minimum number of times of erasure MNERC and an invalid physical offset address MNIPAD corresponding thereto. The total number of invalid physical addresses TNIPA is the total number of physical addresses in an invalid state in a corresponding physical segment address SGAD. The maximum number of times of erasure MXERC and the invalid physical offset address MXIPAD thereof, and the minimum number of times of erasure MNERC and the invalid physical offset address MNIPAD thereof are extracted from the physical address in the invalid state. Then, the physical segment table PSEGTBL1 is stored into the random access memory RAM in FIG. 1.

Next, FIG. 8B will be described. The physical segment table PSEGTBL2 includes, for each physical segment address SGAD (PAD [31:16]), the total number of valid physical addresses TNVPA, the maximum number of times of erasure MXERC and a valid physical offset address MXVPAD corresponding thereto, and the minimum number of times of erasure MNERC and a valid physical offset address MNVPAD corresponding thereto. The total number of valid physical addresses TNVPA is the total number of physical addresses in a valid state in a corresponding physical segment address SGAD. The maximum number of times of erasure MXERC and the valid physical offset address MXVPAD thereof, and the minimum number of times of erasure MNERC and the valid physical offset address MNVPAD thereof are extracted from the physical address in the valid state. Then, the physical segment table PSEGTBL2 is stored into the random access memory RAM in FIG. 1. The physical segment tables PSEGTBL1 and PSEGTBL2 are used in a case of performing dynamic wear leveling or static wear leveling described later.

### <Detail of Write Physical Address Table>

Each of FIG. 9A and FIG. 9B is a view illustrating configuration example of a write physical address table stored in the control circuit in FIG. 2 or the random access memory in FIG. 1. FIG. 9A is a view illustrating a state of a write physical address table NXPADTBL in an initial state at time at which utilization of a device is started. FIG. 9B is a view illustrating a state of the write physical address table NXPADTBL after contents are arbitrarily updated. The write physical address table NXPADTBL is a table of determining which physical address is to be preferentially assigned to a logical address when receiving a writing instruction associated with the logical address from the side of the host (CPU_CP in FIG. 1) and writing data into physical addresses of the non-volatile memory devices NVM10 to NVM17.

Here, the write physical address table NXPADTBL has a configuration that can register a plurality (N) of physical addresses. Here, the write physical address tables NXPADTBL (NXPADTBL1 and NXPADTBL2) determine a physical address to be an actual object of writing. A period after a logical address is received and until a physical address is determined by utilization of the table influences writing speed. Thus, information in the write physical address tables NXPADTBL (NXPADTBL1 and NXPADTBL2) is held in the write physical address tables NXPTBL1 and NXPTBL2 in the control circuit MDLCT0 in FIG. 2 and backup thereof is held in the random access memory RAM in FIG. 1.

The write physical address table NXPADTBL includes an entry number ENUM, a write physical address NXPAD, and a validity flag NXPVLD, the number of times of erasure NXPERC, a layer mode number NXLYM, and a write layer number NXLYC corresponding to the write physical address NXPAD. When two logical address areas (LRNG1 and LRNG2) are determined in the SSD configuration information (SDCFG), the control circuit MDLCT0 in FIG. 2 divides the write physical address table NXPADTBL into two according thereto. Here, N/2 entries from entry numbers 0 to (N/2−1) are managed as the write physical address table NXPADTBL1 and the remaining N/2 entries from entry numbers (N/2) to (N−1) are managed as the write physical address table NXPADTBL2. Then, the write physical address table NXPADTBL1 is used with respect to a writing request to the logical address area (LRNG1) and the write physical address table NXPADTBL2 is used with respect to a writing request to the logical address area (LRNG2).

The entry number ENUM indicates N values (zeroth to (N−1)th) in a plurality of (N) pairs of write physical addresses NXPAD. The N values indicate writing priority (the number of registrations). What has a small N value in the write physical address table NXPADTBL1 is preferentially used in ascending order in response to a writing request to the logical address area (LRNG1). What has a small N value in the write physical address table NXPADTBL2 is used preferentially in ascending order in response to a writing request to the logical address area (LRNG2). Also, in a case where a value of the validity flag NXPVLD is 0, it is indicated that a physical address to be an object is invalid. In a case where the value is 1, it is indicated that a physical address to be an object is valid. For example, when a zeroth entry number ENUM is used, a value of a zeroth validity flag NXPVLD becomes 1. Thus, it is possible to determine that the zeroth entry number ENUM is used and the first is to be used in next reference to the table.

Here, with reference to FIG. 9A, initial setting (such as T1 to T3 in FIG. 6A) of the write physical address table NXPADTBL will be described with a case where N=32 as an example.

Also, a physical address area (PRNG1) is set according to the logical address area (LRNG1) and serial write physical addresses NXPAD from an address “00000000” to an address “0000000F” in the physical address area (PRNG1) are respectively registered to entry numbers ENUM=0 to ((32/2)−1). Also, the layer mode number NXLYM is set to “1” and the write layer number NXLYC is set to “0.” Similarly to the layer mode number LYM and the layer number LYC described with reference to FIG. 7, the layer mode number NXLYM and the write layer number NXLYC indicate that a mode is the first operation mode and that a used memory-cell selection line is LY0. Similarly, the physical address area (PRNG2) is set according to the logical address area (LRNG2) and serial write physical addresses NXPAD from an address “02800000” to an address “0280000F” in the physical address area (PRNG2) are respectively registered to entry numbers ENUM=(32/2) to (32−1). Also, the layer mode number NXLYM is set to “0” and the write layer number NXLYC is set to “0.” Similarly to the layer mode number LYM and the layer number LYC described with reference to FIG. 7, it is indicated that a mode is the second operation mode. Then, all validity flags NXPVLD and the number of times of erasure NXPERC corresponding to these write physical addresses NXPAD are set to 0.

Then, in the state illustrated in FIG. 9A, a case where a writing request (WQ) with a sector count (SEC) value being 1 (512 byte) is input into the logical address area (LRNG1) of the memory module (semiconductor device) NVMMD0 for (N/2) times by the information processing device CPU_CP through the interface signal HDH_IF is considered. In this case, data included in each writing request (WQ) is written into places corresponding to serial addresses from an address “00000000” to an address “000000F” in the physical address PAD (NXPAD) in the non-volatile memory device based on FIG. 9A.

Moreover, a case where a writing request (WQ) with a sector count (SEC) value being 1 (512 byte) is input into the logical address area (LRNG2) of the memory module NVMMD0 for (N/2) times by the information processing device CPU_CP through the interface signal HDH_IF is considered. In this case, data included in each writing request (WQ) is written into places corresponding to serial addresses from an address “02800000” to an address “0280000F” in the physical address PAD (NXPAD) in the non-volatile memory device based on FIG. 9A.

Also, a different operation example is as follows. A case where a writing request (WQ) with a sector count (SEC) value being 16 (8 KB) is input into the logical address area (LRNG1) of the memory module NVMMD0 once by the information processing device CPU_CP through the interface signal HDH_IF is considered. In this case, data included in this writing request (WQ) is decomposed into 16 physical addresses PAD having 512 bytes each and is written into serial addresses from an address “00000000” to an “0000000F” in the physical address PAD in the non-volatile memory device.

Also, a case where a writing request (WQ) with a sector count (SEC) value being 16 (8 KB) is input into the logical address area (LRNG2) of the memory module NVMMD0 once by the information processing device CPU_CP through the interface signal HDH_IF is considered. In this case, data included in this writing request (WQ) is decomposed into 16 physical addresses PAD having 512 bytes each and is written into serial addresses from an address “02800000” to an address “0280000F” in the physical address PAD in the non-volatile memory device.

Along with progress in such a writing operation, the write physical address table NXPADTBL is arbitrarily updated. As a result, as illustrated in FIG. 9B, values of the write physical address NXPAD, the number of times of erasure NXPERC, the write layer number NXLYC, and the like are changed arbitrarily. Here, since the values of the write layer number NXLYC in the write physical address table NXPADTBL1 is in the first operation mode described with reference to FIG. 14, the memory-cell selection line LY is serially shifted and the change is made according thereto. On the other hand, since the value of the write layer number NXLYC in the write physical address table NXPADTBL2 is in the second operation mode described with reference to FIG. 14, the change is not made. Note that the update of the write physical address table NXPADTBL can be performed, for example, in a period in which writing is actually performed on the phase-change memory cell in the memory array.

### <Initial Setting of Address Conversion Table and Non-Volatile Memory Device>

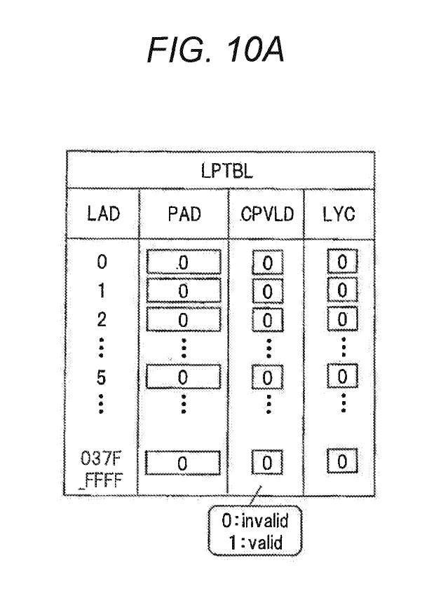

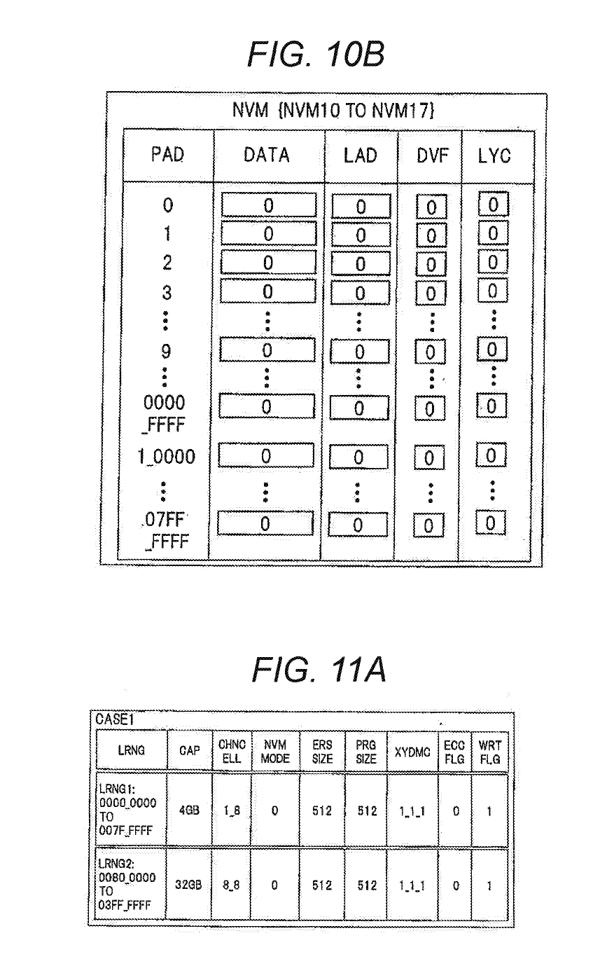

FIG. 10A is a view illustrating a configuration example of an address conversion table stored into the random access memory in FIG. 1 and a state example thereof after initial setting. FIG. 10B is a view illustrating a state example of the non-volatile memory device in FIG. 1 after the initial setting. The initial setting is performed, for example, by the control circuit MDLCT0 in the period of T1 (immediately after power activation) in FIG. 6A.

The address conversion table LPTBL illustrated in FIG. 10A manages, for each logical address LAD, a currently-assigned physical address PAD, a validity flag CPVLD of the physical address, and a layer number LYC of the physical address. After the initial setting, all physical addresses PAD corresponding to all logical addresses LAD are set to 0. The validity flag CPVLD is set to 0 (invalid) and the layer number LYC is set to “0.” Also, as illustrated in FIG. 10B, in the non-volatile memory devices NVM10 to NVM17, data DATA stored in each physical address PAD is set to 0. Also, a logical address LAD and a data validity flag DVF corresponding to each physical address PAD are also set to 0. A layer number LYC corresponding to each physical address PAD is set to “0.” Note that the logical address LAD, the data validity flag DVF, and the layer number LYC are stored, for example, by utilization of a redundant area previously provided in the non-volatile memory device.

### <Detail of SSD Configuration Information>

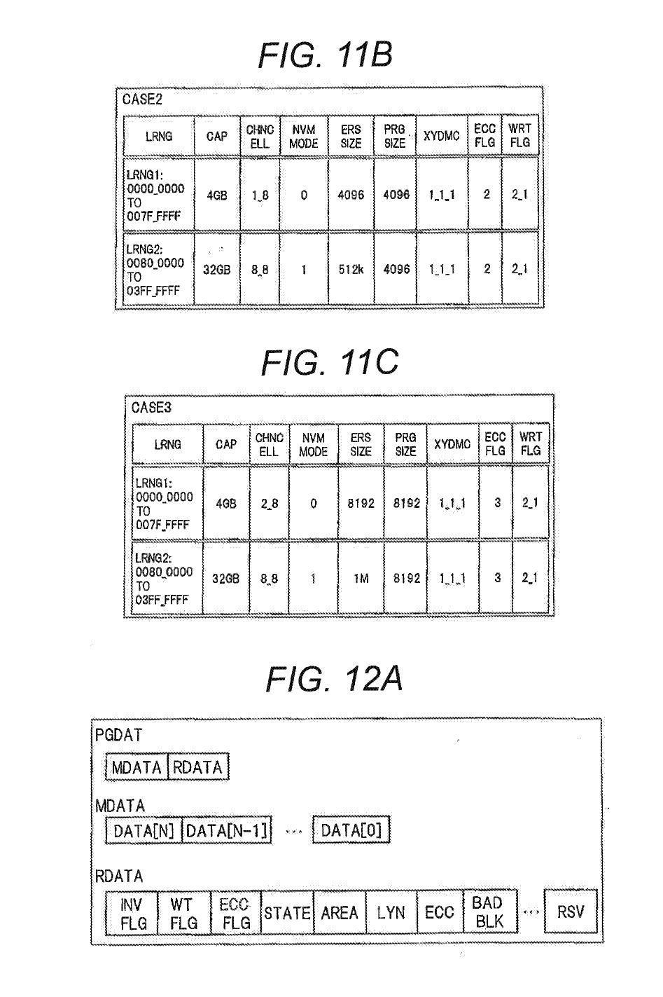

FIG. 11A, FIG. 11B, and FIG. 11C are views illustrating different examples of the SSD configuration information (SDCFG) stored into the non-volatile memory devices NVM10 to NVM17 in FIG. 1. In each drawing, LRNG indicates a logical address area and a range of a logical address LAD in a sector unit (512 byte). The CAP indicates a capacity value of a logical data in a range determined by the logical address area LRNG. For example, the logical address area LRNG1 has a space of logical addresses LAD from “0000_0000” to “007F_FFFF” in a hexadecimal number and has capacity of 4 GB. Also, the logical address area LRNG2 has a space of logical addresses from “0080_0000” to “037F_FFFF” in a hexadecimal number and has a size of 32 GB.

Also, in each drawing, CHNCELL indicates the number of memory cells, into which data is to be written, in all phase-change memory cells CL0 to CLn in the chain memory array CY illustrated in FIG. 3B and the like. For example, as illustrated in FIG. 11A and FIG. 11B, when CHNCELL is “1_8,” writing is performed on “1” of “8” memory cells in the chain memory array CY. When CHNCELL is “8_8,” writing is performed on “8” of the “8” memory cells in the chain memory array CY. Also, for example, as illustrated in FIG. 11C, when CHNCELL is “2_8,” it is indicated that writing is performed on “2” of the “8” memory cells in the chain memory array CY.

Also, in each drawing, in a case where NVMMODE is “0,” it is indicated that it is possible to perform a writing operation while making the minimum erasure data size and the minimum program data size identical when data is written into the non-volatile memory device NVM. In a case where NVMMODE is “1,” it is indicated that a writing operation can be performed on the assumption that the minimum erasure data size and the minimum program data size are different from each other. In each drawing, ERSSIZE indicates the minimum erasure data size [byte] and PRGSIZE indicates the minimum program data size [byte]. In this embodiment, each of the minimum erasure data size and the minimum program data size is expressed in a byte unit.

As illustrated in FIG. 11A, when NVMMODE is set to “0” and the minimum erasure data size (ERSSIZE) and the minimum program data size (PRGSIZE) are made to be an identical size such as 512 bytes, a so-called garbage collection operation becomes unnecessary and a writing operation can be performed at high speed.

Also, as indicated by LRNG2 in FIG. 11B, by setting NVMMODE to “1” and by setting a block erasure size to 512 KB and a page size to 4 KB according to a specification of a NAND-type flash memory, it is possible to correspond to a writing operation on a conventional NAND-type flash memory. Moreover, as indicated by LRNG2 in FIG. 11C, it is possible to set NVMMODE to “1” and to set the block erasure size to 1 MB and the page size to 8 KB according to a specification of a different NAND-type flash memory.

In such a manner, with the SSD configuration information, it is possible to change a specification of a used non-volatile memory device and to flexibly correspond to various specifications. Moreover, since it is possible to reduce the number of dummy chain memory arrays DCY (described later) arranged in X and Y directions of an erasure area by increasing the block erasure size, it is possible to realize large capacity.

In FIG. 11A, FIG. 11B, and FIG. 11C, XYDMC indicates the number of dummy chain memory arrays DCY arranged in X and Y directions on an outer side or inner side of a write area including an erasure area having an erasure data size designated by ERSSIZE. Here, the write area is an area where a plurality of chain memory arrays CY is physically collected. Dummy chain memory array designation information XYDMC that designates a dummy chain memory array DCY has three kinds of information. That is, in a case where a value on a left side (left side in the drawing) of XYDMC is “1,” it is indicated that the write area is identical to the erasure area and is an area where a plurality of chain memory arrays CY is physically collected. It is also indicated that the dummy chain memory array DCY is arranged in the X and Y directions on the outer side of the write area. In a case where a value on the left side is “0,” it is indicated that an area which is the write area except for the dummy chain memory array DCY becomes the erasure area and that the dummy chain memory array DCY is arranged in the X and Y directions on the inner side of the write area. Also, the erasure area is an area where a plurality of chain memory arrays CY is physically collected.

A value in the middle (middle in the drawing) of the dummy chain memory array designation information XYDMC indicates the number of dummy chain memory arrays DCY arranged in the X direction of the write area. Also, a value on a right side (right side in the drawing) of the dummy chain memory array designation information XYDMC indicates the number of dummy chain memory arrays DCY arranged in the Y direction of the write area.

An example of the dummy chain memory array designation information XYDMC is as follows. That is, when the dummy chain memory array designation information XYDMC is “1_1_1,” it is indicated that one dummy chain memory array DCY is arranged in the X and Y directions on the outer side of the write area (=erasure area). When the dummy chain memory array designation information XYDMC is “0_1_1,” it is indicated that one dummy chain memory array DCY is arranged in the X and Y directions on the inner side of the write area. When the dummy chain memory array designation information XYDMC is “1_2_2,” it is indicated that two dummy chain memory arrays DCY are arranged in the X and Y directions on the outer side of the write area. Also, when the dummy chain memory array designation information XYDMC is “0_2_2,” it is indicated that two dummy chain memory arrays DCY are arranged in the X and Y directions on the inner side of the write area.

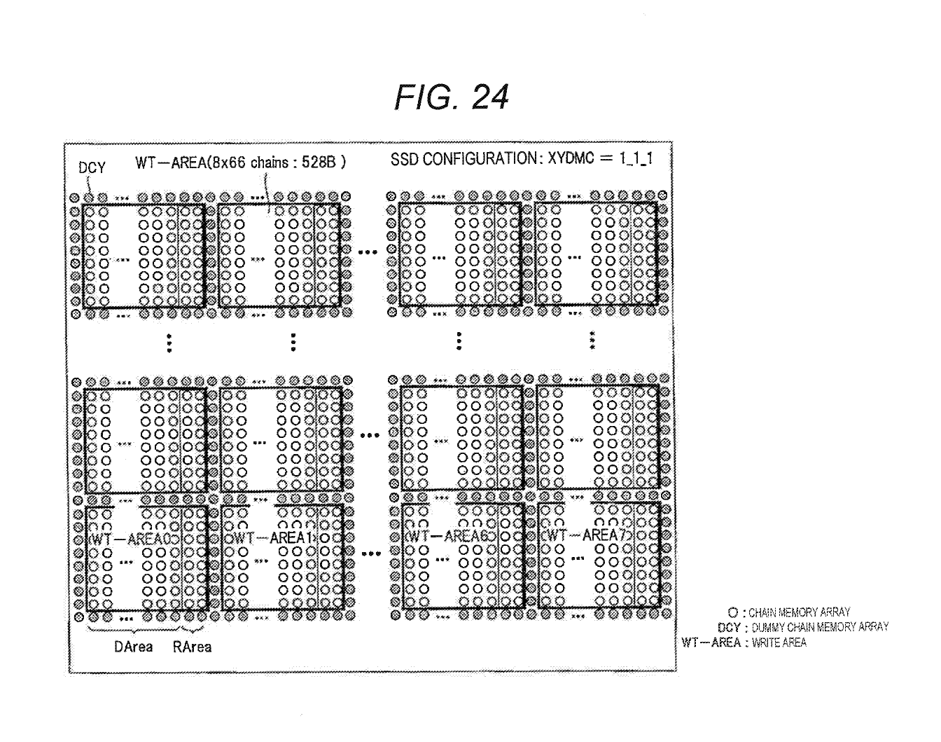

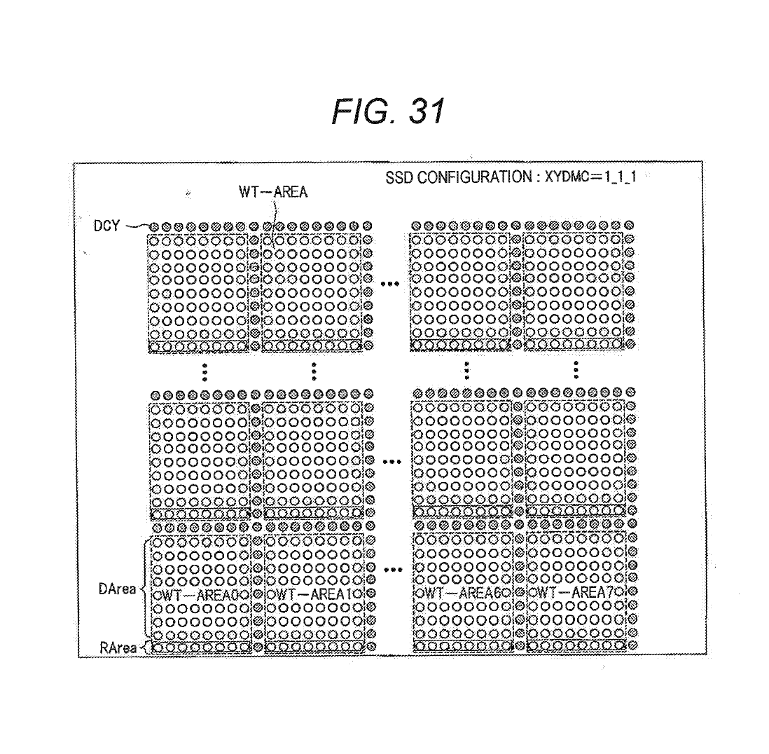

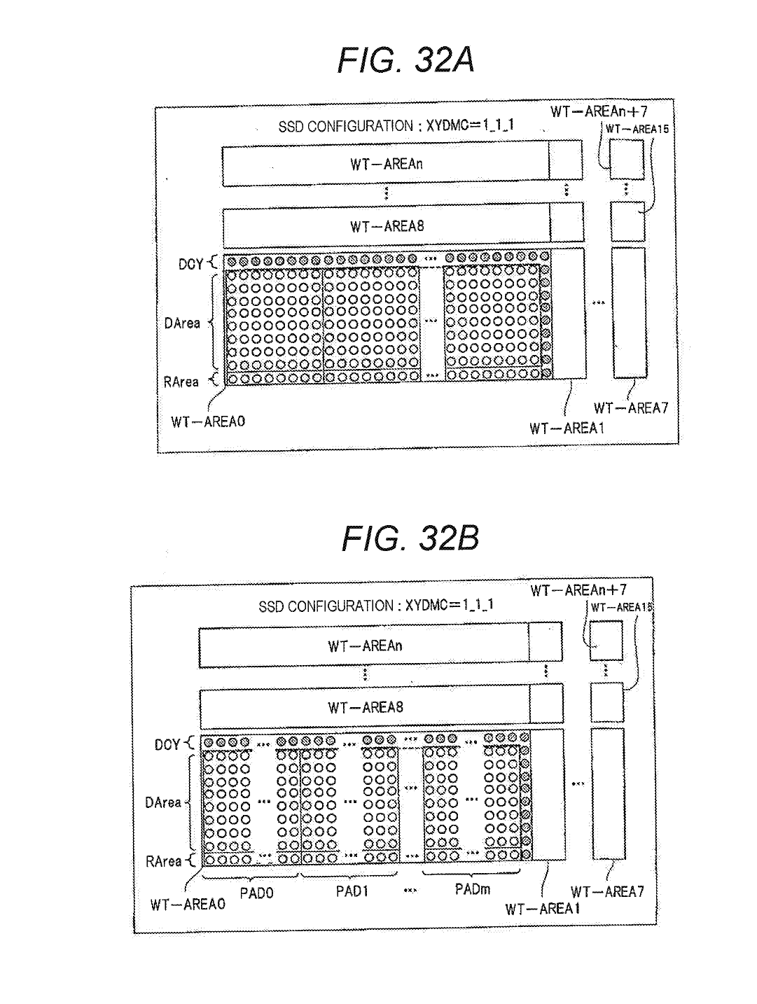

As it will be described later, in each of FIG. 24, FIG. 31, FIG. 32A, and FIG. 32B, an example of an arrangement of a dummy chain memory array DCY and a chain memory array CY of one memory array ARY in a non-volatile memory device in a case where the dummy chain memory array designation information XYDMC is “1_1_1” in FIG. 11A is illustrated. In these drawings, a chain memory array CY is indicated by a blank ∘-shape and a dummy chain memory array DCY is indicated by a ∘-shape filled with dots. In the following drawings, the chain memory array and the dummy chain memory array are displayed in a similar manner.

Since the dummy chain memory array designation information XYDMC is “1_1_1,” one dummy chain memory array is arranged in each of the X direction and the Y direction on the outer side of the write area (=erasure area) in each of FIG. 24, FIG. 31, FIG. 32A, and FIG. 32B. Also, in this case, data of all memory cells in all chain memory arrays CY in the write area (=erasure area) is set to “1” (Set state). Thus, batch-erasure is performed and only data of “0” (Reset state) is subsequently written into each physical address PAD.

For example, with reference to FIG. 24 as an example, the erasure area includes a plurality of chain memory arrays CY (blank ∘) physically adjacent to each other. One dummy chain memory array DCY (∘ filled with dot) is arranged in each of the X direction and the Y direction on the outer side of the erasure area in a manner adjacent to the erasure area. In a plan view, those are recognized as a matrix (write area=erasure area), which includes a plurality of chain memory arrays CY, one dummy chain memory array row that is on the outer side thereof and is extended in an X direction of the matrix in a manner adjacent to the matrix, and one dummy chain memory array column that is extended in the Y direction thereof. When recognition is made in such a manner, each of the dummy chain memory array row and the dummy chain memory array column includes a plurality of dummy chain memory arrays DCY.

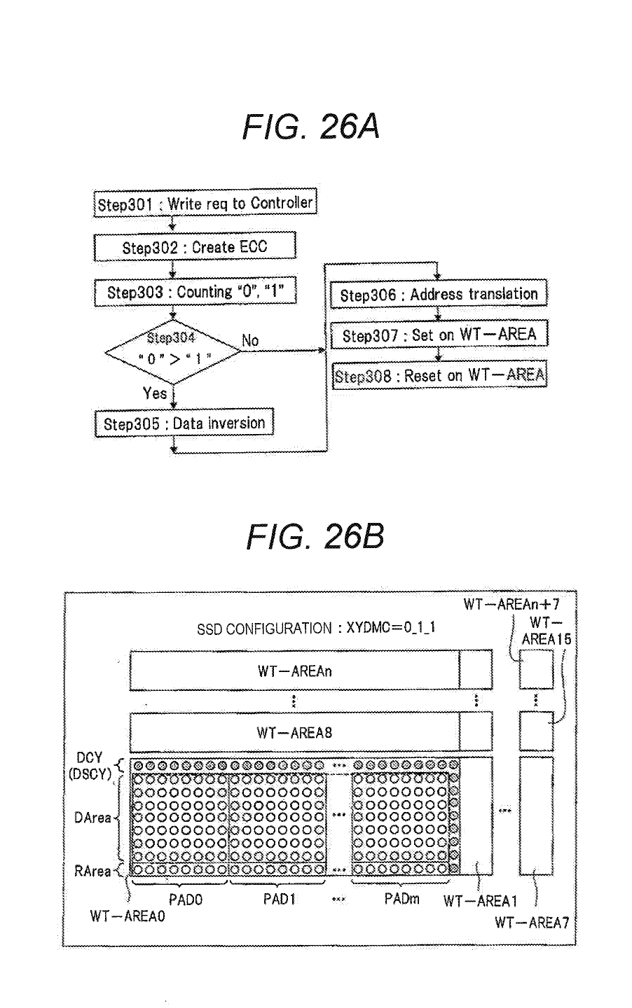

Also, as it will be described later, in FIG. 26B, an example of an arrangement of a dummy chain memory array DCY (∘ filled with dot) and a chain memory array CY (blank ∘) in one memory array ARY in the non-volatile memory device in a case where XYDMC in FIG. 11A is “0_1_1” is illustrated. In this case, the write area includes an erasure area where the dummy chain memory array DCY and the chain memory array CY are physically collected. On an inner side of the write area, the dummy chain memory array DCY is arranged.

In a plan view, these are recognized as one dummy chain memory array DCY row and one dummy chain memory array DCY column that are arranged on the inner side of the write area. Also, data of all memory cells included in all chain memory arrays CY in the erasure area including the plurality of chain memory arrays CY arranged in the matrix becomes “1” (Set state). That is, batch-erasure is performed. Then, only data of “0” (Reset state) is written into each physical address PAD.

For example, in a case of performing an operation of batch-erasure on such a write area, an erasing operation is not performed on the dummy chain memory array DCY arranged on the outer side or the inner side of the write area.

Also, for example, in a case of performing an operation of batch-erasure on such an erasure area, an erasing operation is not performed with respect to the dummy chain memory array DCY arranged on the outer side of the erasure area.

In a case where one memory cell in the X and/or Y direction in a periphery of the erasure area is influenced by a decrease in reliability due to heat disturbance of when the erasing operation is performed on a batch-erasure area in the memory array ARY, the dummy chain memory array designation information XYDMC is set to “1_1_1” or “0_1_1.” Accordingly, one chain memory array CY is arranged as the dummy chain memory array DCY in a periphery of the batch-erasure area. Since the dummy chain memory array DCY is not an object of the erasing operation, it is possible to prevent a decrease in reliability due to heat disturbance.

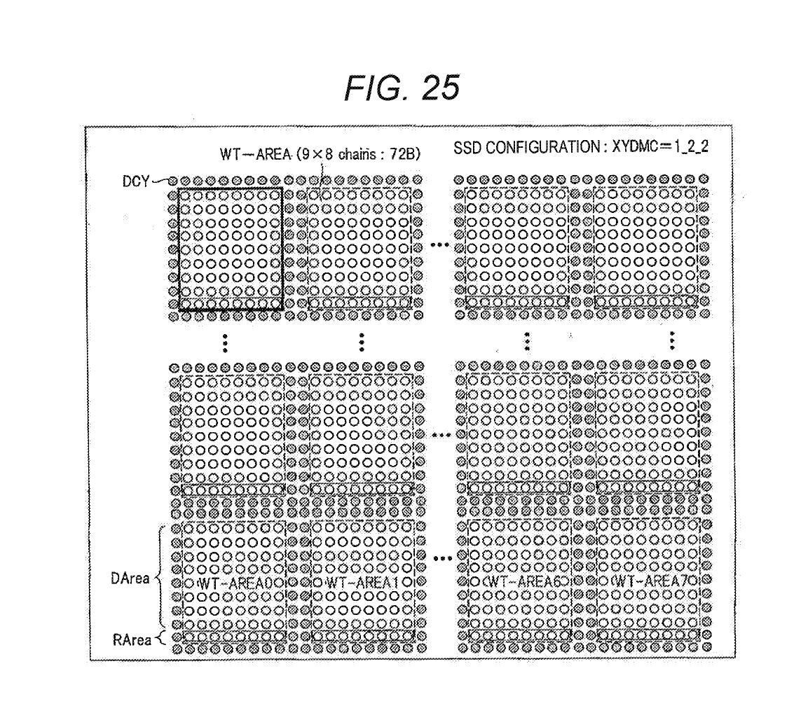

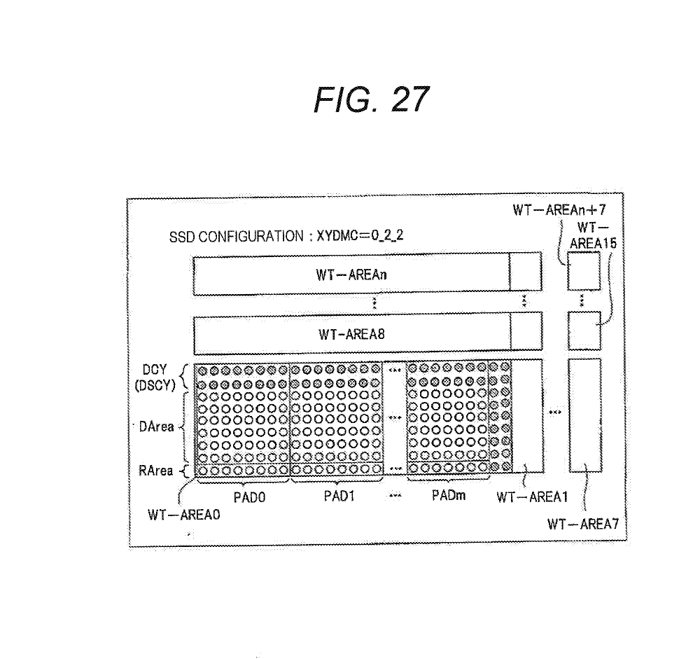

As it will be described later, in FIG. 25, an example of an arrangement of a dummy chain memory array DCY and a chain memory array CY in one memory array ARY in the non-volatile memory device in a case were the dummy chain memory array designation information XYDMC in FIG. 11A is “1_2_2” is illustrated. Also, in FIG. 27, an example of an arrangement of a dummy chain memory array DCY and a chain memory array CY in one memory array ARY in the non-volatile memory device in a case where the dummy chain memory array designation information XYDMC in FIG. 11A is “0_2_2” is illustrated. In FIG. 25 and FIG. 27, two dummy chain memory arrays DCY are arranged in the X direction and the Y direction in the write area on the outer side or the inner side of the write area. That is, two dummy chain memory array DCY rows and two dummy chain memory array DCY columns are arranged in a manner adjacent to the erasure area.

In a case where two memory cells in the X and Y directions in a periphery of the erasure area is influenced by a decrease in reliability due to heat disturbance of when the erasing operation is performed on the batch-erasure area in the memory array ARY, the dummy chain memory array designation information XYDMC is set to “1_2_2” or “0_2_2.” In such a manner, it is possible to arrange two chain memory arrays CY as the dummy chain memory arrays DCY in the periphery of the batch-erasure area and to prevent a decrease in reliability due to the heat disturbance.

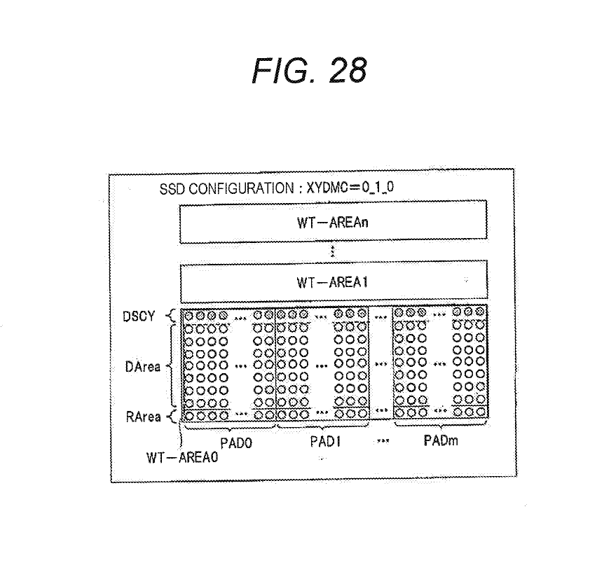

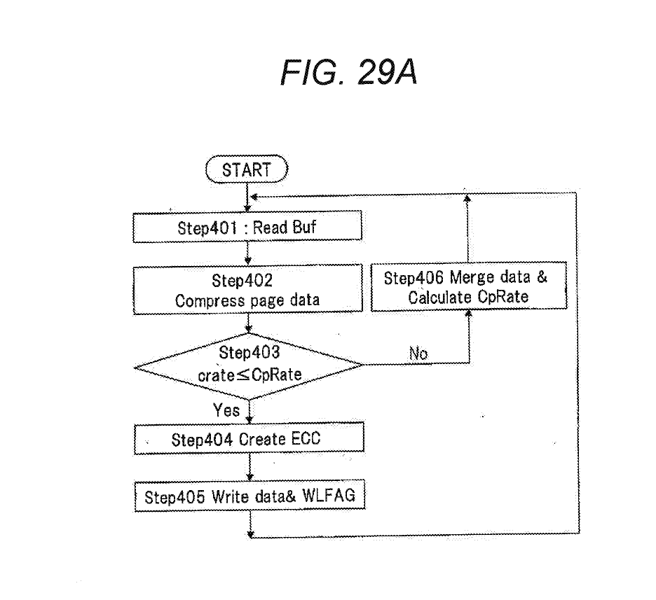

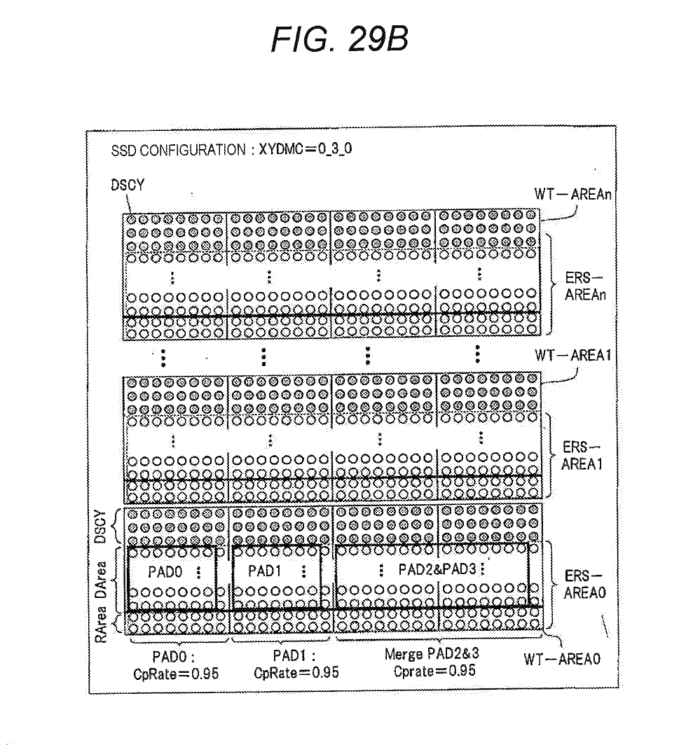

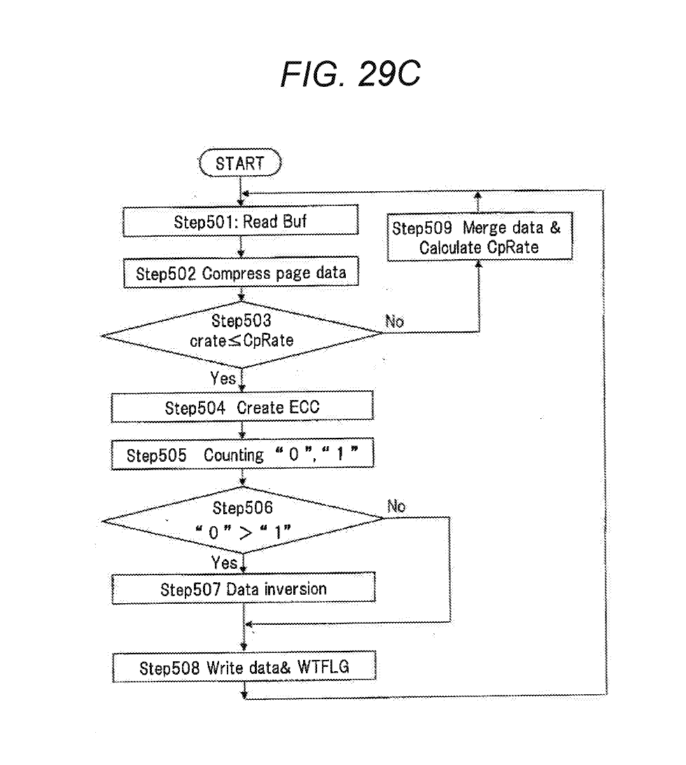

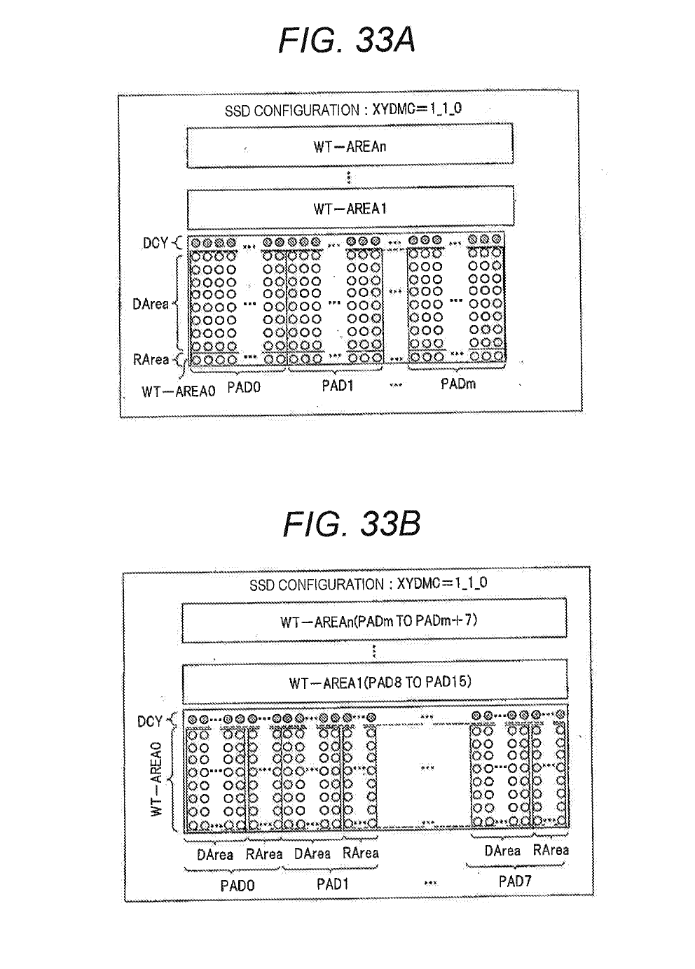

In each of FIG. 33A and FIG. 33B, an example of an arrangement of a dummy chain memory array DCY and a chain memory array CY in one memory array ARY in the non-volatile memory device in a case were the dummy chain memory array designation information XYDMC in FIG. 11A is “1_1_0” is illustrated. Also, in each of FIG. 28 and FIG. 29B, an example of arrangement of a dummy chain memory array DCY and a chain memory array CY in one memory array ARY in the non-volatile memory device in a case where the dummy chain memory array designation information XYDMC in FIG. 11A is “0_1_0” is illustrated. When the dummy chain memory array designation information XYDMC is set in such a manner, one dummy chain memory array DCY row is arranged on an outer side in an X direction of an erasure area where the batch-erasure is performed. Obviously, it is possible to arrange one dummy chain memory array DCY column on the outer side of the erasure area by setting the dummy chain memory array designation information XYDMC to “1_0_1” or “0_0_1.”

In a case where one memory cell in an X direction (Y direction) in a periphery of an erasure area is influenced by a decrease in reliability due to heat disturbance of when an erasing operation is performed on a batch-erasure area in the memory array ARY, the dummy chain memory array designation information XYDMC is set to “1_1_0” or “0_1_0” (“1_0_1” or “0_0_1”). Accordingly, it is possible to prevent a decrease in reliability due to heat disturbance by arranging one chain memory array CY as the dummy chain memory array DCY in the periphery of the batch-erasure area.

In such a manner, it is possible to flexibly change an arrangement of the dummy chain memory array DCY according to a degree of an influence of heat disturbance on a peripheral memory cell in a case where the erasing operation is performed on a memory cell and to realize high reliability of the memory module (semiconductor device) NVMMD0.

FIG. 11A, FIG. 11B, and FIG. 11C will be described again. In these drawings, ECCFLG indicates a unit of data in a case of performing error check and correct (ECC). Although it is not specifically limited, ECC is performed in a unit of 512-byte data when the ECCFLG is 0. ECC is performed in a unit of 2048-byte data when ECCFLG is 1. Similarly, when ECCFLG is 2, 3, and 4, the ECC is performed in a unit of 4096-byte data, 8192-byte data, and 16384-byte data. Also, when ECCFLG is 5, 6, 7, and 8, the ECC is performed in a unit of 32-byte data, 64-byte data, 128-byte data, and 256-byte data.

Since there are various kinds of storage devices such as a hard disk, an SSD, a cache memory, and a main memory, a unit of reading or writing data is different. For example, in storage such as a hard disk or an SSD, reading or writing is performed in a data unit equal to or larger than 512 bytes. Also, a cache memory reads/writes data from/to a main memory in a line size unit (such as 32 byte or 64 byte). Even when a data unit is different in such a manner, it is possible to perform ECC in a different data unit according to ECCFLG and to flexibly correspond to a request with respect to the memory module (semiconductor device) NVMMD0.

Also, in FIG. 11A to FIG. 11C, WRTFLG is writing method selection information and indicates a writing method during writing. Although it is not specifically limited, when the writing method selection information WRTFLG is 0, write data WDATA input into the memory module (semiconductor device) NVMMD0 and an ECC code ECC generated from the write data WDATA are written into the non-volatile memory without processing.

When WRTFLG is 1, the writing method is as follows. That is, the number of pieces of bit data “0” and the number of pieces of bit data “1” are counted and the number of pieces of bit data “0” and the number of pieces of bit data “1” are compared with each other in the write data WDATA and data of the ECC code ECC generated from the write data WDATA. When the number of pieces of i bit data “0” is larger than the number of pieces of bit data “1,” the information processing circuit MNGER inverts each bit of the write data WDATA and writes the data into the non-volatile memory. On the other hand, when the number of pieces of bit data “0” is not larger than the number of pieces of bit data “1,” the information processing circuit MNGER writes the write data (DATA0) into the non-volatile memory without inverting each bit of the data. Accordingly, the number of pieces of bit data “0” in the write data constantly becomes equal to or smaller than ½. Thus, it is possible to reduce an amount of written bit data “0” by half and to performing writing with low power at high speed.

When the writing method selection information WRTFLG is 2, a writing method is as follows. That is, compressed data CompDATA that is generated by compression of the write data WDATA and the ECC code ECC generated from the write data WDATA is generated and the compressed data CompDATA is written into the non-volatile memory. By the compression, a write size of the compressed data CompDATA becomes smaller than the sum of a write size of the write data WDATA and a write size of the ECC code ECC generated from the write data WDATA. Thus, it is possible to effectively increase capacity of the memory module (semiconductor device) NVMMD0.

As a compressing method of generating the compressed data, there are a run-length code, an LZ code, and the like. A compressing method is selected according to a kind of used data.

A writing method in a case where the writing method selection information WRTFLG is 3 will be described in the following. The writing method in this case is a method of converting the write data WDATA into write data RdcDATA, in which the maximum number of pieces of bit data “0” is limited, and of writing the data into the non-volatile memory. Next, an example of a writing method in a case of writing write data in 32 bits while limiting the maximum number of pieces of written bit data “0” to 8 bits in the write data will be described.

The total number possible combinations T and the total number of pieces of written “0” R in a case where the maximum number of pieces of written bit data “0” is limited to r bits in write data of t bits can be expressed by an expression (1) and an expression (2).

$$\begin{matrix}[ Math 1 ] & \\ T = {\sum }_{r = 0}^{r} {}_{t}^{}{C}{}_{r}^{} & ( 1 ) \\ [ Math 2 ] & \\ R = {\sum }_{r = 0}^{r} r \times {}_{t}^{}{C}{}_{r}^{} & ( 2 )\end{matrix}$$

When t=32 and r=8 are assigned to the expressions (1) and (2), T=15033173 and R=114311168. Also, an average number of times of writing “0” bit becomes Ravg=R/T=7.60. Here, when the number of necessary bits in a case where T is expressed by a binary number is I, I=log₂ (T)=log 2 (15033173)=23.84.

That is, even in a case where the maximum number of pieces of written bit data “0” is limited to 8 bits, which is ¼ of 32 bits, of write data of 32 bits, it is possible to distinguish data in 15033173 combinations.

In such a manner, it is possible to reduce the number of bits, to which “0” is written, and to realize writing at high speed by a writing method of limiting the maximum number of pieces of bit data “0.”

The writing methods of when the writing method selection information WRTFLG is 1 to 3 have been described. It is possible to set a writing method by combination of these methods. In each of FIG. 11B and FIG. 11C, an example of a combination is illustrated. That is, in these drawings, examples in which 1 and 2 of the writing method selection information WRTFLG are combined are illustrated. In these drawings, the writing method selection information WRTFLG is “2_1.”

When the writing method selection information WRTFLG is “2_1,” data is generated first by a method set by “2” of the writing method selection information WRTFLG. Then, with respect to the data generated first, data is generated and written into the non-volatile memory by a method set by “1” of the writing method selection information WRTFLG.

As an example of detail processing, a case where the writing method selection information WRTFLG is “2_1” will be described in the following. First, compressed data CompDATA is generated by compression of the write data WDATA input into the memory module (semiconductor device) NVMMD0 and the ECC code ECC generated from the write data WDATA. Then the number of pieces of bit data “0” and the number of pieces of bit data “1” in the compressed data CompDATA are counted and the number of pieces bit data “0” and the number of pieces of bit data “1” are compared with each other. When the number of pieces of bit data “0” is larger than the number of pieces of bit data “1,” the information processing circuit MNGER inverts each bit of the compressed data CompDATA and writes the data into the non-volatile memory. On the other hand, when the number of pieces of bit data “0” is smaller than the number of pieces of bit data “1,” the compressed data CompDATA is written into the non-volatile memory without inversion of each bit of the data.

Also, for example, when the writing method selection information WRTFLG is “3_2,” data is generated first by a method set by “3” of the writing method selection information WRTFLG. Then, with respect to the data generated first, data is generated and written into the non-volatile memory by a method set by “2” of the writing method selection information WRTFLG.

In this case, specifically, when the write data WDATA that is input into the memory module (semiconductor device) NVMMD0 is 512 bytes, conversion into data RdsData of when the maximum number of pieces of written bit data “0” is limited to 128 bytes is performed. Then, compressed data CompRsdDATA is generated by compression of the data RdsData and an ECC code ECC, which is generated from the data RdsData, and written into the non-volatile memory.

In such a manner, the SSD configuration information (SDCFG) can be programmed arbitrarily. Thus, it is possible to flexibly correspond to levels of a function, performance, and reliability requested to the memory module (semiconductor device) NVMMD0.

### <Configuration Example of Write Data>

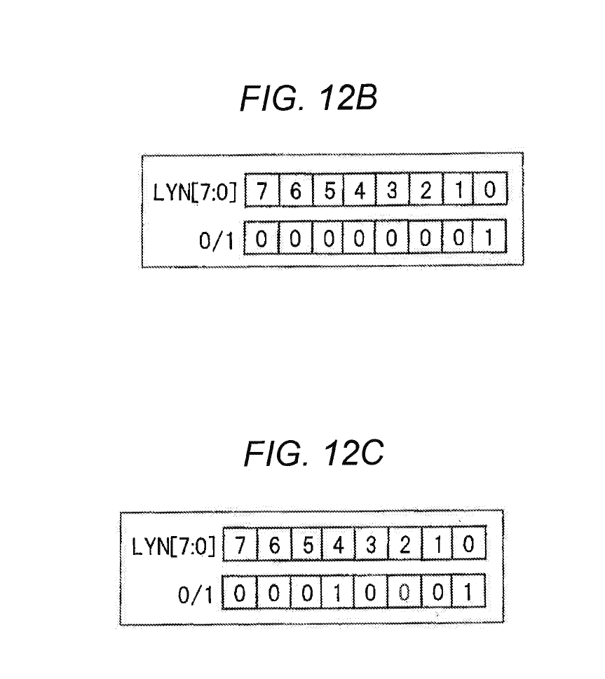

FIG. 12A is a view illustrating a configuration example of data written by the control circuit MDLCT0 into the non-volatile memory devices NVM10 to NVM17 in the memory module NVMMD0 in FIG. 1. FIG. 12B and FIG. 12C are views illustrating configuration examples of the data write layer information in FIG. 12A. In FIG. 12A, write data (page data) PGDAT includes main data MDATA (512 byte) and redundant data RDATA (16 byte) although it is not specifically limited. The main data MDATA is write data WDATA input by the information processing device (processor) CPU_CP in FIG. 1 into the memory module NVMMD0. Redundant data RDATA corresponding to the write data WDATA is data generated by the control circuit MDLCT0 in FIG. 1. The redundant data RDATA includes a data inversion flag INVFLG, a writing flag WTFLG, an ECC flag ECCFLG, state information STATE, area information AREA, data write layer information LYN, an ECC code ECC, bad block information BADBLK, and a preliminary area RSV.

The data inversion flag INVFLG indicates whether the main data MDATA written by the control circuit MDLCT0 into the non-volatile memory devices NVM10 to NVM17 is data that is generated by inversion of each bit of original write data. When 0 is written into the data inversion flag INVFLG, it is indicated that data is written without inversion of each bit of the original main data. When 1 is written, it is indicated that data generated by inversion of each bit of the original main data is written.

The writing flag WTFLG indicates a writing method executed in a case where the control circuit MDLCT0 writes the main data MDATA into the non-volatile memory devices NVM10 to NVM17. That is, the writing flag WTFLG corresponds to the writing method selection information WRTFLG described with reference to FIG. 11A to FIG. 11C. Thus, although it is not specifically limited, it is indicated that the main data MDATA is written by a normal method when 0 is written into WTFLG (WTFLG0) and it is indicated that data generated by inversion of each bit of original main data is written when 1 is written into WTFLG (WTFLG1). When 2 is written into WTFLG (WTFLG 2), it is indicated that original data is compressed and the compressed data is written. When 3 is written into WTFLG (WTFLG 3), it is indicated that original data is coded and the coded data is written. Also, when 2_1 is written into WTFLG (WTFLG2_1), it is indicated that original data is compressed, each bit of the compressed data is inverted, and the inverted data is written. Moreover, when 3_2 is written into WTFLG (WTFLG3_2), original data is coded and compressed and the compressed data is written.

The ECC flag ECCFLG indicates a size of the main data MDATA to which an ECC code is generated when the control circuit MDLCT0 writes the main data MDATA into the non-volatile memory devices NVM10 to NVM17. Although it is not specifically limited, it is indicated that a code is generated with respect to a data size of 512 bytes when 0 is written into ECCFLG and it is indicated that a code is generated with respect to a data size of 1024 bytes when 1 is written into ECCFLG. When 2 is written into ECCFLG, it is indicated that a code is generated with respect to a data size of 2048 bytes and it is indicated that a code is generated with respect to a data size of 32 bytes when 3 is written into ECCFLG.

The ECC code ECC is data necessary for detecting and correcting an error of the main data MDATA. ECC is generated by the control circuit MDLCT0 according to the main data MDATA and written into the redundant data RDATA when the control circuit MDLCT0 writes the main data MDATA into the non-volatile memory devices NVM10 to NVM17. The state information STATE indicates whether the main data MDATA written into the non-volatile memory devices NVM10 to NVM17 is in a valid state, an invalid state, or an erased state. Although it is not specifically limited, when 0 is written into the state information STATE, it is indicated that the main data MDATA is in the invalid state. Also, it is indicated that the main data MDATA is in the valid state when 1 is written into the state information STATE and it is indicated that the main data MDATA is in the erased state when 3 is written into the state information STATE.

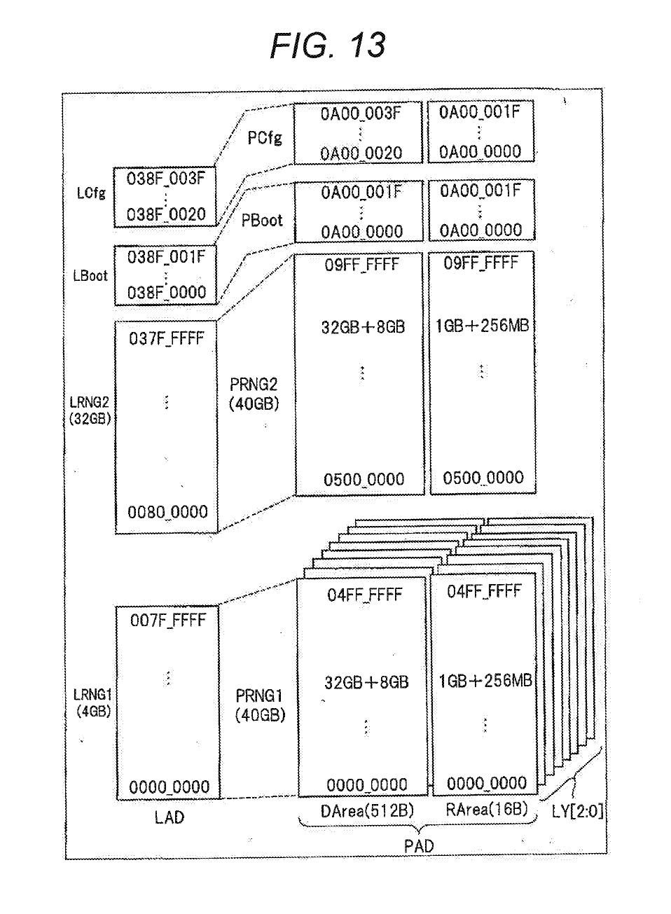

The area information AREA is information indicating whether data, into which the main data MDATA is written, is written into the first physical address area PRNG1 or the second physical address area PRNG2 in an address map range (ADMAP) illustrated in FIG. 13 (described later). Although it is not specifically limited, it is indicated that the main data MDATA is written into the first physical address area PRNG1 when a value of the area information AREA is 1 and it is indicated that the main data MDATA is written into the second physical address area PRNG2 when a value of the area information AREA is 2.

Also, in FIG. 12B and FIG. 12C, data write layer information LYN [n:0] is information indicating data of which memory cell is written in the valid state among phase-change memory cells CL0 to CLn in a chain memory array CY. In initial setting, LYN [n:0] is set to 0. In this example, a case where eight phase-change memory cells CL0 to CL7 are included in the chain memory array CY is illustrated.

The data write layer information LYN includes 8 bits of LYN [7:0]. LYN [7] to LYN [0] respectively correspond to the phase-change memory cells CL7 to CL0. For example, when valid data is written into the phase-change memory cell CL0, “1” is written into LYN [0] and “0” is written into the others. Also, for example, when valid data is written into the phase-change memory cell CL1, “1” is written into LYN [1] and “0” is written into the others. Relationships between the phase-change memory cells CL2 to CL7 and LYN [2] to LYN [7] are in a similar manner.

In an example of FIG. 12B, “1” is written into LYN [0] and “0” is written into LYN [7:1]. Thus, it is indicated that valid data is written into the phase-change memory cell CL0 in the chain memory array CY. In an example of FIG. 12C, “1” is written into LYN [0] and LYN [4] and “0” is written into LYN [7:5] and LYN [3:1]. Thus, it is indicated that valid data is written into the phase-change memory cells CL0 and CL 4 in the chain memory array CY.

In FIG. 12A, the bad block information BADBLK indicates whether the main data MDATA written into the non-volatile memory devices NVM10 to NVM17 can be used. Although it is not specifically limited, it is indicated that the main data MDATA can be used when 0 is written into the bad block information BADBLK and it is indicated that the main data MDATA cannot be used when 1 is written. For example, when it is possible to perform error correction by ECC, the bad block information BADBLK becomes 0. When it is not possible to perform error correction, the bad block information BADBLK becomes 1. The preliminary area RSV is an area where definition can be freely made by the control circuit MDLCT0.

### <Detail of Address Map Range>

FIG. 13 is a view illustrating an example of the address map range (ADMAP) stored in the random access memory in FIG. 1. As described with reference to FIG. 6A and the like, the address map range (ADMAP) is generated, for example, by utilization of the SSD configuration information (SDCFG), which is stored in NVM10 to NVM17 and is illustrated in FIG. 11A, and is stored into the random access memory RAM by the control circuit MDLCT0.

### <Writing Operation Flow of Memory Module (Semiconductor Device)>

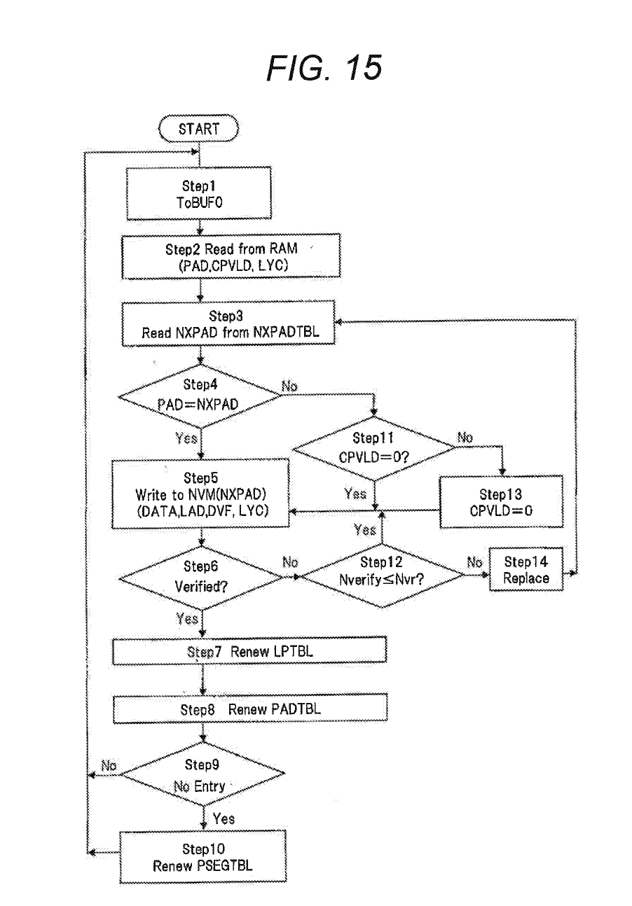

FIG. 15 is a flowchart illustrating an example of a detail writing processing procedure performed in the memory module NVMMD0 when a writing request (WREQ01) is input into the memory module NVMMD0 by the information processing device CPU_CP in FIG. 1. Here, processing contents of the information processing circuit MNGER in FIG. 2 is mainly illustrated. Although it is not specifically limited, the information processing circuit MNGER associates one physical address to each size of 512-byte main data MDATA and 16-byte redundant data RDATA and performs writing into the non-volatile memory devices NVM10 to NVM17.

First, a writing request (WQ01) including a logical address value (such as LAD=0), a data writing instruction (WRT), a sector count value (such as SEC=1), and 512-byte write data (WDATA0) is input into the control circuit MDLCT0 by the information processing device CPU_CP. The interface circuit HOST_IF in FIG. 2 extracts clock information embedded in the writing request (WQ01), converts writing request (WQ01), which is converted into serial data, into parallel data, and performs transfer to a buffer BUF0 and the information processing circuit MNGER (Step 1).

Next, the information processing circuit MNGER decodes the logical address value (LAD=0), the data writing instruction (WRT), and the sector count value (SEC=1) and searches an address conversion table LPTBL (FIG. 10A) in the random access memory RAM. Accordingly, the information processing circuit MNGER reads a current physical address value (such as PAD=0) stored at an address of the logical address value (LAD=0), and a value of a validity flag CPVLD and a layer number LYC corresponding to the physical address value (PAD=0). Moreover, the information processing circuit MNGER reads a value of the number of times of erasure (such as PERC=400) and a value of a validity flag PVLD corresponding to the physical address value (PAD=0) from the physical address table PADTBL (FIG. 7) in the random access memory RAM (Step 2).

Next, the information processing circuit MNGER uses the address map range (ADMAP) (FIG. 13) stored in the random access memory RAM and determines whether the logical address value (LAD=0) input into the control circuit MDLCT0 by the information processing device CPU_CP is a logical address value in the logical address area LRNG1 or a logical address value in the logical address area LRNG2.

Here, in the information processing circuit MNGER, when the logical address value (LAD=0) is the logical address value in the logical address area LRNG1, the write physical address table NXPADTBL1 in FIG. 9A and FIG. 9B is referred to. When the logical address value (LAD=0) is the logical address value in the logical address area LRNG2, the write physical address table NXPADTBL2 is referred to. Note that as described above, actually, the table is stored in the write physical address tables NXPTBL1 and NXPTBL2 in FIG. 2. The information processing circuit MNGER reads necessary data, the number of pieces of which is designated by a sector count value (SEC=1), in order of writing priority (that is, ascending order in entry number ENUM) from one of the write physical address tables. In this case, one write physical address (such as NXPAD=100), a value of a validity flag NXPVLD corresponding to the write physical address (NXPAD=100), a value of the number of times of erasure NXPERC, and a write layer number NXLYC are read (Step 3).

Next, the information processing circuit MNGER determines whether the current physical address value (PAD=0) and a write physical address value to be a next object of writing (NXPAD=100) are identical (Step 4). When the two are identical, Step 5 is executed. When the two are different, Step 11 is executed. In Step 5, the information processing circuit MNGER writes various kinds of data into addresses corresponding to the physical address value (NXPAD=100) in the non-volatile memory devices NVM10 to NVM17. Here, write data (WDATA0) is written as the main data MDATA illustrated in FIG. 12A. A data inversion flag INVFLG, a writing flag WTFLG, an ECC flag ECCFLG, state information STATE, data write layer information LYN, and an ECC code ECC are written as the redundant data RDATA. In addition, as illustrated in FIG. 10B, a logical address value (LAD=0), a validity flag value (DVF=1), and a layer number LYC corresponding to the physical address value (NXPAD=100) are written.

Here, for example, when a write layer number NXLYC read from the write physical address table NXPADTBL1 is “10,” the main data MDATA (write data (WDATA0)) and the redundant data RDATA are written into one phase-change memory cell CL0 in each chain memory array CY. Along with this, “0” is written into the data write layer information LYN [7:1] in the redundant data RDATA in FIG. 12A and “1” is written into the data write layer information LYN [0]. On the other hand, for example, when a write layer number NXLYC read from the write physical address table NXPADTBL2 is “00,” the main data MDATA (write data (WDATA0)) and the redundant data RDATA are written into all phase-change memory cells CL0 to CLn in each chain memory array CY. Also, “1” is written into the data write layer information LYN [7:0] in the redundant data RDATA.

In FIG. 15, in Step 11, the information processing circuit MNGER determines whether a value of the validity flag CPVLD corresponding to the physical address value (PAD=0) read from the address conversion table LPTBL (FIG. 10A) is 0. When the value of the validity flag CPVLD is 0, it is indicated that the current physical address value (PAD=0) corresponding to the logical address value (LAD=0) is invalid and that only the new physical address value (NXPAD=100) corresponds to the logical address value (LAD=0). In other words, even when the new physical address value (NXPAD=100) is assigned to the logical address value (LAD=0) as it is, an overlapped physical address values is not assigned to the logical address value (LAD=0). Thus, in this case, the information processing circuit MNGER executes Step 5 described above.

On the other hand, when the value of the validity flag CPVLD is 1 in Step 11, it is indicated that the physical address value (PAD=0) corresponding to the logical address value (LAD=0) is still valid. Thus, when the new physical address value (NXPAD=100) is assigned to the logical address value (LAD=0) as it is, there are overlapped physical address values with respect to the logical address value (LAD=0). Thus, in Step 13, the information processing circuit MNGER changes the value of the validity flag CPVLD of the physical address value (PAD=0) corresponding to the logical address value (LAD=0) in the address conversion table LPTBL into 0 (invalid). In addition, the validity flag PVLD corresponding to the physical address value (PAD=0) in the physical address table PADTBL is changed to 0 (invalid). In such a manner, the information processing circuit MNGER executes Step 5 described above after making the physical address value (PAD=0) corresponding to the logical address value (LAD=0) invalid.

In Step 6 performed after Step 5, the information processing circuit MNGER and/or each of the non-volatile memory devices NVM10 to NVM17 checks whether the write data (WDATA 0) is written correctly. When the data is written correctly, Step 7 is executed. When the data is not written correctly, Step 12 is executed. In Step 12, the information processing circuit MNGER and/or each of the non-volatile memory devices NVM10 to NVM17 checks whether the number of times of verify check (Nverify) to check whether the write data (WDATA0) is written correctly is equal to or smaller than the set number of times (Nvr). When the number of times of verify check (Nverify) is equal to or smaller than the set number of times (Nvr), Step 5 and Step 6 are executed again. When the number of times of verify check (Nverify) is larger than the set number of times (Nvr), it is determined that the write data (WDATA0) cannot be written into the write physical address value (NXPAD=100) read from the write physical address tables NXPADTBL1 and NXPADTBL2 (Step 14) and Step 3 is executed again. Note that such data verification processing is performed with write data verification circuits WVO to WVm in the non-volatile memory device illustrated in FIG. 3A. There is a case where the processing is performed only with an internal circuit in the non-volatile memory device and a case where the processing is arbitrarily performed along with an external part thereof (information processing circuit MNGER).

In Step 7 performed after Step 6, the information processing circuit MNGER updates the address conversion table LPTBL. More specifically, for example, the new physical address value (NXPAD=100) is written into an address of the logical address value (LAD=0), a value of the validity flag CPVLD is set to 1, and the write layer number NXLYC is written into the layer number LYC. In next Step 8, the information processing circuit MNGER updates the physical address table PADTBL. More specifically, for example, a new value of the number of times of erasure is generated by addition of 1 to the value of the number of times of erasure (NXPERC) of the write physical address value (NXPAD=100) in the write physical address table. Then, the new value of the number of times of erasure is written into a corresponding place (number of times of erasure (PERC) of physical address value (NXPAD=100)) in the physical address table PADTBL. Also, the validity flag PVLD in the physical address table PADTBL is set to 1 and the write layer number NXLYC is written into the layer number LYC.

In Step 9, the information processing circuit MNGER determines whether writing into all write physical addresses NXPAD stored in the write physical address table NXPADTBL is completed. When the writing into all write physical addresses NXPAD stored in the write physical address table NXPADTBL is completed, Step 10 is performed. When the writing is not completed, a new writing request with respect to the memory module NVMMD0 from the information processing device CPU_CP is waited for.

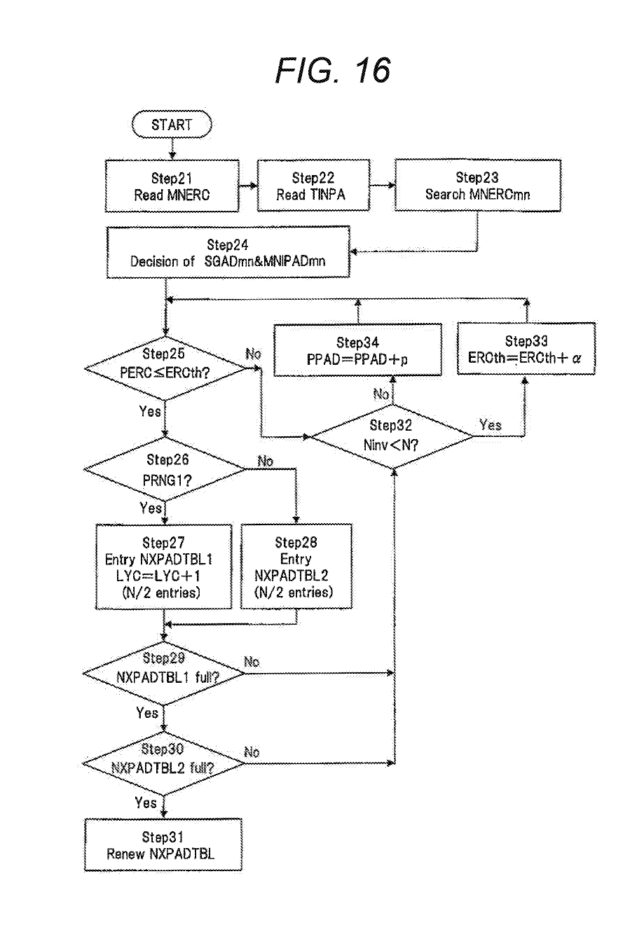

In Step 10, for example, at a time point at which writing into all write physical addresses NXPAD stored in the write physical address table NXPADTBL is completed, the information processing circuit MNGER updates the physical segment table PSEGTBL (FIG. 8A and FIG. 8B). That is, when all entries in the write physical address table NXPADTBL are used, the physical segment table PSEGTBL is updated and the write physical address table NXPADTBL is updated by utilization of this, a detail of the update being described with reference to FIG. 16.

In the update of the physical segment table PSEGTBL, the information processing circuit MNGER refers to a validity flag PVLD and the number of times of erasure PERC of a physical address in the physical address table PADTBL. Then, with a physical address, in which a validity flag PVLD is 0 (invalid), in the physical address table PADTBL as an object, the total number of invalid physical addresses TNIPA, the maximum number of times of erasure MXERC and an invalid physical offset address MXIPAD thereof, and the minimum number of times of erasure MNERC and an invalid physical offset address MNIPAD thereof are updated in each physical segment address SGAD. Also, with a physical address, in which a validity flag PVLD is 1 (valid), in the physical address table PADTBL as an object, the total number of valid physical addresses TNVPA, the maximum number of times of erasure MXERC and a valid physical offset address MXVPAD thereof, and the minimum number of times of erasure MNERC and a valid physical offset address MNVPAD thereof are updated in each physical segment address SGAD.

Also, the information processing circuit MNGER updates the write physical address table NXPADTBL. When the update of the write physical address table NXPADTBL is over, a writing request from the information processing device CPU_CP to the memory module NVMMD0 is waited for.

In such a manner, the information processing circuit MNGER uses the write physical address table NXPADTBL when performing writing into the non-volatile memory devices NVM10 to NVM17. Thus, for example, it is possible to realize a writing operation at high speed compared to a case of searching the physical address table PADTBL for a physical address with the small number of times of erasure in each time of writing. Also, as illustrated in FIG. 2, it is possible to manage/update each table independently in a case where a plurality of write physical address tables NXPTBL1 and NXPTBL2 is included. Accordingly, it becomes possible to realize a writing operation at high speed. For example, it becomes possible to update the write physical address table NXPTBL2 while the write physical address table NXPTBL1 is used, to perform transition to NXPTBL2 when NXPTBL1 is used up, and to update the NXPTBL1 while the NXPTBL2 is used.

### <Updating Method of Write Physical Address Table (Wear Leveling Method [1])>

FIG. 16 is a flowchart illustrating an example of an updating method of the write physical address table in each of FIG. 9A and FIG. 9B. As illustrated in each of FIG. 9A and FIG. 9B, the information processing circuit MNGER manages, as a write physical address table NXPADTBL1, N/2 entries from 0 to (N/2−1) in the entry number ENUM in the write physical address table NXPADTBL and manages, as a write physical address table NXPADTBL2, N/2 entries from (N/2) to (N−1) in the entry number EMUM.

Also, in an example of the address map range (ADMAP) in FIG. 13, “0000_0000” to “04FF_FFFF” of the physical address PAD indicates the first physical address area PRNG1 and “0500_0000” to “09FF_FFFF” of the physical address PAD indicates the second physical address area PRNG2. Thus, a range of a physical segment address SGA in the first physical address area PRNG1 is from “0000” to “04FF” and a range of a physical segment address SGA in the second physical address area PRNG2 is from “0500” to “09FF.”

The information processing circuit MNGER uses the write physical address table NXPADTBL1 with respect to the physical address PAD in the range of the first physical address area PRNG1 and updates this. Also, the information processing circuit MNGER uses the write physical address table NXPADTBL2 with respect to the physical address PAD in the second physical address area PRNG2 and updates this. To update the write physical address table NXPADTBL, a physical segment address is determined first and a physical offset address in the determined physical segment address is subsequently determined. As illustrated in FIG. 8A, the physical segment table PSEGTBL1 in the random access memory RAM stores, for each physical segment address SGAD, the total number of physical addresses in an invalid state (TNIPA), a physical offset address having the minimum number of times of erasure among physical addresses in the invalid state (MNIPAD), and the number of times of erasure (MNERC) thereof.

Thus, as illustrated in FIG. 16, the information processing circuit MNGER first refers to the physical segment table PSEGTBL1 in the random access memory RAM and reads, with respect to each physical segment address SGAD, the total number of physical addresses in the invalid state (TNIPA), the physical offset address having the minimum number of times of erasure (MNIPAD), and the number of times of erasure (MNERC) thereof (Step 21). Then, a physical segment address SGAD with the total number of physical addresses in the invalid state (TNIPA) in each physical segment address SGAD larger than the number of registrations N in the write physical address table NXPADTBL is selected (Step 22). Moreover, values of the minimum number of times of erasure (MNERC) in selected physical segment addresses SGAD are compared with each other and a minimum value (MNERCmn) among the values of the minimum number of times of erasure is calculated (Step 23).

Then, a physical segment address (SGADmn) having the minimum value (MNERCmn) and a physical offset address thereof (MNIPADmn) are determined as a first candidate to be registered into the write physical address table NXPADTBL (Step 24). Note that for existence of the physical segment address SGAD selected in Step 22, a size of a physical address space is made to be larger than a size of a logical address space at least for a size of addresses that can register the write physical address table NXPADTBL.

Then, the information processing circuit MNGER refers to the physical address table PADTBL (FIG. 7), reads a value of the number of times of erasure PERC corresponding to a physical offset address PPAD that is a current candidate in the physical segment address (SGADmn) from the random access memory RAM, and compares the read value with a threshold for the number of times of erasure ERCth (Step 25). Step 25 is a part of loop processing and the physical offset address (MNIPADmn) becomes a candidate of the physical offset address PPAD in the processing performed for the first time. When the value of the number of times of erasure PERC is equal to or smaller than the threshold for the number of times of erasure ERCth, the information processing circuit MNGER confirms the physical offset address PPAD, which is a current candidate, as an object of registration and performs Step 26.

On the other hand, when the value of the number of times of erasure PERC is larger than the threshold for the number of times of erasure ERCth, the information processing circuit MNGER temporarily removes the physical offset address PPAD, which is the current candidate, from the candidate and performs Step 32. In Step 32, the information processing circuit MNGER refers to the physical address table PADTBL and determines whether the number of physical offset addresses in the invalid state (Ninv) which addresses have the number of times of erasure equal to or smaller than the threshold for the number of times of erasure ERCth in the physical segment address (SGADmn) is smaller than the number of addresses N that can register the write physical address table NXPADTBL (Ninv<N). When the number is smaller, Step 33 is performed. When the number is larger, Step 34 is performed.

In Step 34, the information processing circuit MNGER performs calculation of the physical offset address PPAD that is the current candidate, generates a physical offset address PPAD to be a new candidate, and executes Step 25 again. In Step 34, a p value is added to the current physical offset address PPAD and a physical offset address PPAD to be a new candidate is calculated. The p value in Step 34 can be programmed and an optimal value is selected according to a minimum data size managed by the information processing circuit MNGER or a configuration of the non-volatile memory. In the present embodiment, for example, p=8 is used. In Step 33, the information processing circuit MNGER generates a new threshold for the number of times of erasure ERCth generated by addition of a certain value a to the threshold for the number of times of erasure ERCth and executes Step 25 again.

In Step 26, it is checked whether the physical offset address PPAD that becomes an object of registration in Step 25 is an address in the first physical address area PRNG1. When the physical offset address PPAD that becomes the object of registration is an address in the first physical address area PRNG1, Step 27 is executed. When the address is not an address in the first physical address area PRNG1 (that is, when address is address in second physical address area PRNG2), Step 28 is executed.

In Step 27, the information processing circuit MNGER registers an address, in which the physical segment address (SGADmn) is included in the physical offset address PPAD that becomes the object of registration, as a write physical address NXPAD into the write physical address table NXPADTBL1. In addition, a value of the validity flag NXPVLD (here, it is 0) of the write physical address NXPAD is registered and a value of the number of times of erasure (PERC) of the write physical address NXPAD is registered as the number of times of erasure NXPERC. Also, a value generated by addition of 1 to a current layer number LYC of the write physical address NXPAD is registered as a new layer number NXLYC. Although it is not specifically limited, N/2 pairs can be resisted into the write physical address table NXPADTBL1 in ascending order in the entry number ENUM.

As illustrated in FIG. 3B and the like, the maximum value of the layer number LYC (NXLYC) becomes n when (n+1) phase-change memory cells CL0 to CLn are included in a chain memory array CY. Note that in an example of the write physical address table NXPADTBL in each of FIG. 9A and FIG. 9B, the layer number NXLYC=“n.” When the layer number LYC (NXLYC) reaches the maximum value n, a value of a new layer number LYC (NXLYC) becomes 0. Writing into the non-volatile memory devices NVM10 to NVM17 is performed by utilization of the write physical address table NXPADTBL. Thus, by serially shifting the layer number LYC (NXLYC) in an update of the table, it is possible to realize the first operation mode described with reference to FIG. 14 and the like.

In Step 28, the information processing circuit MNGER registers an address, in which the physical segment address (SGADmn) is included in a physical offset address PPAD that is an object of registration, as the write physical address NXPAD into the write physical address table NXPADTBL2. In addition, a value of the validity flag NXPVLD (here, it is 0) of the write physical address NXPAD is registered and the number of times of erasure (PERC) and a current layer number LYC of the write physical address NXPAD are registered as the number of times of erasure NXPERC and a layer number NXLYC. Although it is not specifically limited, N/2 pairs can be registered into the write physical address table NXPADTBL2 in ascending order in the entry number ENUM. Note that the number of registered pairs in the write physical address tables NXPADTBL1 and NXPADTBL2 can be set arbitrarily by the information processing circuit MNGER and is set in such a manner that writing speed with respect to the non-volatile memory devices NVM10 to NVM17 becomes the highest.

In next Step 29, the information processing circuit MNGER checks whether registration is completed with respect to all pairs (all entry numbers) in the write physical address table NXPADTBL1. When the registration of all pairs is not completed, Step 32 is executed. When the registration of all pairs is completed, Step 30 is executed. In next Step 30, the information processing circuit MNGER checks whether registration of all pairs in the write physical address table NXPADTBL2 is completed. When the registration of all pairs is not completed, Step 32 is executed. When registration of all pairs is completed, the update of the write physical address table NXPADTBL is completed (Step 31).

When such an update flow is used, roughly, a physical address segment having a physical address with the minimum number of times of erasure is determined (Step 21 to Step 24) and physical addresses with the number of times of erasure equal to or smaller than a predetermined threshold are serially extracted with the smallest physical address as an origin in the physical address segment (Step 25, and Step 32 to Step 34). Here, when the number of extracted addresses is smaller than a predetermined number of registrations (Step 32), a threshold for the number of times of erasure is gradually increased (Step 33) and physical addresses are serially extracted in a similar manner (Step 25 and Step 34) until the number of extracted addresses satisfies the predetermined number of registrations (Step 32, Step 29, and Step 30). Accordingly, wear leveling (dynamic wear leveling) to perform leveling of the number of times of erasure of physical addresses in the invalid state (that is, physical address that is not currently assigned to logical address) can be realized.

### <Detail of Assignment of Address in Non-Volatile Memory Device>

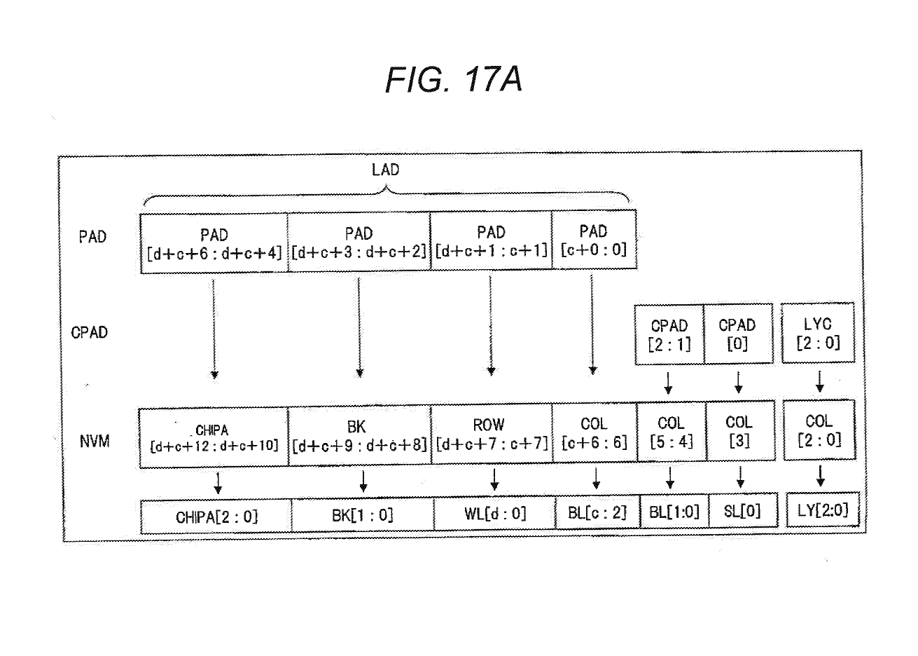

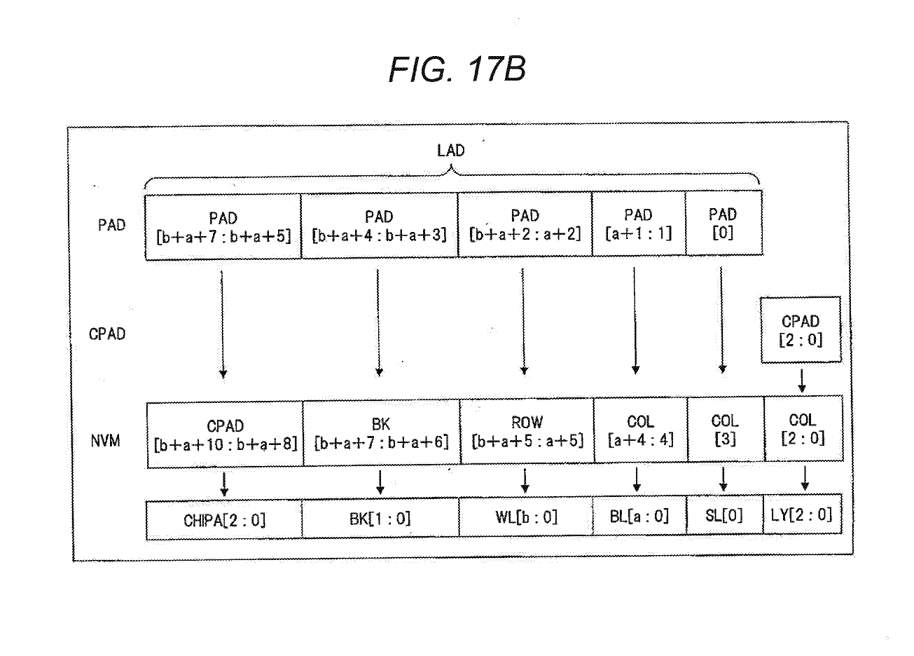

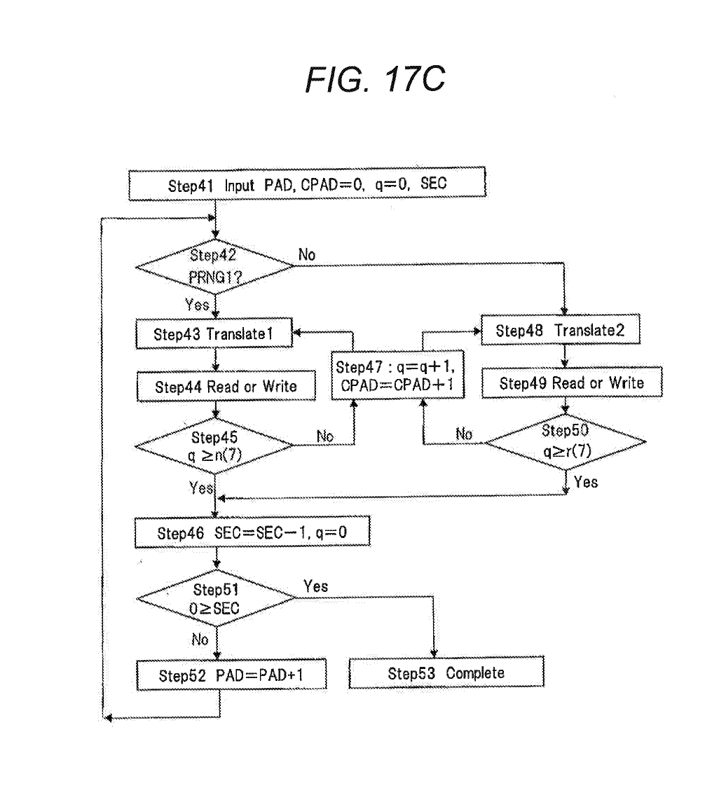

FIG. 17A is a view illustrating an example of a correspondence relationship between a logical address, physical address, and an in-chip address in a non-volatile memory device assigned to the first physical address area PRNG1 in FIG. 13 and the like. FIG. 17B is a view illustrating an example of a correspondence relationship between a logical address, a physical address, and an in-chip address in a non-volatile memory device assigned to the second physical address area PRNG2 in FIG. 13 and the like.

In each of FIG. 17A and FIG. 17B, a correspondence relationship between a logical address LAD, a physical address PAD, a physical address CPAD, a chip address CHIPA [2:0] of the non-volatile memory devices NVM10 to NVM17, a bank address BK [10] in each chip, a row address ROW, and a column address COL is illustrated. In addition, a correspondence relationship between a layer number LYC and a column address COL, a correspondence relationship between a row address ROW and a word line WL, and a correspondence relationship between a column address COL, a bit line BL, a chain memory array selection line SL, and a memory-cell selection line LY are illustrated.

Although it is not specifically limited, the following is assumed. That is, there are eight chips of the non-volatile memories NVM10 to NVM17. In one chip of the non-volatile memory device, there are two chain memory array selection lines SL. In one chain memory array CY, there are eight memory cells and eight memory-cell selection lines LY. Also, in one memory bank BK, there are 528 memory arrays ARY. One chain memory array CY is selected in one memory array ARY. That is, 528 chain memory arrays CY are simultaneously selected in the one memory bank BK. There are four memory banks. In the first physical address area PRNG1 in FIG. 17A, data is held in only one memory cell among the eight memory cells in one chain memory array CY. In the second physical address area PRNG2 in FIG. 17B, data is held in eight memory cells among eight memory cells in one chain memory arrays CY.

Assignment of an address in each of FIG. 17A and FIG. 17B is performed, for example, by the information processing circuit MNGER in FIG. 2. In FIG. 17A, the information processing circuit MNGER in FIG. 2 associates a layer number NXLYC (LYC [2:0]) and a physical address NXPAD (PAD [31:0]) that are stored in the write physical address table NXPADTBL1 (FIG. 9A and FIG. 9B) with a physical address CPAD [2:0] in a case of writing data into the non-volatile memory devices NVM10 to NVM17. Also, in a case of reading data from the non-volatile memory devices NVM10 to NVM17, a physical address PAD [31:0] and a layer number LYC [2:0] of the physical address PAD which are stored in the address conversion table LPTBL (FIG. 10A) are associated to the physical address CPAD [2:0].

The layer number LYC [2:0] corresponds to a column address COL [2:0]. The column address COL [2:0] corresponds to a memory-cell selection line LY [2:0]. A value of the layer number LYC [2:0] becomes a value of the memory-cell selection line LY [2:0] and data is written into a memory cell designated by the layer number LYC [2:0]. Also, data is read from a memory cell designated by the layer number LYC [2:0].

A physical address CPAD [0] corresponds to a column address COL [3]. The column address COL [3] corresponds to the chain memory array selection line SL [0]. A physical address CPAD [2:1] corresponds to a column address COL [5:4] and the column address COL [5:4] corresponds to a bit line BL [1:0]. The physical address PAD [c+0:0] corresponds to a column address COL [c+6:6] and the column address COL [c+6:6] corresponds to a bit line BL [c:2]. A physical address PAD [d+c+1:1] corresponds to a row address ROW [d+c+7:7] and the row address ROW [d+c+7:7] corresponds to the word line WL [d:0].

A physical address CPAD [d+c+3:d+c+2] corresponds to a bank address BK [d+c+9:d+c+8] and the bank address BK [d+c+9:d+c+8] corresponds to a bank address BK [1:0]. A physical address CPAD [d+c+6:d+c+4] corresponds to a chip address BK [d+c+12:d+c+10] and the chip address CHIPA [d+c+12:d+c+10] corresponds to a chip address CHIPA [2:0].

Here, for example, a case of writing 512-byte main data and 16-byte redundant data is assumed.

It is assumed that a physical address PAD [d+c+6:d+c+4] is 3, a physical address PAD [d+c+3:d+c+2] is 2, a physical address PAD [d+c+1:c+1] is 8, a physical address CPAD [c+0:0] is 0, a physical address CPAD [2:1] is 0, a physical address CPAD [0] is 0, and the layer number LYC [2:0] is 0. In this case, the information processing circuit MNGER in FIG. 2 changes a value of the physical address CPAD [2:0] by +1 from 0 to 7, writes data into each address by 528 bits, and writes data of 528 bytes in total without changing a value of the layer number LYC and a value of the physical address PAD. In a case of reading 512-byte main data and 16-byte redundant data on the same assumption, the information processing circuit MNGER in FIG. 2 changes a value of the physical address CPAD [2:0] by +1 from 0 to 7, reads data from each address by 528 bits, and reads data of 528 bytes in total without changing a value of the layer number LYC and a value of the physical address PAD.

That is, in a case of this example, in FIG. 3A, four bit lines BL are serially selected with respect to one word line WL in each of memory arrays ARY0 to ARY 527. Also, as illustrated in FIG. 3B, two chain memory arrays CY which are placed in intersection points of the word lines WL and the bit lines BL and which are selected by chain memory array selection lines SL are selected. However, in this case, one phase-change memory cell is selected in each chain memory array CY.

One the other hand, in FIG. 17B, in a case of writing data into the non-volatile memories NVM10 to NVM17, the information processing circuit MNGER in FIG. 2 associates the physical address NXPAD (PAD [31:0]) stored in the write physical address table NXPADTBL2 and the physical address CPAD [2:0] with addresses of the non-volatile memories NVM10 to NVM17. Also, in a case of reading data from the non-volatile memory devices NVM10 to NVM17, the physical address PAD [31:0] stored in the address conversion table LPTBL and the physical address CPAD [2:0] are associated with the addresses of the non-volatile memory devices NVM10 to NVM17.

The physical address CPAD [2:0] corresponds to a column address COL [2:0] and the column address COL [2:0] corresponds to a memory-cell selection line LY [2:0]. A value of the physical address CPAD [2:0] becomes a value of the memory-cell selection line LY [2:0] and data is written into a memory cell designated by the physical address CPAD [2:0]. Also, data is read from the memory cell designated by the physical address CPAD [2:0].

A physical address PAD [0] corresponds to a column address COL [3] and the column address COL [3] corresponds to a chain memory array selection line SL [0]. A physical address PAD [a+1:1] corresponds to a column address COL [a+1:1]. The column address COL [a+1:1] corresponds to a bit line BL [a:0]. A physical address PAD [b+a+2:2] corresponds to a row address ROW [b+a+2:2] and the row address ROW [b+a+2:2] corresponds to a word line WL [b:0].

A physical address PAD [b+a+4:b+a+3] corresponds to a bank address BK [b+a+4:b+a+3] and the bank address BK [b+a+4:b+a+3] corresponds to a bank address BK [1:0]. A physical address PAD [b+a+7:b+a+5] corresponds to a chip address BK [b+a+7:b+a+5] and a chip address CHIPA [b+a+7:b+a+5] corresponds to the chip address CHIPA [2:0].

Here, for example, a case of writing 512-byte main data and 16-byte redundant data is assumed. It is assumed that a physical address PAD [b+a+7:b+a+5] is 3, a physical address PAD [b+a+4:b+a+3] is 2, a physical address PAD [b+a+2:a+2] is 8, a physical address PAD [a+1:1] is 0, a physical address PAD [0] is 0, and a physical address CPAD [2:0] is 0.

In this case, the information processing circuit MNGER in FIG. 2 changes a value of the physical address CPAD [2:0] by +1 from 0 to 7, writes data into each address by 528 bits, and writes data of 528 bytes in total without changing a value of the physical address PAD. In a case of reading 512-byte main data and 16-byte redundant data on the same assumption, the information processing circuit MNGER in FIG. 2 changes a value of the physical address CPAD [2:0] by +1 from 0 to 7, reads data from each address by 528 bits, and reads data of 528 bytes in total without changing a value of the physical address PAD.

That is, in a case of this example, in FIG. 3A, one bit line BL is selected with respect to one word line WL in each of the memory arrays ARY0 to ARY527. Also, as illustrated in FIG. 3B, one of two chain memory arrays CY which are placed in intersection points of the word lines WL and the bit lines BL and which are selected by the chain memory array selection lines SL is selected. However, in this case, eight phase-change memory cells are selected in each chain memory array CY.

FIG. 17C is a view illustrating an example of a change in a physical address PAD and a physical address CPAD in a case where the information processing circuit MNGER in FIG. 2 writes/reads data into/from the non-volatile memory device. First, the information processing circuit MNGER determines a sector count SEC, a physical address PAD, and a physical address CPAD (=0). Then, after setting a variable q to 0 (Step 41), the information processing circuit MNGER checks whether the physical address PAD is a physical address in the first physical address area PRNG1 (Step 42). When the physical address PAD is not a physical address in the first physical address area PRNG1, Step 48 is executed. Also, when the physical address PAD is a physical address in the first physical address area PRNG1, address conversion illustrated in FIG. 17A is performed (Step 43) and data is written into/read from the non-volatile memory device (Step 44).

Next, the information processing circuit MNGER checks whether a value of the variable q is equal to or larger than n (Step 45). When the value of the variable q is smaller than n, a new physical address CPAD generated by addition of 1 to a physical address CPAD is calculated (Step 47) and Step 43 is executed again. Then, Step 44 is executed. When the value of the variable q is equal to or larger than n, the sector count SEC is reduced by one and the value of the variable q is set to 0 (Step 46). Then, Step 51 is executed. In Step 51, it is checked whether a value of the sector count SEC is equal to or smaller than 0. When the value of the sector count SEC is not equal to or smaller than 0, a new physical address PAD generated by addition of 1 to a physical address PAD is calculated (Step 52). Then, the processing is brought back to Step 42 again and kept performed. When the value of the sector count SEC is equal to or smaller than 0, writing or reading of data is completed (Step 53).

In a case where 1 is added to the physical address CPAD in Step 47, a chain memory array selection line SL or a bit line BL (that is, position of chain memory array CY) is changed as it is understood from FIG. 17A.

In Step 48, the information processing circuit MNGER performs address conversion illustrated in FIG. 17B (Step 48) and writes/reads data into/from the non-volatile memory device (Step 49). Then the information processing circuit MNGER checks whether a value of the variable q is equal to or larger than r (Step 50). When the value of the variable q is smaller than r, a new physical address CPAD generated by addition of 1 to a physical address CPAD is calculated (Step 47) and Step 48 is executed again. Then, Step 49 is executed. When the value of the variable q is equal to or larger than r, processing in and after Step 46 is executed.

When 1 is added to the physical address CPAD in Step 47, a memory-cell selection line LY (that is, position of memory cell in chain memory array CY) is changed as it is understood from FIG. 17B.

Note that an n value in Step 45 or an r value in Step 50 can be programed. An optimal value is selected according to a minimum data size managed by the information processing circuit MNGER or a configuration of the non-volatile memory device. In the present embodiment, for example, n=r=7 is used.

### <Example of Updating Operation of Address Conversion Table and Non-Volatile Memory Device>

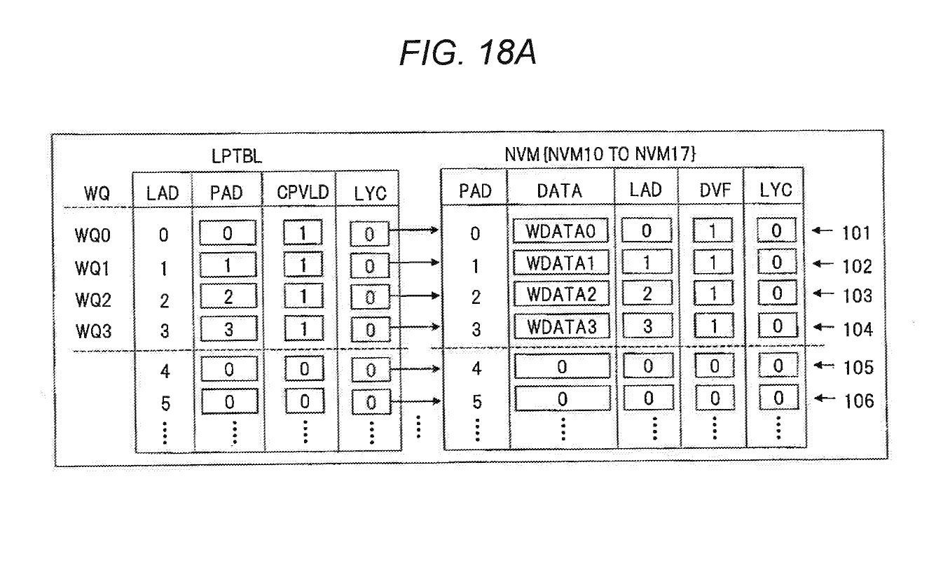

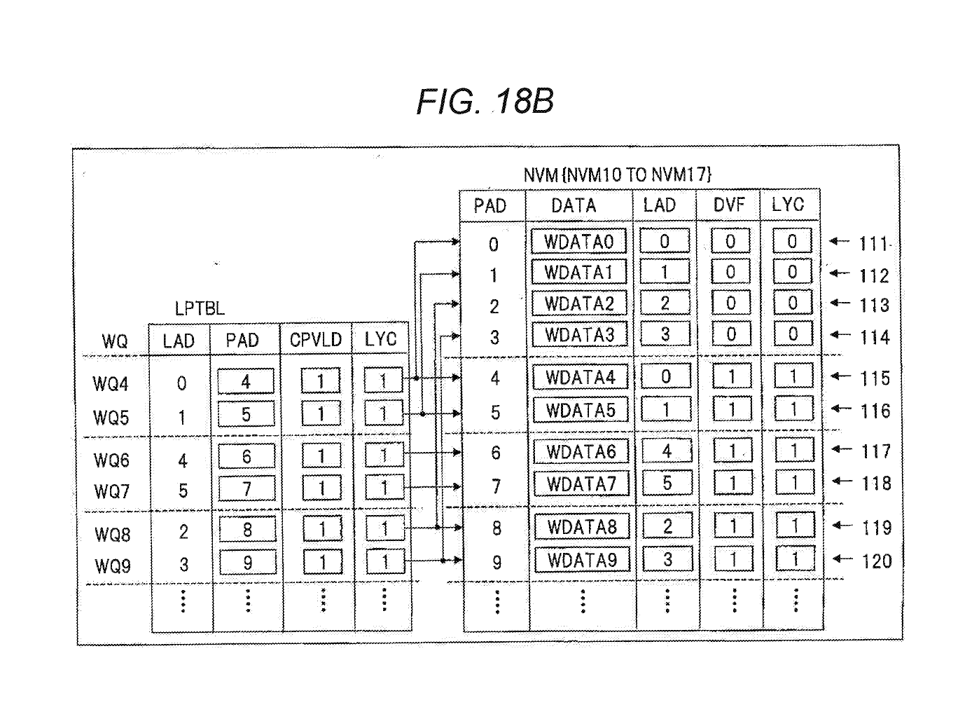

Each of FIG. 18A and FIG. 18B is a view illustrating an example an updating method of the address conversion table LPTBL and a data updating method of a non-volatile memory device in a case where the control circuit MDLCT0 in FIG. 1 writes data into the first physical address area PRNG1 of the non-volatile memory device. The address conversion table LPTBL is a table for converting a logical address LAD, which is input into the control circuit MDLCT0 by the information processing device CPU_CP, into a physical address PAD of the non-volatile memory device.

The address conversion table LPTBL includes a physical address PAD corresponding to a logical address LAD, and a validity flag CPVLD and a layer number LYC of the physical address. Also, the address conversion table LPTBL is stored into the random access memory RAM. The non-volatile memory device stores data DATA, a logical address LAD, a data validity flag DVF, and a layer number LYC that correspond to the physical address PAD.

In FIG. 18A, a state after writing requests WQ0, WQ1, WQ2, and WQ3 with respect to a logical address area LRNG1 are input into the control circuit MDLCT0 by the information processing device CPU_CP after time T0 is illustrated. More specifically, an address, data, a validity flag, and a layer number LYC stored in the address conversion table LPTBL and the non-volatile memory device at the time T1 that is after data of these writing requests is written into the first physical address area PRNG1 of the non-volatile memory device is illustrated.

The writing request WQ0 includes a logical address value (LAD=0), a data writing instruction (WRT), a sector count value (SEC=1), and write data (DATA0). The writing request WQ1 includes a logical address value (LAD=1), a data writing instruction (WRT), a sector count value (SEC=1), and write data (DATA1). The writing request WQ2 includes a logical address value (LAD=2), a data writing instruction (WRT), a sector count value (SEC=1), and write data (DATA2). The writing request WQ3 includes a logical address value (LAD=3), a data writing instruction (WRT), a sector count value (SEC=1), and write data (DATA3). When the writing requests WQ0, WQ1, WQ2, and WQ3 are input into the control circuit MDLCT0, an interface circuit HOST_IF transfers these writing requests to the buffer BUF0.

Then, the information processing circuit MNGER serially reads the writing requests WQ0, WQ1, WQ2, and WQ3 stored in the buffer BUF0. Since the logical address values (LAD) of the writing requests WQ0, WQ1, WQ2, and WQ3 are respectively 0, 1, 2, and 3, the information processing circuit MNGER reads information corresponding to these from the address conversion table LPTBL, which is stored in the random access memory RAM, through a memory control circuit RAMC. That is, a value of a physical address (PAD), a value of a validity flag (CPVLD), and a layer number LYC are read from each of an address 0, an address 1, an address 2, and an address 3 of the logical address LAD in the address conversion table LPTBL.

As illustrated in FIG. 10A, all read values of validity flag (CPVLD) are 0 at first. Thus, it is understood that no physical address PAD is assigned to the address 0, the address 1, the address 2, and the address 3 of the logical address LAD. Then, the information processing circuit MNGER reads write physical address values (NXPAD) and layer numbers NXLYC stored in 0 to 3 of the entry number ENUM in the write physical address table NXPADTBL1 and assigns these to the address 0, the address 1, the address 2, and the address 3 of the logical address LAD. In this example, the write physical address values (NXPAD) stored in 0 to 3 of the entry number ENUM are respectively 0, 1, 2, and 3 in decimal numbers and the layer numbers NXLYC are resepectively 0, 0, 0, and 0.

Then, the information processing circuit MNGER generates ECC codes ECC0, 1, 2, and 3 respectively corresponding to write data DATA0, 1, 2, and 3 of the writing request WQ0, 1, 2, and 3 and generates, according to a data format illustrated in FIG. 12A, write data WDATA0, 1, 2, and 3 for the non-volatile memory device. That is, the write data WDATA0 includes main data MDATA0, which includes write data (DATA0), and redundant data RDATA0 corresponding thereto. The write data WDATA1 includes main data MDATA1, which includes write data (DATA1), and redundant data RDATA1 corresponding thereto. Similarly, the write data WDATA2 includes main data MDATA2, which includes write data (DATA2), and redundant data RDATA2 corresponding thereto. The write data WDATA3 includes main data MDATA3, which includes write data (DATA3), and redundant data RDATA3 corresponding thereto.

The information processing circuit MNGER respectively writes the write data WDATA0, 1, 2, and 3 into four physical addresses in the non-volatile memory device. The redundant data RDATA0, 1, 2, and 3 respectively include the ECC codes ECC0, 1, 2, and 3. In addition, a data inversion flag value (INVFLG=0), a writing flag value (WTFLG=0), an ECC flag value (ECCFLG=0), a state information value (STATE=1), an area information value (AREA=1), a data write layer information value (LYN=1), a bad block information value (BADBLK=0), and a preliminary area value (RSV=0) are included in common.

Note that in a case where a writing request is for the logical address area LRNG1, the area information value (AREA) becomes 1. In a case where a writing request is for the logical address area LRNG2, the area information value (AREA) becomes 2. Also, when a layer number NXLYC value read from the written physical address table NXPADTBL1 is 0 (actually, “10”), LYN [n:1] becomes 0 and LYN [0] becomes 1 in the data write layer information LYN [n:0]. Also, it is indicated that data is written into the phase-change memory cell CL0 in the chain memory array CY.

In addition, according to decimal numbers 0, 1, 2, and 3 of the write physical address values (NXPAD), the information processing circuit MNGER performs writing on the non-volatile memory devices NVM10 to NVM17 through the arbitration circuit ARB and the memory control circuits NVCT10 to NVCT17. That is, to the address 0 of the physical address PAD of the non-volatile memory device NVM, the write data WDATA0, a logical address value (LAD=0), and a layer number (LYC=0) corresponding to the writing request WQ0 are written and 1 is written as a value of a data validity flag (DVF). To the address 1 of the physical address PAD of the non-volatile memory device NVM, the write data WDATA1, a logical address value (LAD=1), and a layer number (LYC=0) corresponding to the writing request WQ1 are written and 1 is written as a value of a data validity flag (DVF). Similarly, to the address 2 of the physical address PAD, the write data WDATA2, a logical address value (LAD=2), a data validity flag (DVF=1), and a layer number (LYC=0) are written. To the address 3 of the physical address PAD, the write data WDATA3, a logical address value (LAD=3), a data validity flag (DVF=1), and a layer number (LYC=0) are written.

Finally, the information processing circuit MNGER updates the address conversion table LPTBL, which is stored in the random access memory RAM, through the memory control circuit RAMC. That is, to the address 0 of the logical address LAD, a physical address (PAD=0), a validity flag (CPVLD=1), and a layer number (LYC=0) after the assignment are written. To the address 1 of the logical address LAD, a physical address (PAD=2), a validity flag (CPVLD=1), and a layer number (LYC=0) after the assignment are written. To the address 2 of the logical address LAD, a physical address (PAD=2), a validity flag (CPVLD=1), and a layer number (LYC=0) after the assignment are written. To the address 3 of the logical address LAD, a physical address (PAD=3), a validity flag (CPVLD=1), and a layer number (LYC=0) after the assignment are written.

In FIG. 18B, a state after writing requests WQ4, WQ5, WQ6, WQ7, WQ8, and WQ9 are input into the control circuit MDLCT0 by the information processing device CPU_CP after time T1 is illustrated. More specifically, an address, data, and a validity flag stored in the address conversion table LPTBL and the non-volatile memory device at time T2 that is after data of these writing requests is written into the first physical address area PRNG1 of the non-volatile memory device are illustrated.

The writing request WQ4 includes a logical address value (LAD=0), a data writing instruction (WRT), a sector count value (SEC=1), and write data (DATA4). The writing request WQ5 includes a logical address value (LAD=1), a data writing instruction (WRT), a sector count value (SEC=1), and write data (DATA5). The writing request WQ6 includes a logical address value (LAD=4), a data writing instruction (WRT), a sector count value (SEC=1), and write data (DATA6). The writing request WQ7 includes a logical address value (LAD=5), a data writing instruction (WRT), a sector count value (SEC=1), and write data (DATA7). The writing request WQ8 includes a logical address value (LAD=2), a data writing instruction (WRT), a sector count value (SEC=1), and write data (DATAB). The writing request WQ9 includes a logical address value (LAD=3), a data writing instruction (WRT), a sector count value (SEC=1), and write data (DATA9). When the writing requests WQ4, WQ5, WQ6, WQ7, WQ8, and WQ9 are input into the control circuit MDLCT0, the interface circuit HOST_IF transfers these writing requests to the buffer BUF0.

Next, the information processing circuit MNGER serially reads the writing requests WQ4, WQ5, WQ6, WQ7, WQ8, and WQ9 stored in the buffer BUF0. Subsequently, according to the data format illustrated in FIG. 12A, the information processing circuit MNGER generates write data WDATA4, 5, 6, 7, 8, and 9 respectively corresponding to the writing requests WQ4, 5, 6, 7, 8, and 9. The write data WDATA4 includes main data MDATA4, which includes the write data DATA4, and redundant data RDATA4. The write data WDATA5 includes main data MDATA5, which includes write the data DATA5, and redundant data RDATA5. The write data WDATA6 includes main data MDATA6, which includes the write data DATA6, and redundant data RDATA6. The write data WDATA7 includes main data MDATA7, which includes the write data DATA7, and redundant data RDATA7. The write data WDATA8 includes main data MDATA8, which includes the write data DATA8, and redundant data RDATA8. The write data WDATA9 includes main data MDATA9, which includes the write data DATA9, and redundant data RDATA9.

The redundant data RDATA4, 5, 6, 7, 8, and 9 respectively include ECC codes ECC4, 5, 6, 7, 8, and 9 generated by the information processing circuit MNGER with utilization of the write data DATA4, 5, 6, 7, 8, and 9. In addition, a data inversion flag value (INVFLG=0), a writing flag value (WTFLG=0), an ECC flag value (ECCFLG=0), a state information value (STATE=1), an area information value (AREA=1), a bad block information value (BADBLK=0), and a preliminary area value (RSV=0) are included in common.

The information processing circuit MNGER respectively writes the write data WDATA4, 5, 6, 7, 8, and 9 into six physical addresses in the non-volatile memory device. Here, since the logical address values (LAD) of the writing requests WQ4, 5, 6, 7, 8, and 9 are respectively 0, 1, 4, 5, 2, and 3, the information processing circuit MNGER reads information corresponding to these from the address conversion table LPTBL, which is stored in the random access memory RAM, through the memory control circuit RAMC. That is, a physical address value (PAD), a validity flag value (CPVLD), and a layer number LYC are read from each of the address 0, the address 1, the address 4, the address 5, the address 2, and the address 3 of the logical address LAD in the address conversion table LPTBL.

In the address conversion table LPTBL in FIG. 18A, a physical address value (PAD) is 0, avalidityflagvalue (CPVLD) is 1, a layer number LYC is 0 at the address 0 of the logical address LAD. It is necessary to invalidate already-written data of the address 0 of the physical address PAD along with the writing request WQ4 to the address 0 of the logical address LAD. Thus, the information processing circuit MNGER sets the validity flag value (DVF) at the address 0 of the physical address PAD in the non-volatile memory device to 0 (101 in FIG. 18A to 111 in FIG. 18B). Similarly, in FIG. 18A, a physical address value (PAD) is 1, a validity flag value (CPVLD) is 1, and a layer number LYC is 0 at the address 1 of the logical address LAD. It is necessary to invalidate data at the address 1 of the physical address PAD along with the writing request WQ5. Thus, the information processing circuit MNGER sets the validity flag value (DVF) at the address 1 of the physical address PAD to 0 (102 in FIG. 18A to 112 in FIG. 18B).

Also, in the address conversion table LPTBL in FIG. 18A, a physical address value (PAD) is 0, a validity flag value (CPVLD) is 0, and a layer number LYC is 0 at the address 4 of the logical address LAD associated with the writing request WQ6. It is understood that no physical address PAD is assigned to the address 4 of the logical address LAD. Similarly, in FIG. 18A, a physical address value (PAD) is 0, a validity flag value (CPVLD) is 0, and a layer number LYC is 0 at the address 5 of the logical address LAD associated with the writing request WQ7. It is understood that no physical address PAD is assigned to the address 5 of the logical address LAD.

On the other hand, in the address conversion table LPTBL in FIG. 18A, a physical address value (PAD) is 2, a validity flag value (CPVLD) is 1, a layer number LYC is 0 at the address 2 of the logical address LAD. It is necessary to invalidate the already-written data at the address 2 of the physical address PAD along with the writing request WQ8 to the address 2 of the logical address LAD. Thus, the information processing circuit MNGER sets the validity flag value (DVF) at the address 2 of the physical address PAD to 0 (103 in FIG. 18A to 113 in FIG. 18B). Similarly, in FIG. 18, a physical address value (PAD) is 3, a validity flag value (CPVLD) is 1, and a layer number LYC is 0 at the address 3 of the logical address LAD. It is necessary to invalidate data at the address 3 of the physical address PAD invalid along with the writing request WQ9. Thus, the information processing circuit MNGER sets a validity flag value (DVF) at the address 6 of the physical address PAD to 0 (104 in FIG. 18A to 114 in FIG. 18B).

Next, the information processing circuit MNGER reads write physical address values (NXPAD) and layer numbers NXLYC stored in 4 to 9 of the entry number ENUM in the write physical address table NXPADTBL1 and respectively assigns these to the address 0, the address 1, address 4, the address 5, the address 2, and the address 3 of the logical addresses LAD. In this example, the write physical address values (NXPAD) stored in 4 to 9 of the entry number ENUM are respectively 4, 5, 6, 7, 8, and 9 and the layer numbers NXLYC are respectively 1, 1, 1, 1, 1, and 1.

Then, the information processing circuit MNGER performs writing into the non-volatile memory devices NVM10 to NVM17 through the arbitration circuit ARB and the memory control circuits NVCT10 to NVCT17 according to the write physical address values (NXPAD) 4, 5, 6, 7, 8, and 9. That is, to the address 4 of the physical address PAD of the non-volatile memory device NVM, write data WDATA4, a logical address value (LAD=0), and a layer number (LYC=1) corresponding to the writing request WQ4 are written and 1 is written as a value of a data validity flag (DVF). To the address 5 of the physical address PAD of the non-volatile memory device NVM, write data WDATA5, a logical address value (LAD=1), and a layer number (LYC=1) corresponding to the writing request WQ5 are written and 1 is written as a value of a data validity flag (DVF).

Also, to the address 6 of the physical address PAD of the non-volatile memory device NVM, the information processing circuit MNGER writes write data WDATA6, a logical address value (LAD=4), and a layer number (LYC=1) corresponding to the writing request WQ6 and writes 1 as a value of a data validity flag (DVF). Similarly, to the address 7 of the physical address PAD of the non-volatile memory device NVM, write data WDATA7, a logical address value (LAD=5), and a layer number (LYC=1) corresponding to the writing request WQ7 are written and 1 is written as a value of a data validity flag (DVF).

Moreover, to the address 8 of the physical address PAD of the non-volatile memory device NVM, the information processing circuit MNGER writes write data WDATA8, a logical address value (LAD=2), and a layer number (LYC=1) corresponding to the writing request WQ8 and 1 is written as a value of a data validity flag (DVF). Similarly, to the address 9 of the physical address PAD of the non-volatile memory device NVM, write data WDATA9, a logical address value (LAD=3), and a layer number (LYC=1) corresponding to the writing request WQ9 are written and 1 is written as a value of a data validity flag (DVF).

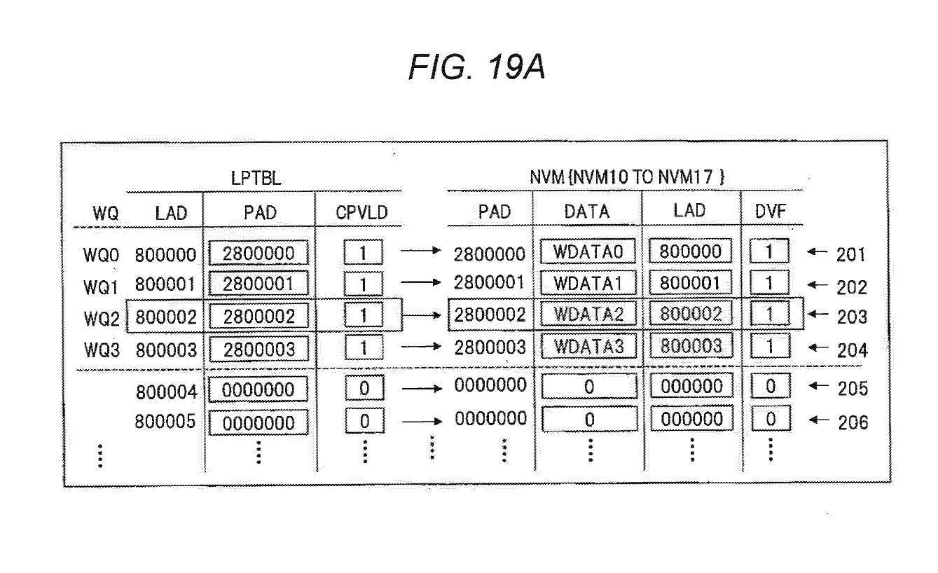

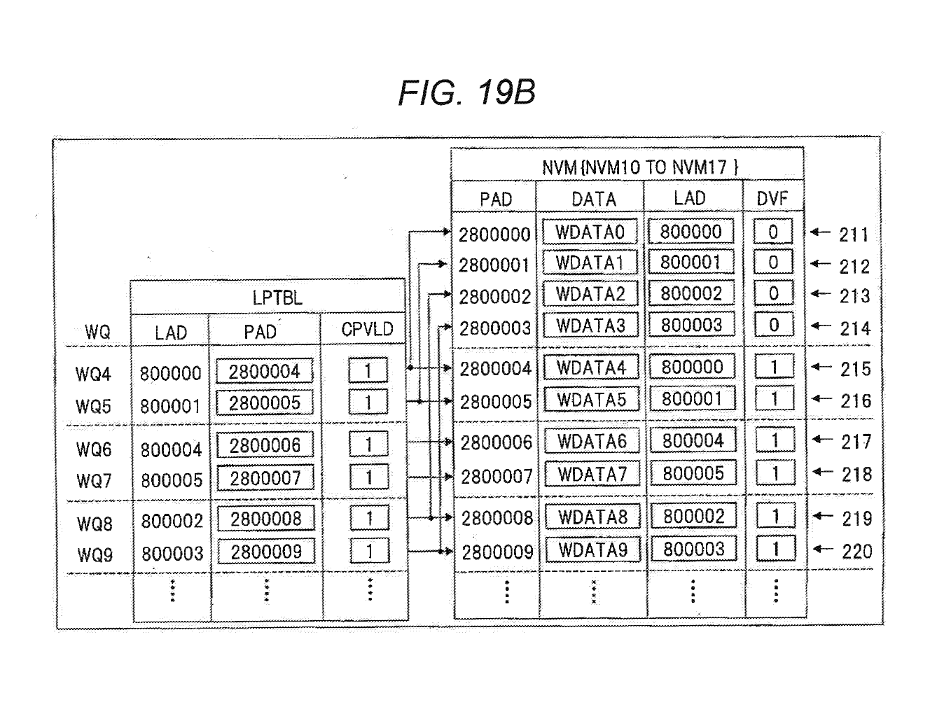

Each of FIG. 19A and FIG. 19B is a view illustrating an example of an updating method of the address conversion table LPTBL and an data updating method of the non-volatile memory device in a case where the control circuit MDLCT0 in FIG. 1 writes data into the second physical address area PRNG2 of the non-volatile memory device. Here, similarly to cases of FIG. 18A and FIG. 18B, states of the address conversion table LPTBL and the non-volatile memory device NVM are illustrated. The address conversion table LPTBL includes a physical address PAD corresponding to a logical address LAD, and a validity flag CPVLD and a layer number LYC of the physical address. Also, the address conversion table LPTBL is stored into the random access memory RAM. The non-volatile memory device stores data DATA, a logical address LAD, a data validity flag DVF, and a layer number LYC corresponding to the physical address PAD. Here, all of the layer numbers LYC are omitted from the drawing since the numbers are “0.”

In FIG. 19A, a state after writing requests WQ0, WQ1, WQ2, and WQ3 with respect to the logical address area LRNG2 are input into the control circuit MDLCT0 by the information processing device CPU_CP after time T0 is illustrated. More specifically, an address, data, and a validity flag stored in an address conversion table LPTBL and the non-volatile memory device at time T1 that is after data of these writing requests is written into the second physical address area PRNG2 of the non-volatile memory device are illustrated.

The writing request WQ0 includes a logical address value (LAD=“800000”) in a hexadecimal number, a data writing instruction (WRT), a sector count value (SEC=1), and write data (DATA0). The writing request WQ1 includes a logical address value (LAD=“800001”) in a hexadecimal number, a data writing instruction (WRT), a sector count value (SEC=1), and write data (DATA1). The writing request WQ2 includes a logical address value (LAD=“800002”) in a hexadecimal number, a data writing instruction (WRT), a sector count value (SEC=1), and write data (DATA2). The writing request WQ3 includes a logical address value (LAD=“800003”) in a hexadecimal number, a data writing instruction (WRT), a sector count value (SEC=1), and write data (DATA3).

When the writing requests WQ0, WQ1, WQ2, and WQ3 are input into the control circuit MDLCT0, the interface circuit HOST_IF transfers these writing requests to the buffer BUF0. Then, the information processing circuit MNGER serially reads the writing request WQ0, WQ1, WQ2, and WQ3 stored in the buffer BUF0. Here, the information processing circuit MNGER refers to the address conversion table LPTBL, which is stored in the random access memory RAM, through the memory control device RAMC and reads various kinds of information corresponding to the writing requests WQ0, 1, 2, and 3. More specifically, a physical address value (PAD) and a validity flag CPVLD are read from each of an address “800000,” an address “800001,” an address “800002,” and an address “800003” of the logical address LAD in the address conversion table LPTBL.

It is understood that no physical address PAD is assigned to each of the address “800000,” the address “800001,” the address “800002,” and the address “800003” of the logical address LAD at first since all of the read validity flags CPVLD are 0 as illustrated in FIG. 10A. Then, in response to the writing requests WQ0, 1, 2, and 3, the information processing circuit MNGER generates write data WDATA0, 1, 2, and 3 for the non-volatile memory device according to the data format illustrated in FIG. 12A. The write data WDATA0 includes main data MDATA0, which includes the write data DATA0, and redundant data RDATA0 thereof. The write data WDATA1 includes main data MDATA1, which includes the write data DATA1, and redundant data RDATA1 thereof. The write data WDATA2 includes main data MDATA2, which includes the write data DATA2, and redundant data RDATA2 thereof. The write data WDATA3 includes main data MDATA3, which includes the write data DATA3, and redundant data RDATA3 thereof.

The redundant data RDATA0, 1, 2, and 3 respectively include ECC codes ECC0, 1, 2, and 3 generated by the information processing circuit MNGER with utilization of the write data DATA0, 1, 2, and 3. In addition, a data inversion flag value (INVFLG=0), a writing flag value (WTFLG=0), an ECC flag value (ECCFLG=0), a state information value (STATE=1), an area information value (AREA=1), a bad block information value (BADBLK=0), and a preliminary area value (RSV=0) are included in common.

The information processing circuit MNGER respectively writes the write data WDATA0, 1, 2, and 3 into four physical addresses of the non-volatile memory device. Here, for example, the information processing circuit MNGER reads write physical addresses NXPAD stored in 16 to 19 of the entry number ENUM in the write physical address table NXPADTBL2 and assigns these addresses to logical addresses according to the writing requests WQ0 to WQ3. Here, it is assumed that the write physical address values (NXPAD) are “2800000,” “2800001,” “2800002,” and “2800003.” The information processing circuit MNGER respectively assigns these to the address “800000,” the address “800001,” the address “800002,” and the address “800003” of the logical address LAD.

According to the write physical address values (NXPAD), the information processing circuit MNGER performs writing into the non-volatile memory devices NVM10 to NVM17 through the arbitration circuit ARB and the memory control circuits NVCT10 to NVCT17. More specifically, to the address “2800000” of the physical address PAD of the non-volatile memory device, write data WDATA0 and a logical address value (LAD=“800000”) corresponding to the writing request WQ0 are written and 1 is written as a data validity flag DVF. To the address “2800001” of the physical address PAD of the non-volatile memory device, write data WDATA1 and a logical address value (LAD=“800001”) corresponding to the writing request WQ1 are written and 1 is written as a data validity flag DVF.

Also, to the address “2800002” of the physical address PAD of the non-volatile memory device, the information processing circuit MNGER writes write data WDATA2 and a logical address value (LAD=“800002”) corresponding to the writing request WQ2 and writes 1 as a data validity flag DVF. Similarly, to the address “2800003” of the physical address PAD of the non-volatile memory device, write data WDATA3 and a logical address value (LAD=“800003”) corresponding to the writing request WQ3 are written and 1 is written as a data validity flag DVF.

Finally, the information processing circuit MNGER updates the address conversion table LPTBL, which is stored in the random access memory RAM, through the memory control circuit RAMC. More specifically, to the address “800000” of the logical address LAD in the address conversion table LPTBL, a physical address value (PAD=“2800000”) and a validity flag value (CPVLD=1) are written. Also, to the address “800001” of the logical address LAD, a physical address value (PAD=“2800001”) and a validity flag value (CPVLD=1) are written. Similarly, to the address “800002” of the logical address LAD, a physical address value (PAD=“2800002”) and a validity flag value (CPVLD=1) are written. To the address “800003” of the logical address LAD, a physical address value (PAD=“2800003”) and a validity flag value (CPVLD=1) are written.

In FIG. 19B, a state after writing requests WQ4, WQ5, WQ6, WQ7, WQ8, and WQ9 are input into the control circuit MDLCT0 by the information processing device CPU_CP after time T1 is illustrated. More specifically, an address, data, and a validity flag stored into the address conversion table LPTB and the non-volatile memory device at time T2 that is after data of these writing requests is written into the second physical address area PRNG2 of the non-volatile memory device are illustrated.

The writing request WQ4 includes a logical address value (LAD=“800000”), a data writing instruction (WRT), a sector count value (SEC=1), and write data (DATA4). The writing request WQ5 includes a logical address value (LAD=“800001”), a data writing instruction (WRT), a sector count value (SEC=1), and write data (DATA5). The writing request WQ6 includes a logical address value (LAD=“800004”), a data writing instruction (WRT), a sector count value (SEC=1), and write data (DATA6). The writing request WQ7 includes a logical address value (LAD=“800005”), a data writing instruction (WRT), a sector count value (SEC=1), and write data (DATA7). The writing request WQ8 includes a logical address value (LAD=“800002”), a data writing instruction (WRT), a sector count value (SEC=1), and write data (DATA8). The writing request WQ9 includes a logical address value (LAD=“800003”), a data writing instruction (WRT), a sector count value (SEC=1), and write data (DATA9).

When the writing requests WQ4, WQ5, WQ6, WQ7, WQ8, and WQ9 are input into the control circuit MDLCT0, the interface circuit HOST_IF transfers these writing requests to the buffer BUF0. Then, the information processing circuit MNGER serially reads the writing requests WQ4, WQ5, WQ6, WQ7, WQ8, and WQ9 stored in the buffer BUF0. Then, according to the data format illustrated in FIG. 12A, the information processing circuit MNGER generates write data WDATA4, 5, 6, 7, 8, and 9 for the non-volatile memory device which data respectively correspond to the writing requests WQ4, 5, 6, 7, 8, and 9.

The write data WDATA4 includes main data MDATA4, which includes the write data DATA4, and redundant data RDATA4 thereof. The write data WDATA5 includes main data MDATA5, which includes the write data DATA5, and redundant data RDATA5 thereof. The write data WDATA6 includes main data MDATA6, which includes the write data DATA6, and redundant data RDATA6 thereof. The write data WDATA7 includes main data MDATA7, which includes the write data DATA7, and redundant data RDATA7 thereof. The write data WDATA8 includes main data MDATA8, which includes the write data DATA8, and redundant data RDATA8 thereof. The write data WDATA9 includes main data MDATA9, which includes the write data DATA9, and redundant data RDATA9.

The redundant data RDATA4, 5, 6, 7, 8, and 9 respectively include ECC codes ECC 4, 5, 6, 7, 8, and 9 generated by the information processing circuit MNGER with utilization of the write data DATA4, 5, 6, 7, 8, and 9. In addition, a data inversion flag value (INVFLG=0), a writing flag value (WTFLG=0), an ECC flag value (ECCFLG=0), a state information value (STATE=1), an area information value (AREA=1), a bad block information value (BADBLK=0), and a preliminary area value (RSV=0) are included in common.

The information processing circuit MNGER respectively writes the write data WDATA4, 5, 6, 7, 8, and 9 into six physical addresses of the non-volatile memory device. Here, the information processing circuit MNGER refers to the address conversion table LPTBL, which is stored in the random access memory RAM, through a memory control circuit RAMC and reads various kinds of information corresponding to the writing requests WQ4, 5, 6, 7, 8, and 9. More specifically, a physical address PAD and a validity flag CPVLD are read from each of the address “800000,” the address “800001,” the address “800004,” the address “800005,” the address “800002,” and the address “800003” of the logical address LAD in the address conversion table LPTBL.

In the address conversion table LPTBL in FIG. 19A, a physical address value (PAD) is “2800000” and a validity flag value (CPVLD) is 1 at the address “800000” of the logical address LAD. Along with the writing request WQ4 to the address “800000” of the logical address LAD, it is necessary to invalidate the already-written data of the physical address. Thus, the information processing circuit MNGER sets a validity flag DVF at the address “2800000” of the physical address PAD to 0 (201 in FIG. 19A to 211 in FIG. 19B). Similarly, a physical address value (PAD) is “2800001” and a validity flag value (CPVLD) is 1 at the address “800001” of the logical address LAD in FIG. 19A. Along with the writing request WQ5, it is necessary to invalidate the already-written date of the physical address. Thus, the information processing circuit MNGER sets a validity flag DVF at the address “2800001” of the physical address PAD to 0 (202 in FIG. 19A to 212 in FIG. 19B).

On the other hand, in the address conversion table LPTBL in FIG. 19A, a physical address value (PAD) is 0 and a validity flag value (CPVLD) is 0 at the address “800004” of the logical address LAD associated with the writing request WQ6. It is understood that no physical address PAD is assigned to the address “800004” of the logical address LAD. Similarly, a physical address value (PAD) is 0 and a validity flag value (CPVLD) is 0 at the address “800005” of the logical address LAD associated with the writing request WQ7. It is understood that no physical address PAD is assigned to the address “800005” of the logical address LAD.

Also, in the address conversion table LPTBL in FIG. 19A, a physical address value (PAD) is “2800002” and a validity flag value (CPVLD) is 1 at the address “800002” of the logical address LAD. It is necessary to invalidate the already-written physical address along with the writing request WQ8 to the address “800002” of the logical address LAD. Thus, the information processing circuit MNGER sets a validity flag value (DVF) at the address “2800002” of the physical address PAD to 0 (203 in FIG. 19A to 213 in FIG. 19B). Similarly, a physical address value (PAD) is “2800003” and a validity flag value (CPVLD) is 1 at the address “800003” of the logical address LAD in FIG. 19A. Along with the writing request WQ9, it is necessary to invalidate already-written data at the physical address. Thus, the information processing circuit MNGER sets a validity flag value (DVF) at the address “2800003” of the physical address PAD to 0 (204 in FIG. 19A to 214 in FIG. 19B).

Then, according to the writing requests WQ4 to WQ9, the information processing circuit MNGER reads write physical addresses NXPAD stored in 20 to 25 of the entry number ENUM in the write physical address table NXPADTBL2 and assigns these to logical addresses. Here, it is assumed that the write physical address values (NXPAD) are “2800004,” “2800005,” “2800006,” “2800007,” “2800008,” and “2800009.” Then, these values are respectively assigned to the address “800000,” the address “800001,” the address “800004,” the address “800005,” the address “800002,” and the address “800003” of the logical address LAD.

Then, according to the assignment of these physical addresses, the information processing circuit MNGER performs writing on the non-volatile memory devices NVM10 to NVM17 through the arbitration circuit ARB and the memory control circuits NVCT10 to NVCT17. More specifically, to the address “2800004” of the physical address PAD of the non-volatile memory device NVM, write data WDATA4 and a logical address value (LAD=“800000”) corresponding to the writing request WQ4 are written and 1 is written into a data validity flag DVF. To the address “2800005” of the physical address PAD, write data WDATA5 and a logical address value (LAD=“800001”) corresponding to the writing request WQ5 are written and 1 is written into a data validity flag DVF.

Similarly, to the address “2800006” of the physical address PAD, write data WDATA6 and a logical address value (LAD=“800004”) corresponding to the writing request WQ6 are written and 1 is written into a data validity flag DVF. To the address “2800007” of the physical address PAD, write data WDATA7 and a logical address value (LAD=“800005”) corresponding to the writing request WQ7 are written and 1 is written into a data validity flag DVF. To the address “2800008” of the physical address PAD, write data WDATA8 and a logical address value (LAD=“800002”) corresponding to the writing request WQ8 are written and 1 is written into a data validity flag DVF. To the address “2800009” of the physical address PAD, write data WDATA9 and a logical address value (LAD=“800003”) corresponding to the writing request WQ9 are written and 1 is written as a data validity flag DVF. Finally, the information processing circuit MNGER updates the address conversion table LPTBL, which is stored in the random access memory RAM, into a state illustrated in FIG. 19B through the memory control circuit RAMC.

### <First Reading Operation of Memory Module (Semiconductor Device)>

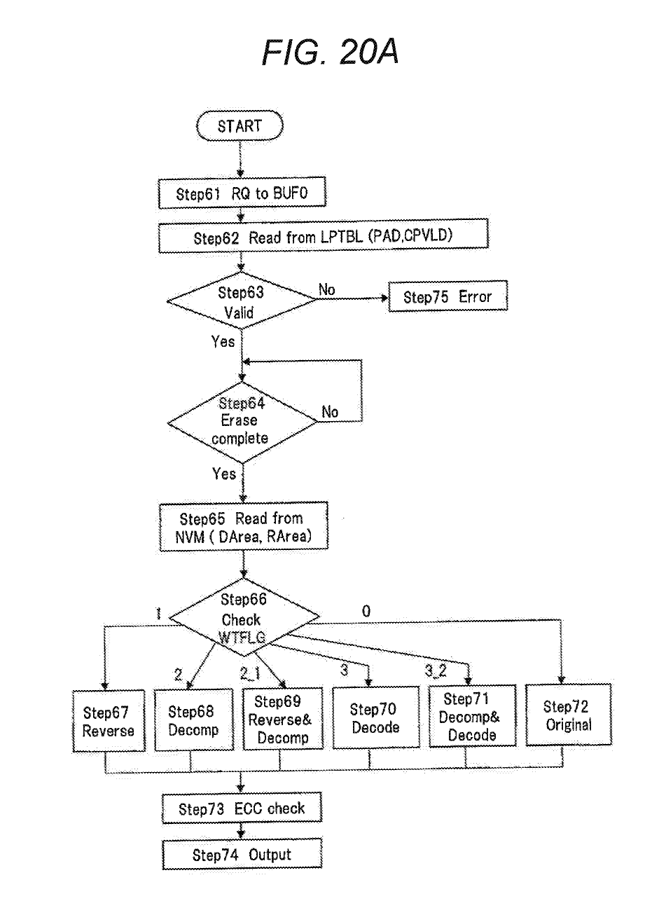

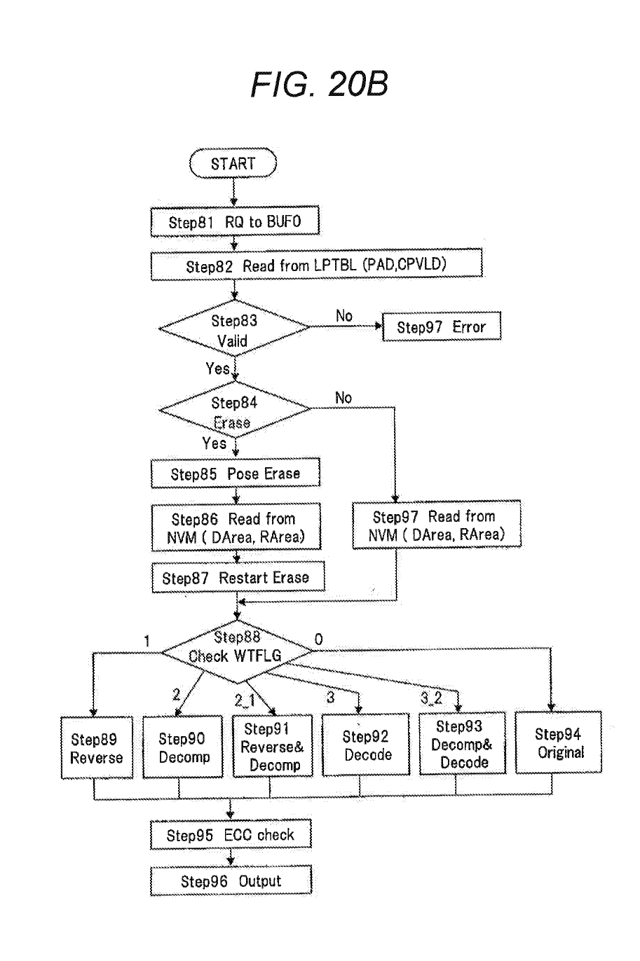

FIG. 20A is a flowchart illustrating an example of a data reading operation performed by the memory module NVMMD0 in a case where a reading request (RQ) is input into the memory module NVMMD0 by the information processing device CPU_CP in FIG. 1. First, the information processing device CPU_CP inputs a reading request (RQ) including a logical address value (such as LAD=0), a data-reading instruction (RD), and a sector count value (SEC=1) into the control circuit MDLCT. In response to this input, the interface circuit HOST_IF extracts clock information embedded in the reading request (RQ), converts the reading request (RQ), which is converted into serial data, into parallel data, and transfers this to the buffer BUF0 and the information processing circuit MNGER (Step 61).

Then, the information processing circuit MNGER decodes the logical address value (LAD=0), the data-reading instruction (RD), and the sector count value (SEC=1), refers to the address conversion table LPTBL stored in the random access memory RAM, and reads various kinds of information. More specifically, in the address conversion table LPTBL, a physical address value PAD (such as PAD=0) stored at an address 0 of the logical address LAD, and a validity flag CPVLD and a layer number LYC corresponding to the physical address PAD are read (Step 62). Then, it is checked whether the read validity flag CPVLD is 1 (Step 63).

When the validity flag CPVLD is 0, the information processing circuit MNGER recognizes that no physical address PAD is assigned to the logical address value (LAD=0). In this case, it is not possible to read data from the non-volatile memory device NVM. Thus, through the interface circuit HOST_IF, the information processing circuit MNGER informs the information processing device CPU_CP of generation of an error (Step 75).

The memory module NVMMD0 of this embodiment includes a normal mode, an erasure priority mode, and a reading priority mode. Although it is not specifically limited, these modes are set into the memory module NVMMD0 by the information processing device CPU_CP. In the flow in FIG. 20A, a case where the memory module NVMMD0 is in the normal mode or the erasure priority mode is illustrated. Also, as described with reference to FIG. 11A to FIG. 11C, it is designated by dummy chain memory array designation information XYDMC of SSD configuration information (SDCFG) to set a dummy chain memory array DCY in a periphery of the erasure area. A writing method is designated by writing method selection information WRTFLG.

When it is determined in Step 63 that the read validity flag CPVLD is 1, batch-erasure in the erasure area is performed in Step 64. When the batch-erasure in the erasure area is completed in Step 64, Step 65 is executed next. Note that the erasure area that is erased in Step 64 is arbitrated by the arbitration circuit ARB in such a manner as to be an area different from an area where reading is performed. Also, the erasure area the batch-erasure of which is performed here is an area excluding the dummy chain memory array DCY designated by the dummy chain memory array designation information XYDMC. That is, an erasing operation is not performed with respect to the dummy chain memory array DCY provided in a manner physically adjacent to the erasure area where the batch-erasure is performed.

When the information processing circuit MNGER determines that the logical address value (LAD=0) corresponds to the physical address value PAD (PAD=0), Step 65 is executed after the erasure operation in Step 64 is completed. When the physical address value PAD (PAD=0) corresponding to the logical address value (LAD=0) is an address in the first physical address area PRNG1, the physical address value PAD (PAD=0), a physical address value CPAD (CPAD=0), and a layer number LYC are converted into the chip address CHIPA, the bank address BK, the row address ROW, and the column address COL of the non-volatile memory device NVM illustrated in FIG. 17A. On the other hand, when the physical address value (PAD=0) corresponding to the logical address value (LAD=0) is an address in the second physical address area PRNG2, the physical address value PAD (PAD=0) and the physical address value CPAD (CPAD=0) are converted into the chip address CHIPA, the bank address BK, the row address ROW, and the column address COL of the non-volatile memory device NVM illustrated in FIG. 17B. Moreover, the chip address CHIPA, the bank address BK, the row address ROW, and the column address COL of the non-volatile memory device NVM which addresses are converted from the physical address value PAD (PAD=0), the physical address value CPA, and the layer number LYC are input into the non-volatile memory device NVM through the arbitration circuit ARB and the memory control circuit NVCT. Then, according to the operation illustrated in FIG. 17C, the data (DATA0) stored in the non-volatile memory device NVM is read. The data (DATA0) includes main data MDATA0 stored in a main data area of the non-volatile memory device NVM and redundant data RDATA0 stored in a redundant data area thereof. The redundant data RDATA0 includes a writing flag WTFLG and an ECC code ECC0 (Step 65).

Then, the information processing circuit MNGER reads a logical address area LRNG in SSD configuration information (SDCFG) stored in the non-volatile memory NVM. Then, it is checked to which logical address area LRNG the logical address value (LAD=0) belongs. Moreover, a value of the writing flag WTFLG included in the read redundant data RDATA0 is checked in Step 66. That is, as described with reference to FIG. 12A (and FIG. 11A to FIG. 11C), a value of the writing flag WTFLG indicates a writing method of when writing is performed, the value being one of 0 to 3 or one of combinations thereof. In Step 66, a writing method of when writing is performed is determined.

When the value of the writing flag WTFLG is 0 as a result of the checking, Step 72 is executed next. When the value is 1, Step 67 is executed next. When the value is 2, Step 68 is executed next. When the value is 3, Step 70 is executed next. Similarly, when the value of the writing flag WTFLG is 2_1, Step 69 is executed next. When the value is 3_2, Step 71 is executed next.

When the writing flag WTFLG is 0, data is written into the non-volatile memory device NVM without processing. Thus, in Step 72, the read data (main data MDATA0) is sent to Step 73. When the writing flag WTFLG is 1, data is inverted when being written. Thus, in Step 67, the read data (main data MDATA0) is inverted and sent to Step 73. Also, when the writing flag WTFLG is 2, data is compressed and written. Thus, in Step 68, the read data (main data MDATA0) is decompressed (Decomp) and sent to Step 73. When the writing flag WTFLG is 3, data is coded (code) and written. Thus, in Step 70, the read data (main data MDATA0) is decoded (Decode) and sent to Step 73.

When the writing flag WTFLG is 2_1, the data is compressed, inverted, and written. Thus, in Step 69, the read data (main data MDATA0) is inverted, decompressed (Decomp), and sent to Step 73. When the writing flag WTFLG is 3_2, the read data is coded and compressed. Thus, in Step 71, the read data (main data MDATA0) is decompressed (Decomp), decoded (Decode), and sent to Step 73.

In such a manner, processing corresponding to a value of the read writing flag WTFLG is executed in Step 67 to Step 72 and main data (MDATA0) and an ECC code (CCO) to which the processing corresponding to the writing method is applied are acquired. In Step 73, the information processing circuit MNGER checks whether there is an error in the main data (MDATA) by using the ECC code (ECC0). When there is an error, the error is corrected. When there is no error or when the error is corrected, data without an error is transferred to the information processing device CPU_CP through the interface circuit HOST_IF (Step 74).

Although, it is not specifically limited, in a case of performing a reading operation, the reading operation is not executed on a dummy chain memory array DCY arranged in a periphery (physically adjacent area) of an area to be an object of the reading operation (erasure area). Accordingly, it becomes possible to reduce the number of cells selected in the reading operation and to increase speed of the reading operation.

### <Second Reading Operation of Memory Module (Semiconductor Device)>

FIG. 20B is a flowchart illustrating a different example of a reading operation. Since FIG. 20B is similar to FIG. 20A, a different point will be mainly described.

In FIG. 20B, Step 81 to Step 83, and Step 97 correspond to Step 61 to Step 63, and Step 75 in FIG. 20A. Also, in FIG. 20B, Step 88 to Step 96 correspond to Step 66 to Step 96 in FIG. 20A. Thus, a description of these steps is omitted.

In FIG. 20B, a case where a reading priority mode is set with respect to the memory module NVMMD0 is illustrated. In the reading operation, when validity is determined in Step 83, it is determined in Step 84 whether the erasing operation is executed. When it is determined in Step 84 that the erasing operation is executed, the erasing operation is temporarily stopped in Step 85 since the reading priority mode is set. After the erasing operation is temporarily stopped in Step 85, data (DATA1) stored in non-volatile memory device NVM is read in Step 86 similarly to Step 65 illustrated in FIG. 20A. The data (DATA1) includes main data MDATA1 stored into a main data area of the non-volatile memory device NVM and redundant data RDATA1 stored in a redundant data area thereof. Moreover, the redundant data RDATA1 includes a writing flag WTFLG and an ECC code ECC1.

After the main data MDATA1 and the redundant data RDATA1 are read, the erasing operation that is temporarily stopped is resumed in Step 87. Also, when it is determined in Step 84 that the erasing operation is not executed, the main data (MDATA1) and the redundant data (RDATA1) are read in Step 97 similarly to Step 86.

The main data (MDATA1) and the redundant data (RDATA1) read in Step 86 or Step 97 are sent to Step 88 and processing similar to the processing described in FIG. 20A is performed.

In this embodiment, since the erasing operation is temporarily stopped, it becomes possible to reduce response time of the reading operation. Also, in this embodiment, in a case of performing a reading operation, the reading operation is not executed on a dummy chain memory array DCY arranged in a periphery (physically adjacent area) of an area to be an object of the reading operation (erasure area). Accordingly, it becomes possible to reduce the number of cells selected in the reading operation and to increase speed of the reading operation.

Also, an example of setting the memory module NVMMD0 to the reading priority mode has been described. However, alternatively, a reading priority command may be prepared as a command to be supplied to the memory module NVMMD0. In this case, the memory module NVMMD0 is configured in such a manner that the flow in FIG. 20B is executed when the reading priority command is supplied.

### <First Writing Operation of Memory Module (Semiconductor Device) According to Writing Method Selection Information>

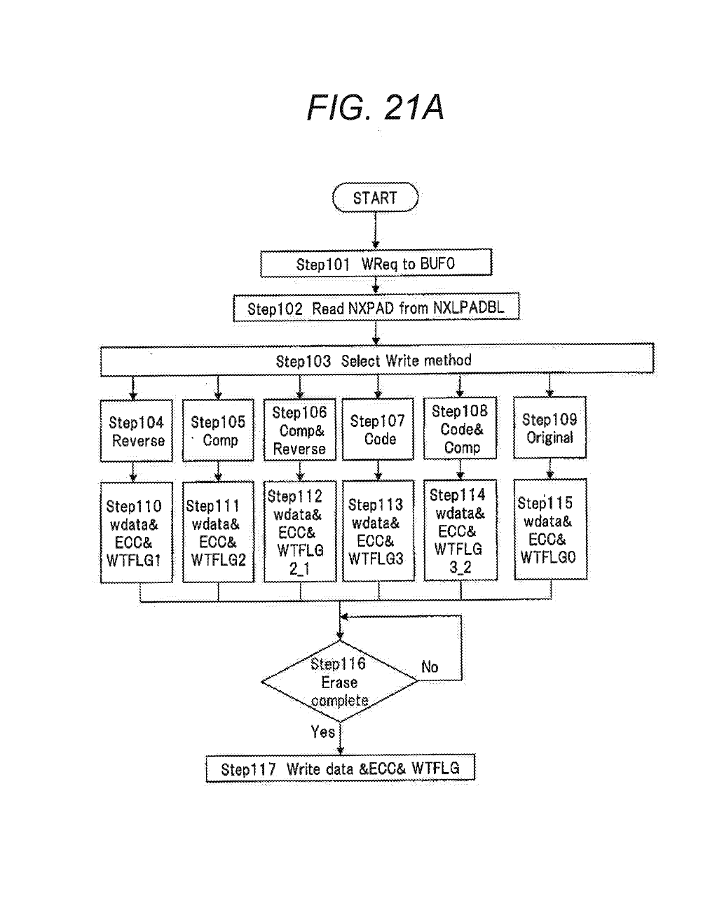

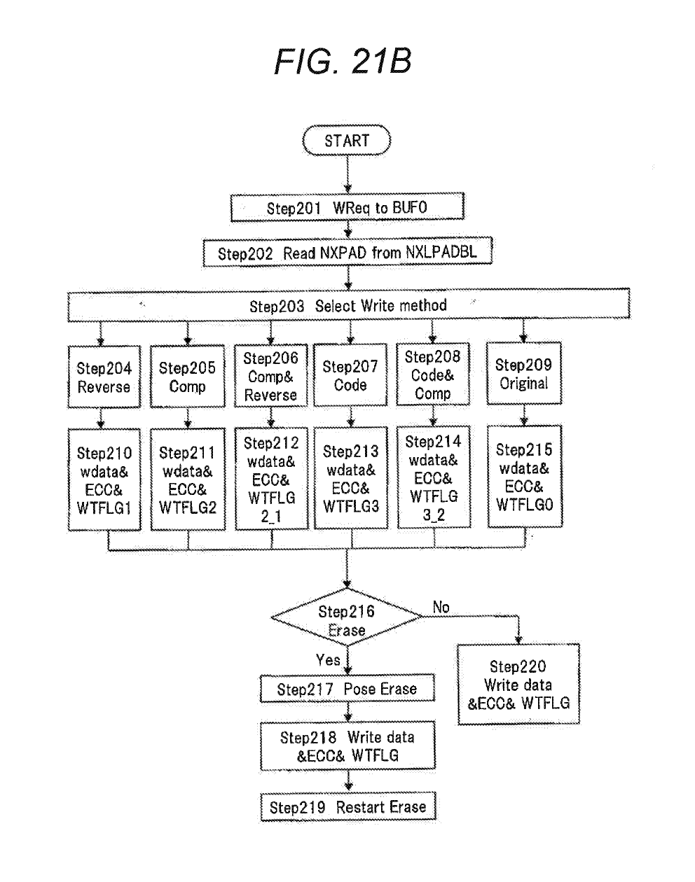

FIG. 21A is a flowchart illustrating an example of a writing operation of a memory module according to writing method selection information (WRTFLG) with the SSD configuration information (SDCGF) illustrated in FIG. 11A to FIG. 11C as an example. Although it is not specifically limited, bit data of “1” is expressed in a memory cell in a set state and bit data of “0” is expressed in a memory cell in a reset state. Also, in FIG. 21A, a writing operation in a case where a writing operation performed in response to a normal writing command or a writing operation of when a mode is set to an erasure priority mode is illustrated.

First, a writing request (WQ01) including a logical address value (LAD), a data writing instruction (WRT), a sector count value (SEC=1), and 512-byte write data (DATA0) is input into the information processing circuit MNGER by the information processing device CPU_CP through the interface circuit HOST_IF and stored into the buffer BUF0 (Step 101). The information processing circuit MNGER uses the address map range (ADMAP) stored in the random access memory RAM and determines whether the logical address value (LAD) is a logical address value in the logical address area LRNG1 or a logical address value in the logical address area LRNG2. Also, writing method selection information WRTFLG is read. Moreover, a write physical address NXPAD corresponding to a logical address is read from the write physical address table NXLPADBL (Step 102).

According the read writing method selection information WRTFLG, the information processing circuit MNGER selects a writing method in Step 103. That is, according to contents of the writing method selection information WRTFLG, one of Step 104 to Step 109 is selected. When the writing method selection information WRTFLG is 0, Step 109 is selected as a method of writing. In this case, write data is prepared as write data wdata without being processed and ECC data that is based on the write data wdata is generated in Step 115. Also, in Step 115, a value of the writing flag WTFLG is generated as 0 (WTFLG 0). When the writing method selection information WRTFLG is 1, Step 104 is selected as a writing method. In this case, in Step 104, write data is inverted. The inverted data is prepared as write data wdata in Step 110 and ECC data that is based on the write data wdata is generated. Also, in Step 110, a value of the writing flag WTFLG is generated as 1 (WTFLG 1).

When the writing method selection information WRTFLG is 2, Step 105 is selected. In this case, write data is compressed (Comp) in Step 105. In Step 111, the compressed write data is set as write data wdata and ECC data that is based on the write data wdata is generated. Moreover, in Step 111, a value of the writing flag WTFLG is generated as 2 (WTFLG 2). When the writing method selection information WRTFLG is 3, Step 107 is selected. In this case, write data is coded (Code). The coded write data is set as write data wdata in Step 113 and ECC data that is based on the write data wdata is generated. Also, in Step 113, a value of the writing flag WTFLG is generated as 3 (WTFLG 3).

When the writing method selection information WRTFLG is 2_1, Step 106 is selected. In this case, write data is compressed and inverted in Step 106. The compressed and inverted write data is set as write data wdata in Step 112 and ECC data that is based on the write data wdata is generated. Also, in Step 112, a value of the writing flag WTFLG is generated as 2_1 (WTFLG 2_1). When the writing method selection information WRTFLG is 3_2, Step 108 is selected. In this case, write data is coded and compressed in Step 108. The coded and compressed write data is set as write data wdata in Step 114 and ECC data that is based on the write data wdata is generated. Also, in Step 114, a value of the writing flag WTFLG is generated as 3_2 (WTFLG 3_2).

Since each writing method has been described with reference to FIG. 12A (and FIG. 11A to FIG. 11C), a detail description thereof is omitted here.

In a normal writing command or in an erasure priority mode, priority is given to a batch-erasing operation on an erasure area. Thus, after each of Step 110 to Step 115, it is determined in Step 116 whether batch-erasure in the erasure area is completed. In Step 116, when the batch-erasure in the erasure area is not completed, writing of data (write data wdata, ECC data, and writing flag WTFLG) generated in each of Step 110 to Step 115 is waited for. That is, in Step 117 after the batch-erasure in the erasure area is completed, the write data wdata, the ECC data, and the writing flag WTFLG are written into the write physical address NXPAD. The write data wdata is included as main data MDATA. The ECC data and the writing flag WTFLG are included in redundant data RDATA. The main data MDATA and the redundant data RDATA are respectively written into a main data area DArea and a redundant data RDATA in the physical address NXPAD.

The writing operation is performed, for example, on an erasure area where batch-erasure is performed. In this case, writing is not performed on a dummy chain memory array DCY arranged in a periphery (physically adjacent area) of the erasure area. Thus, it becomes possible to increase speed of the writing operation.

### <Second Writing Operation of Memory Module (Semiconductor Device) According to Writing Method Selection Information>

FIG. 21B is a flowchart illustrating a different example of a writing operation. Since FIG. 21B is similar to FIG. 21A, a different point will be mainly described.

In FIG. 21B, Step 201 to Step 215 correspond to Step 101 to Step 115 in FIG. 21A. Also, in FIG. 21B, Step 218 and Step 220 correspond to Step 117 in FIG. 21A. Thus, a description of these steps will be omitted.

In FIG. 21B, a case where the memory module NVMMD0 is set to a writing priority mode is illustrated. In a writing operation, it is determined in Step 216 whether an erasing operation is executed. When it is determined that the erasing operation is executed, the erasing operation is temporarily stopped in Step 217 since the writing priority mode is set. After the erasing operation is temporarily stopped in Step 217, data is written in Step 218 similarly to Step 117 illustrated in FIG. 21A. After the data is written, in Step 219, the temporarily stopped erasing operation is resumed. Also, in Step 216, when it is determined that the erasing operation is not executed, data is written in Step 220 similarly to Step 117 illustrated in FIG. 21A.

In this embodiment, an erasing operation is temporarily stopped. Thus, it becomes possible to reduce response time of the writing operation. Also, in this embodiment, in a case of performing a writing operation, the writing operation is not executed on a dummy chain memory array DCY arranged in a periphery (physically adjacent area) of an area to be an object of the writing operation (erasure area). Accordingly, it becomes possible to reduce the number of cells selected in the writing operation and to increase speed of the writing operation.

Also, an example of setting the memory module NVMMD0 to the writing priority mode has been described. However, alternatively, a writing priority command may be prepared as a command supplied to the memory module NVMMD0. In this case, the memory module NVMMD0 is configured in such a manner that the flow in FIG. 21B is executed when the writing priority command is supplied.

### <Wear-Leveling Method>

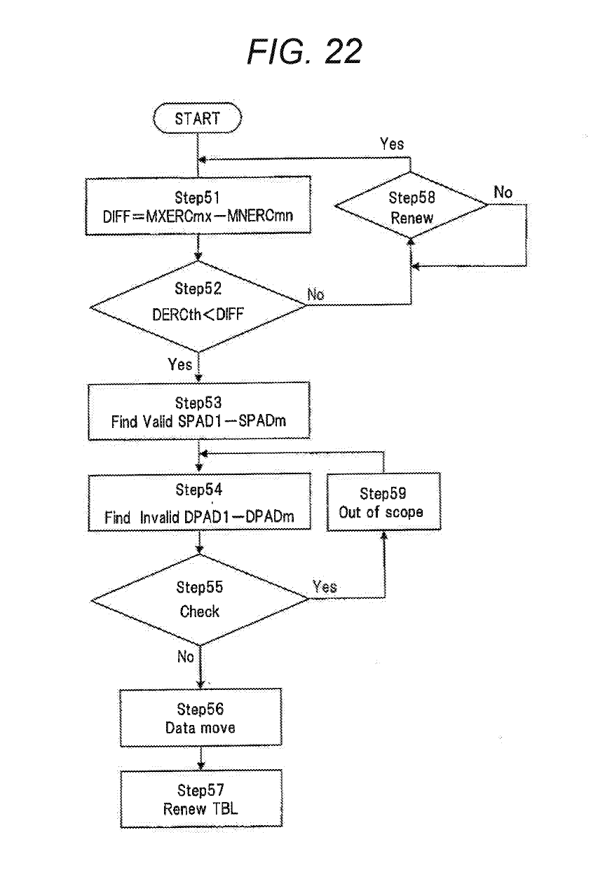

FIG. 22 is a flowchart illustrating an example of a wear leveling method executed by the information processing circuit MNGER in FIG. 2 in addition to a case of FIG. 16. As illustrated in FIG. 9A and FIG. 9B, the information processing circuit MNGER manages N/2 entries from the entry numbers 0 to (N/2−1) in the write physical address table NXPADTBL as a write physical address table NXPADTBL1 and the remaining N/2 entries from the entry numbers (N/2) to N as a write physical address table NXPADTBL2. As illustrated in FIG. 16, dynamic wear leveling, which is performed by an update of the write physical address table NXPADTBL by utilization of the physical segment table PSEGTBL1 in FIG. 8A, is a dynamic leveling method of the number of times of erasure with respect to physical addresses in an invalid state.

However, since the dynamic wear leveling is performed on physical addresses in the invalid state, there is a case where a difference between the number of times of erasure of the physical addresses in the invalid state and the number of times of erasure of physical addresses in a valid state is gradually increased as a whole. For example, when writing is performed at a certain logical address (physical address corresponding thereto) and the physical address becomes a valid state, in a case where a writing instruction is not generated with respect to the logical address (physical address corresponding thereto) for a long period after that, the physical address is excluded from an object of the wear leveling for a long period. Thus, as illustrated in FIG. 22, the information processing circuit MNGER in FIG. 2 executes a static leveling method (static wear leveling) of the number of times of erasure to control a variation in the number of times of erasure of physical addresses in the invalid state and the number of times of erasure of physical addresses in the valid state.

The information processing circuit MNGER performs the static leveling method of the number of times of erasure illustrated in FIG. 22 in each of the first physical address area PRNG1 and the second physical address area PRNG2 in the address range map (ADMAP) in FIG. 13. First, the information processing circuit MNGER detects a maximum value MXERCmx in the maximum number of times of erasure MXERC in the physical segment table PSEGTBL1 related to an invalid physical address (FIG. 8A) and a minimum value MNERCmn in the minimum number of times of erasure MNERC in the physical segment table PSEGTBL2 related to a valid physical address (FIG. 8B). Then, a difference between the maximum value MXERCmx and the minimum value MNERCmn (=MXERCmx−MXERCmn) DIFF is calculated (Step 51).

In Step 52, the information processing circuit MNGER sets a threshold DERCth for a difference between the number of times of erasure of the physical addresses in the invalid state and the number of times of erasure of the physical addresses in the valid state and compares the threshold DERCth with the difference in the number of times of erasure DIFF. When the difference in the number of times of erasure DIFF is larger than the threshold DERCth, the information processing circuit MNGER performs Step 53 for leveling of the number of times of erasure. When the difference is smaller, Step 58 is performed. In Step 58, the information processing circuit MNGER determines whether the physical segment table PSEGTBL1 or PSEGTBL2 is updated. When the update is performed, the difference in the number of times of erasure DIFF is calculated again in Step 51. When neither of the physical segment tables is updated, Step 58 is performed again.

In Step 53, the information processing circuit MNGER selects m physical addresses SPAD1 to SPADm in ascending order from the smallest number of times of erasure in the minimum number of times of erasure MNERC in the physical segment table PSEGTBL2 related to the valid physical address. In Step 54, the information processing circuit MNGER selects, as candidates, m physical addresses DPAD1 to DPADm in descending order from the largest number of times of erasure in the maximum number of times of erasure MXERC in the physical segment table PSEGTBL1 related to the invalid physical address.

In Step 55, the information processing circuit MNGER checks whether the physical addresses DPAD1 to DPADm, which are selected as the candidates, are registered in the write physical address table NXPADTBL. When any of the physical addresses DPAD1 to DPADm, which are selected as the candidates, is registered in the write physical address table NXPADTBL, the registered one of the physical addresses DPAD1 to DPADm is excluded from the candidates in Step 59 and supplementation of the candidate is performed in Step 54. When the selected physical addresses DPAD1 to DPADm are not registered in the written physical address table NXPADTBL, Step 56 is performed.

In Step 56, the information processing circuit MNGER moves data at the physical addresses SPAD1 to SPADm in the non-volatile memory device to the physical addresses DPAD1 to DPADm. In Step 57, the information processing circuit MNGER updates all tables to be updated due to movement of the data at the physical addresses SPAD1 to SPADm into the physical addresses DPAD1 to DPADm.

By utilization of such static wear leveling along with the dynamic wear leveling illustrated in FIG. 16, it becomes possible to perform leveling of the number of times of erasure in the whole of the non-volatile memory devices NVM10 to NVM17. Note that in this example, an example of moving data of m physical addresses is illustrated. However, a value of m can be programmed by the information processing circuit MNGER according to intended performance. When the number of registrations in the write physical address table NXPADTBL is N, the value is set in such a manner that 1<m<N, for example.

### <First Pipeline Writing Operation>

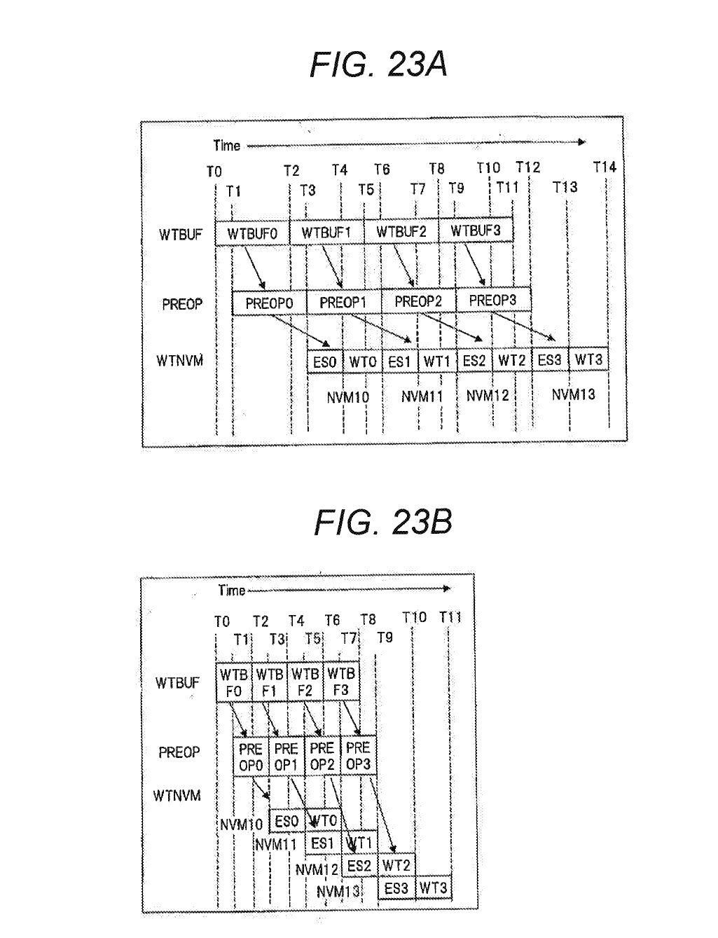

FIG. 23A is a view illustrating an example of a data-writing operation executed in a pipeline manner in an inner part of a memory module NVMMD0 when writing requests are serially generated for the memory module NVMMD0 by the information processing device CPU_CP in FIG. 1. Although it is not specifically limited, write data of N×512 bytes can be stored into each of the buffers BUF0 to BUF3 in the control circuit MDLCT0 in FIG. 2.

In buffer transfer operations WTBUF0, 1, 2, and 3 illustrated in FIG. 23A, writing requests WQ are transferred to the buffers BUF0, 1, 2, and 3. In previous preparation operations PREOP0, 1, 2, and 3, previous preparation operations to write write data which is transferred to the buffer BUF0, 1, 2, and 3 into the non-volatile memory device NVM are performed. In data-writing operations WTNVM0, 1, 2, and 3, the write data stored in the buffers BUF0, 1, 2, and 3 is written into the non-volatile memory device NVM.

As illustrated in FIG. 23A, the buffer transfer operations WTBUF0, 1, 2, and 3, the previous preparation operations PREOP0, 1, 2, and 3, and data-writing operations WTNVM0, 1, 2, and 3 are executed by a pipeline operation performed by the control circuit MDLCT0. Accordingly, it becomes possible to increase writing speed. More specifically, a pipeline operation in the following is performed.

In the interface circuit HOST_IF, N writing requests (WQ [1] to WQ [N]) generated in a period from time T0 to T2 are first transferred to the buffer BUF0 (WTBUF0). When it becomes impossible to store write data into the buffer BUF0, N writing requests (WQ [N+1] to WQ [2N]) generated in a period from time T2 to T 4 are transferred to the buffer BUF1 (WTBUF1). When it becomes impossible to store write data into the buffer BUF1, N writing requests (WQ [2N+1] to WQ [3N]) generated in a period from time T4 to T6 are transferred to the buffer BUF2 (WTBUF2). When it becomes impossible to store write data into the buffer BUF2, N writing requests (WQ [3N+1] to WQ [4N]) generated in a period from time T6 to T8 are transferred to the buffer BUF3 (WTBUF3).

In the period from time T1 to T3, the information processing circuit MNGER performs previous preparation (PREOP0) to write the write data stored in the buffer BUF0 into the non-volatile memory device NVM. Main operation contents of the previous preparation operation PREOP0 performed by the information processing circuit MNGER will be described in the following. Note that the other previous preparation operations PREOP1, 2, and 3 are operations similar to the previous preparation operation PREOP0.

(1) By utilization of a value of a logical address LAD included in the writing requests (WQ [1] to WQ [N]), a physical address PAD is read from the address conversion table LPTBL. When necessary, values of validity flags (CPVLD, PVLD, and DVF) of the physical address PAD are set to 0 and data is invalidated.

(2) The address conversion table LPTBL is updated.

(3) A write physical address NXPAD stored in the write physical address table NXPADTBL is read and the logical address LAD included in the writing requests (WQ [1] to WQ [N]) is assigned to the write physical address NXPAD.

(4) The physical segment table PSEGTBL is updated.

(5) The physical address table PADTBL is updated.

(6) The write physical address table NXPADTBL is updated for preparation for next writing.

Then, the information processing circuit MNGER writes the write data stored in the buffer BUF0 into the non-volatile memory device NVM in a period from time T3 to T5 (WTNVM0). In this case, a physical address of the non-volatile memory device NVM to which the data is written is identical to the value of the write physical address NXPAD in (3). The other data-writing operations WTNVM1, 2, and 3 are operations similar to the data-writing operation WTNVM0.

### <Second Pipeline Writing Operation>

FIG. 23B is a view illustrating a different example of a data-writing operation performed in a pipeline manner in an inner part of the memory module NVMMD0. Since FIG. 23B is similar to FIG. 23A, a different point will be mainly described.

In FIG. 23A, in a case of performing writing on the non-volatile memory device NVM, erasing operations (ES0, ES1, ES2, and ES3) and writing operations (WT0, WT1, WT2, and WT3) are successively performed. On the other hand, in FIG. 23B, an area to be an object of the erasing operation and an area to be an object of the writing operation are different. Thus, the erasing operation and the writing operation are pipelined in such a manner as to be overlapped temporally. For example, the non-volatile memories NVM10, NVM11, NVM12, and NVM13 are formed of different semiconductor chips. Accordingly, the erasing operations (ES1, ES2, and ES3) and the writing operations (WT0, WT1, and WT2) can be temporally overlapped with each other and speed of the writing operations can be increased.

### <First Layout of Non-Volatile Memory Device>

FIG. 24 is a schematic plan view of one memory array ARY in the non-volatile memory devices NVM10 to NVM17. In the drawing, a plurality of ∘-shapes filled with dots and blank ∘-shapes indicate chain memory arrays CY arranged in intersection points of word lines WL0 to WLk and bit lines BL0 to BLi. Each of the chain memory arrays CY is illustrated, for example, in FIG. 4 as a chain memory array CY1. As it is understood from FIG. 4, each chain memory array includes a plurality of phase-change memories. The plurality of phase-change memories is connected to each other in series between a corresponding word line WL and a corresponding bit line. Although it is not specifically limited, a plurality of phase-change memories Tcl0 to Tcln is formed in such a manner as to be laminated on a semiconductor substrate.

The plurality of chain memory arrays CY is two-dimensionally arranged in a matrix. In each row and each column in the matrix, a word line and a bit line are arranged and corresponding word line and bit line are connected to a chain memory array CY. In the drawing, a ∘-shape filled with dots (hereinafter, referred to as •-shape) indicates a chain memory array CY that does not store data (dummy chain memory array DCY) and a chain memory array CY of a ∘-shape indicates a chain memory array CY that stores data.

The plurality of chain memory arrays CY arranged in the matrix is divided into a plurality of areas during an erasing operation, a writing operation, and a reading operation based on dummy chain memory array designation information (XYDMC) stored in SSD configuration information (SDCFG). That is, when accessing the non-volatile memory devices NVM10 to NVM17 and performing the erasing operation, the writing operation, and the reading operation, the information processing circuit MNGER accesses these as a plurality of divided areas based on the dummy chain memory array designation information (XYDMC). An arrangement of s-shaped and ∘-shaped chain memory arrays CY in FIG. 24 indicates an arrangement of when the dummy chain memory array designation information (XYDMC) is 1_1_1. In the example in FIG. 24, chain memory arrays CY where data can be written, read, held, and erased are arranged in 8 rows×66 columns. In the drawing, a matrix of the chain memory arrays CY in 8 rows×66 columns is illustrated as a write area WT-AREA. That is, on a lower side of the drawing, write areas WT-AREA0 to WT-AREA7 are illustrated. Each of the write areas WT-AREA and WT-AREA 0 to 7 includes a main data area DArea where the main data MDATA is written and a redundant data area RArea where the redundant data RDATA is written. Also, in 8 rows×64 columns on a left side of the matrix of the chain memory arrays CY included in each write area, the main data area DArea is arranged and in 8 rows×2 columns on a right side thereof, the redundant data area RArea is arranged.

Accordingly, a plurality of areas WT-AREA each of which includes 8 rows×64 columns of ∘-shaped chain memory arrays CY and 8 rows×2 columns of chain memory arrays CY is configured on a memory array. In this embodiment, the area is an area to be erased in the erasing operation. Thus, the area can be seen as an erasure area. As described with reference to FIG. 11A to FIG. 11C, since the dummy chain memory array designation information (XYDMC) is 1_1_1, one dummy chain memory array DCY is arranged in each of a row (X) and a column (Y) adjacent to the write area WT-AREA on an outer side (outer periphery) of the write area WT-AREA. That is, a plurality of chain cell arrays CY that configures one row and one column adjacent to the write area WT-AREA is treated as a dummy chain cell array DCY (•-shape).

For example, when it is assumed that one chain cell array CY stores 1-byte data, data of 8×66=528 bytes can be written into one write area (erasure area). In this case, main data MDATA having 8×64=512 bytes is written into the main data area DArea and redundant data RDATA having 8×2=16 bytes is written into the redundant data area RArea. In this embodiment, the information processing circuit MNGER does not access a chain memory array DCY, which is set as a dummy chain memory array DCY, for the writing operation and the reading operation.

Next, a writing operation on the non-volatile memory device NVM10 in a case where writing requests WQ00, WQ01, WQ02, and WQ03 are serially input into the information processing circuit MNGER in FIG. 2 by the information processing device CPU_CP in FIG. 1 will be described. Although it is not specifically limited, the information processing circuit MNGER associates one physical address for each size of 512-byte main data MDATA and 16-byte redundant data RDATA and performs writing on the non-volatile memory devices NVM10 to NVM17.

Here, it is assumed that the writing request WQ00 includes a logical address value LAD0, a writing instruction WRT, a sector count value SEC1, and 512-byte write data WDATA0. Also, it is assumed that the writing request WQ01 includes a logical address value LAD1, a writing instruction WRT, a sector count value SEC1, and 512-byte write data WDATA1. Similarly, it is assumed that the writing request WQ02 includes a logical address value LAD2, a writing instruction WRT, a sector count value SEC1, and 512-byte write data WDATA2 and the writing request WQ03 includes a logical address value LAD3, a writing instruction WRT, a sector count value SEC1, and 512-byte write data WDATA3.

First, the information processing circuit MNGER refers to the write physical address table NXPADTBL1 and determines physical addresses PAD0, 1, 2, and 3 respectively corresponding to logical addresses LAD0, 1, 2, and 3 and the non-volatile memory device NVM10 into which data is written. Then, the information processing circuit MNGER generates redundant data RDATA0, 1, 2, and 3 respectively corresponding to the write data WDATA0, 1, 2, and 3. Subsequently, the information processing circuit MNGER serially issues, to the non-volatile memory device NVM10, an erasure instruction ERS0, a writing instruction WT0, an erasure instruction ERS1, a writing instruction WT1, an erasure instruction ERS2, a writing instruction WT2, an erasure instruction ERS3, and a writing instruction WT3 through the arbitration circuit ARB and the memory control circuit NVCT0.

The erasure instruction ERS0 includes a physical address PAD0, an erasure instruction ERS, and a sector count value SEC. The writing instruction WT0 includes a physical address PAD0, a writing instruction WT, a sector count value SEC1, 512-byte write data WDATA0, and redundant data RDATA0. The erasure instruction ERS1 includes a physical address PAD1, an erasure instruction ERS, and a sector count value SEC1. The writing instruction WT1 includes a physical address PAD1, a writing instruction WT, a sector count value SEC1, 512-byte write data WDATA1, and redundant data RDATA1. The erasure instruction ERS2 includes a physical address PAD2, an erasure instruction ERS, and a sector count value SEC1. The writing instruction WT2 includes a physical address PAD2, a writing instruction WT, a sector count value SEC1, 512-byte write data WDATA2, and redundant data RDATA2. The erasure instruction ERS3 includes a physical address PAD3, an erasure instruction ERS, and a sector count value SEC1. Similarly, the writing instruction WT3 includes a physical address PAD3, a writing instruction WT, a sector count value SEC1, 512-byte write data WDATA3, and redundant data RDATA3.

A write area WRT-AREA0 of the memory device NVM10 is selected by the physical address PAD0 of the erasure instruction ERS0. By the erasure instruction ERS, data of all memory cells included in all chain memory arrays CY in the write area WRT-AREA0 becomes “1” (Set state). That is, batch-erasure is performed. Then, by the physical address PAD0 and the writing instruction WT in the writing instruction WT0, a write area WRT-AREA0 of the memory device NVM10 is selected. Only data of “0” (Reset state) in the 512-byte write data WDATA0 is written into a memory cell in a chain memory array CY in the main data area DArea and only data of “0” (Reset state) in the 16-byte redundant data RDATA0 is written into a memory cell in a chain memory array CY in the redundant data area RArea.

By the physical address PAD1 of the erasure instruction ERS1, the write area WRT-AREA1 of the memory device NVM10 is selected. By the erasure instruction ERS, data of all memory cells included in all chain memory arrays CY in the write area WRT-AREA1 becomes “1” (Set state) (batch-erasure). The write area WRT-AREA1 of the memory device NVM10 is selected by the physical address PAD1 and the writing instruction WT of the writing instruction WT1. Only data of “0” (in Reset state) in the 512-byte write data WDATA1 is written into a memory cell in the chain memory array CY in the main data area DArea and only data of “0” (Reset state) in the 16-byte redundant data RDATA1 is written into a memory cell in the chain memory array CY in the redundant data area RArea.

Between each of the write areas WT-AREA0 and 1, the write areas WRT-AREA1 and 2, and the write areas WT-AREA2 and 3, a dummy chain memory array DCY is arranged. Thus, for example, when batch-erasure is performed in the write area WRT-AREA1, the dummy chain memory array DCY becomes a buffer area for the heat disturbance and can reduce an influence of the heat disturbance on the data in the write area WT-AREA0 or the write area WT-AREA2. In such a manner, since there is a dummy chain memory array DCY between the write areas WT-AREA, it is possible to reduce an influence of the heat disturbance. Thus, it is possible to write and hold data reliably in the write areas WT-AREA and to provide a highly reliable memory module.

Although it is not specifically limited, when the dummy chain memory array designation information (XYDMC) is set to 1_1_1, for example, on a right side (in FIG. 24) and an upper side (in FIG. 24) in the matrix of the write area (erasure area) WT-AREA, one row and one column of dummy chain memory arrays DCY are set. Obviously, the setting is not limited to the right side and the upper side. In the drawing, the write area WT-AREA is set to be repeatedly arranged on upper, lower, right, and left sides. One low and one column of dummy chain memory arrays DCY are set for each write area WT-AREA. Thus, it is possible to perform setting in such a manner that a dummy chain memory array DCY is arranged between the write areas WT-AREA.

Note that in this embodiment, since the 512-byte main data MDATA and the 16-byte redundant data RDATA are written into the non-volatile memory devices (NVM10 to NVM17), 8 rows×66 columns of chain memory arrays CY are arranged in each write area WT-AREA in such a manner that 528-byte data can be stored.

For example, in a case where the information processing device CPU_CP writes write data, with a minimum unit being 64 bytes, into the memory modules NVMMD0, the information processing circuit MNGER may arrange 8 rows×9 columns of chain memory arrays CY in each write area WT-AREA in such a manner that 72-byte data can be stored in order to write 64-byte main data MDATA and 8-byte redundant data RDATA into the non-volatile memory devices (NVM10 to NVM17).

In such a manner, the information processing device CPU_CP can arrange a chain memory array CY in a write area WT-AREA according to a minimum unit of intended write data and can flexibly correspond to a system request.

Moreover, by arranging a chain memory array CY in a write area WT-AREA according to 64 bytes that is a minimum unit of write data of the information processing device CPU_CP and by using a plurality of write areas WT-AREA, it is possible to store data (having, for example, 512 byte) that is larger than the minimum unit for the integer number of times.

When write data corresponding to one physical address is 512 bytes, in this embodiment, one physical address corresponds to one write area WT-AREA. However, it is obvious that this is not the limitation. In an embodiment described later, data corresponding to a plurality of physical addresses is written into a write area WT-AREA. That is, an example of a write area having a data capacity larger than a capacity of data with respect to one physical address is illustrated.

### Second Embodiment

### Second Layout of Non-Volatile Memory Device

FIG. 25 is a schematic plan view illustrating a different example of one memory array ARY in non-volatile memory devices NVM10 to NVM17. In this embodiment, two dummy chain memory arrays DCY are continuously arranged between write areas WT-AREA. In this case, dummy chain memory array designation information (XYDMC) is set to 1_2_2. Accordingly, an information processing circuit MNGER sets one row and one column of dummy chain memory arrays DCY on an outer side (in outer periphery) of each write area WT-AREA.

Also, each of the write areas WT-AREA and WT-AREA0 to 7 includes a main data area DArea where main data MDATA is written and a redundant data area RArea where redundant data RDATA is written. Also, the above-described main data area DArea is arranged in 8 rows×8 columns on an upper side of a matrix of chain memory arrays CY included in each write area and the above-described redundant data area RArea is arranged in 1 row×8 columns on a lower side thereof.

That is, information processing circuit MNGER performs a reading operation, a writing operation, and a batch-erasing operation on each of the write areas WT-AREA without performing the reading operation, the writing operation, and the erasing operation (batch-erasing operation) on one row and one column of chain memory arrays CY adjacent to an outer side of each of the write areas WT-AREA.

In FIG. 25, a dummy chain memory array DCY is arranged in such a manner as to surround each write area WT-AREA. That is, one column (one row) of the dummy chain memory arrays DCY are arranged with respect to each side of each write area WT-AREA. Accordingly, two columns (two rows) of the dummy chain memory arrays DCY are arranged between the write areas WT-AREA. Obviously, two columns (two rows) of the dummy chain memory arrays DCY may be collectively arranged on two sides (such as upper side and right side in the drawing) of each write area WT-AREA.

In such a manner, even in a case where batch-erasure is performed in any of the write areas WT-AREA, an influence of heat disturbance can be further reduced.

Also, it is possible to determine which chain memory array CY is arranged as a dummy chain memory array DCY by programming it into an initial setting area SSD configuration (SDCFG) in a non-volatile memory device. After power activation, the information processing circuit MNGER reads this initial setting area and determines arrangement of the dummy chain memory array DCY.

As described above, it is possible to flexibly correspond to levels of a function, performance, and reliability requested to a memory module NVMMD0.

### Third Embodiment

### Third Layout of Non-Volatile Memory Device

FIG. 26B is a schematic plan view illustrating a different example of one memory array ARY in a non-volatile memory device. In the drawing, a •-shape and a ∘-shape indicate chain memory arrays CY arranged in intersection points of word lines WL0 to WLk and bit lines BL0 to BLi. In this embodiment, a s-shaped chain memory array DSCY is a chain memory array that does not store data and indicates a chain memory array CY (set chain memory array DSCY) assumed to be “1” (in Set state). On the other hand, the ∘-shape is a chain memory array CY that records data “1” (Set state) or data “0” (Reset state).

In this embodiment, each of write areas WT-AREA (WT-AREA and WT-AREA 0 to 7) includes chain memory arrays CY which are arranged in 9 rows×65 columns and which include •-shapes and ∘-shapes. That is, each write area WT-AREA includes an erasure area ERS-AREA (not illustrated) and a set chain memory array DSCY. Here, the erasure area ERS-AREA includes 8 rows×64 columns of ∘-shaped chain memory arrays CY (in drawing, main data area DArea where main data MDATA is written and redundant data area RArea where redundant data RDATA is written). Since dummy chain memory array designation information (XYDMC) is set to 0_1_1, one dummy chain memory array DCY is set in each of a row direction and a column direction on an inner side of each write area WT-AREA. In other words, one row (one column) of dummy chain memory arrays DCY are arranged in a row direction (column direction) adjacent to an outer side (outer periphery) of the erasure area ERA-AREA.

Also, in this embodiment, in each of the write areas WT-AREA and WT-AREA0 to 7, a main data area DArea where main data MDATA is written is arranged in 7 rows×64 columns (on upper side in the drawing) of a matrix of chain memory arrays CY included in each write area and a redundant data area RArea where redundant data RDATA is written is arranged in 1 row×64 columns (on right side in the drawing).

Also, in this embodiment, each of the write areas WT-AREA and WT-AREA0 to 7 includes a plurality of physical addresses PAD. For example, the write area WT-AREA0 includes physical addresses PAD0 to PADm.

In the chain memory arrays CY in the erasure area ERS-AREA, batch-erasure is performed. The erasure area ERS-AREA is an area where data “0” (Reset state) is written at right time after the batch-erasure. The area includes a ∘-shaped chain memory arrays CY in 8 rows×64 columns. The write area WT-AREA is chain memory arrays CY in 9 rows×64 columns and the erasure area ERS-AREA is chain memory arrays CY in 8 rows×64 columns.

Here, when it is assumed that the write area WT-AREA includes chain memory arrays in 9 rows×65 columns and the erasure area ERS-AREA includes chain memory arrays in 8 rows×64 columns, a ratio of the erasure area ERA-AREA to the write area WT-AREAis (512/585)×100=87.5%. That is, when an amount of bit data “0” in data written into the memory array ARY is equal to or smaller than 87.5%, bit data of “0” can be written into the erasure area ERA-AREA.

FIG. 26A is a flowchart for describing a writing method with respect to the memory array ARY illustrated in FIG. 26B.

A writing operation on the non-volatile memory device NVM10 in a case where a writing request WQ00 is input into the information processing circuit MNGER in FIG. 2 by the information processing device CPU_CP in FIG. 1 will be described.

Although it is not specifically limited, the information processing circuit MNGER associates one physical address for each size of 512-byte main data MDATA and 16-byte redundant data RDATA and performs writing into the non-volatile memory devices NVM10 to NVM17. The writing request WQ00 includes a logical address value LAD0, a writing instruction WRT, a sector count value SEC1, and 512-byte write data WDATA0.

First, when the writing request WQ00 is input into the information processing circuit MNGER in FIG. 2 by the information processing device CPU_CP in FIG. 1 (Step 301), the information processing circuit MNGER generates redundant data RDATA0, which includes ECC data, from the 512-byte (512×8 bit) write data (DATA0) in the writing request WQ00 (Step 302). Next, the information processing circuit MNGER counts the number of pieces of bit data “0” and the number of pieces of bit data “1” in the 512-byte (512×8 bit) write data (DATA0) in the writing request WQ00 (Step 303) and compares the number of pieces of bit data “0” and the number of pieces of bit data “1” (Step 304). Then, when the number of pieces of bit data “0” is larger than the number of pieces of bit data “1,” the information processing circuit MNGER inverts each bit of the write data (DATA0) (Step 305). On the other hand, when the number of pieces of bit data “0” is not larger than the number of pieces of bit data “1,” the information processing circuit MNGER does not invert each bit of the write data (DATA0). The write data that is inverted or not inverted in Step 305 is supplied to Step 306.

In such a manner, each bit of the write data (DATA0) is inverted or not inverted according to the number of pieces of bit data “0” in the 512-byte (512×8 bit) write data (DATA0). Thus, the number of pieces of the bit data “0” constantly becomes equal to or smaller than 2048 bits (=4096/2) in 512 bytes (512×8 bit=4096 bit). That is, the number of pieces of the bit data “0” is constantly equal to or smaller than ½ in the write data. Accordingly, an amount of written bit data “0” can be decreased by half.

Then, the information processing circuit MNGER refers to a write physical address table NXPADTBL1 and determines a physical address PAD0 and an erasure block address ERSAD0, which correspond to an address LAD0, and a non-volatile memory device NVM10 to which data is written (Step 306). The information processing circuit MNGER serially issues an erasure instruction ERS0 and a writing instruction WT0 with respect to the non-volatile memory device NVM10 through an arbitration circuit ARB and a memory control circuit NVCT0. The erasure instruction ERS0 includes the erasure block address ERSAD0, an erasure instruction ERS, and the erasure block address ERSAD0. By the erasure block address ERSAD0 in the erasure instruction ERS0, an erasure area ERS-AREA in the write area WT-AREA0 of the memory device NVM10 is selected. By the erasure instruction ERS, data in all memory cells included in all chain memory arrays CY in the erasure area ERS-AREA becomes “1” (Set state due to operation of batch-erasure) (Step 307). That is, by this erasing instruction, data in all memory cells in chain memory arrays CY assigned to a plurality of physical addresses PAD0 to PADm in the erasure area ERS-AREA becomes “1” (Set state due to operation of batch-erasure).

By the physical address PAD0 and the writing instruction WT in the writing instruction WT0, in the write area WT-AREA0 of the memory device NVM10, only data of “0” (Reset state) in the 512-byte write data WDATA0 is written into memory cells in chain memory arrays CY in a main data area DArea in an erasure area ERS-AREA assigned to the physical address PAD0 (Step 308).

Similarly, by the physical address PAD0 and the writing instruction WT in the writing instruction WT0, in the write area WT-AREA0 of the memory device NVM10, only data of “0” (Reset state) in the redundant data RDATA0 is written into memory cells in chain memory arrays CY in a redundant data area RArea in the erasure area ERS-AREA assigned to the physical address PAD0 (Step 308).

In such a manner, since the number of pieces of bit data “0” constantly becomes equal to or smaller than ½ in the write data DATA0. Thus, as illustrated in FIG. 26B, even when a ratio of the erasure area ERS-AREA is low (is not 100%), it is possible to store the write data DATA into the write area WT-AREA0 by writing the bit data of “0” into the erasure area ERS-AREA. That is, even when the dummy chain memory array is set on an inner side of the write area WT-AREA0, the write data DATA0 can be stored.

Also, by setting a dummy chain memory array that is set on an inner side of the write area WT-AREA0 as a set chain memory array DSCY, it is possible to assume that the set chain memory array DSCY is an area storing bit data of “1” in the write data DATA0. That is, it is assumed that the bit data of “1” is stored at a physical address of the set chain memory array DSCY. Accordingly, it is possible to assume that the bit data of “1” in the write data DATA0 is stored in the set chain memory array DSCY. In this case, it is not requested to perform an operation of writing/reading data into/from the set chain memory array DSCY. For example, it is assumed that “1” is stored at the physical address of the set chain memory array DSCY.

Accordingly, it becomes possible to configure the write area WT-AREA0 with an erasure area ERS-AREA0 where bit data of “0” can be written and the set chain memory array DSCY and to realize the arrangement illustrated in FIG. 26B.

In FIG. 26B, a set chain memory array DSCY is arranged between a plurality of write areas WT-AREA without a heat disturbance buffer area being provided between the plurality of write areas WT-AREA. The set chain memory array DSC functions as a buffer area to absorb an influence of heat disturbance between write areas WT-AREA adjacent to each other. Moreover, the information processing circuit MNGER recognizes an arrangement (address) of the set chain memory array DSCY. Thus, the information processing circuit MNGER can perform reading of data on while assuming that data “1” is recorded in the set chain memory array DSCY.

The set chain memory array DSCY can function as both of a buffer area that absorbs an influence of heat disturbance between the write areas WT-AREA adjacent to each other and a chain memory array CY that records the data “1.” Thus, it is possible to make a penalty of a storage capacity of the non-volatile memory zero, to write and hold data in the write area WT-AREA reliably without receiving an influence of the heat disturbance, and to provide a highly reliable memory module.

Moreover, the number of pieces of the bit data “0” constantly becomes equal to or smaller than ½ in the write data. Thus, it is possible to reduce an amount of written bit data “0” by half and to realize an SSD with high speed and low power.

Note that in FIG. 26A, Step 302 is a step of generating redundant data RDATA including ECC data based on write data. To the generated redundant data RDATA, steps in and after Step 303 are applied. Accordingly, it is possible to reduce the amount of written bit data “0.”

### Fourth Embodiment

### Fourth Layout of Non-Volatile Memory Device

FIG. 27 is a schematic plan view of one memory array ARY in a non-volatile memory device in a case where two chain memory arrays DCY (DSCY) are continuously arranged between write areas WT-AREA. A method of writing data into the write area WT-AREA illustrated in FIG. 27 is similar to that in FIG. 26A described above.

On an inner side of a write area WT-AREA, dummy chain memory arrays DCY in two lows and dummy chain memory arrays DCY in two columns are set. These dummy chain memory arrays DCY are used as a set chain memory array DSCY. In order to set such dummy chain memory arrays DCY, dummy chain memory array designation information XYDMC in an SSD configuration (SDCFG) is set to 0_2_2. Accordingly, on an inner side of each write area WT-AREA, dummy chain memory arrays DCY in two rows and two columns are set.

In each of write areas WT-AREA and WT-AREA0 to 7, the above-described write data is written into a main data area DArea (6 row×64 column). Also, in this embodiment, in 1 row×64 columns (on lower side in the drawing) in a matrix of chain memory arrays CY included in each write area, the above-described redundant data RDATA is arranged.

In this embodiment, a matrix of chain memory arrays CY that stores the redundant data RDATA includes a plurality of chain memory arrays CY arranged in one row.

In FIG. 27, a •-shape and a ∘-shape indicate chain memory arrays CY arranged in intersection points of word lines WL0 to WLk and bit lines BL0 to BLi. Also, similarly to FIG. 26B, the •-shape indicates a chain memory array CY (set chain memory array DSCY) that does not record data but that is assumed as “1” (Set state). The ∘-shape is a chain memory array CY that records data “1” (Set state) or data “0” (Reset state).

Although it is not specifically limited, the write area WT-AREA includes chain memory arrays CY which are arranged in 9 rows×66 columns and which include •-shapes and ∘-shapes. The area includes an erasure area ERS-AREA and a set chain memory array DSCY.

Here, the erasure area ERS-AREA is an area where data “0” (Reset state) can be written after batch-erasure. The area includes ∘-shaped chain memory arrays CY in 7 rows×64 columns. Since the writing area WT-AREA is the chain memory arrays CY in 9 rows×66 columns and the erasure area ERS-AREA is the chain memory arrays CY in 7 rows×64 columns, a ratio of the erasure area ERS-AREA to the write area WT-AREA is (448/594)×100=75.4%.

In the writing method described with reference to FIG. 26A, the number of pieces of bit data “0” constantly becomes equal to or smaller than ½ in the write data. Thus, it is possible to write the bit data of “0” into the erasure area ERS-AREA in the arrangement of the memory array ARY illustrated in FIG. 27. Thus, in a case where an influence of heat disturbance is also on the second one of adjacent chain memory arrays CY in batch-erasure of the erasure area ERS-AREA, such an arrangement is employed and two chain memory arrays DCY are continuously provided between erasure areas ERS-AREA. Thus, it is possible to remove the influence of the heat disturbance and to provide a highly reliable SSD with high speed. Even in this embodiment, dummy chain memory arrays DCY in two rows and two columns are used as a set chain memory array DSCY that stores data. It is possible to program an arrangement of such a set chain memory array DSCY into an initial setting area SSD configuration (SDCFG) in a non-volatile memory device. After power activation, the information processing circuit MNGER reads this initial setting area and determines the arrangement of the chain memory array DSCY.

As described above, it is possible to arrange a dummy chain memory array DCY flexibly according to levels of a function, performance, and reliability requested to a memory module NVMMD0.

### Fifth Embodiment

### Fifth Layout of Non-Volatile Memory Device

FIG. 28 is a schematic plan view illustrating a different arrangement example of one memory array ARY in a non-volatile memory device. In the drawing, a •-shape and ∘-shape indicate chain memory arrays CY arranged-in intersection points of word lines WL0 to WLk and bit lines BL0 to BLi. Also, the •-shape indicates a chain memory array CY (set chain memory array DSCY) that does not record but that is assumed as “1” (Set state). The ∘-shape indicates a chain memory array CY that records data “1” (Set state) or data “0” (Reset state).

Although it is not specifically limited, each of write areas WT-AREA0 to WT-AREAn includes chain memory arrays CY which are arranged in 9 rows×4096 columns and which include •-shapes and ∘-shapes. Each of the areas includes an erasure area ERS-AREA and a set chain memory array DSCY. Also, to each of the write areas WT-AREA0 to WT-AREAn, a plurality of physical addresses (PAD0 to m) can be assigned. That is, it is possible to write a plurality of pieces of write data, each of which corresponds to a physical address, to one write area. For example, it is possible to associate 9 rows×512 columns to one physical address and to write a plurality of pieces of write data in a unit of 9 rows×512 columns.

Also, the erasure area ERS-AREA is an area where data “0” (Reset state) can be written after batch-erasure. The area includes ∘-shaped chain memory arrays CY in 8 rows×4096 columns.

In this embodiment, dummy chain memory array designation information XYDMC in SSD configuration (SDCFG) is set to 0_1_0. Accordingly, on an inner side of each write area WT-AREA (in other words, in outer periphery of erasure area ERS-AREA), one row of dummy chain memory arrays DCY is set and the set dummy chain memory arrays DCY are used as the set chain memory array DSCY.

Also, each of the write areas WT-AREA0 to n includes the above-described main data area DArea (chain memory array CY in 7 row×4096 column) and redundant data area RDATA (chain memory array CY having 1 row×4096 column).

In the arrangement example of this memory array ARY, each write area WT-AREA has 36864 chains (=9 row×4096 column). Among that, an area of the set chain memory array DSCY is 4106 chains (1 row). Thus, a ratio of an area where the data “0” (Reset state) can be written becomes 88.8% 8=((36864−4106)/36864)×100). In the writing method described in FIG. 26A, the number of pieces of bit data “0” is constantly equal to or smaller than ½ in write data. Thus, since a ratio of the area where the data “0” (Reset state) is written is increased, an influence of heat disturbance in a case of writing the data “0” (Reset state) becomes small.

Also, in this embodiment, it is possible to perform a writing operation for a plurality of times after batch-erasure is performed in the erasure area ERS-AREA in each write area WT-RAER. For example, it is possible to associate an erasure area ERS-AREA having 8 rows×512 columns to one physical address and to perform writing for a plurality of times in a unit of 8 rows×512 columns. When writing is performed for a plurality of times after the batch-erasure, it becomes possible to reduce an influence of heat disturbance, which is due to the batch-erasure, by a set chain memory array DSCY. Also, since no dummy chain memory array DCY is set in a column direction, it is possible to perform downsizing and to reduce a unit price in a memory cell (bit cost).

### Sixth Embodiment

FIG. 29A is a writing flowchart in a case where an information processing circuit MNGER compresses data input by an information processing device CPU_CP and writes the data into a non-volatile memory device. Also, FIG. 29B is a schematic plan view illustrating a different example of one memory array ARY in the non-volatile memory device. The writing flow illustrated in FIG. 29A illustrates a writing method with respect to the memory array ARY illustrated in FIG. 29B.

In FIG. 29B, a •-shape and a ∘-shape indicate chain memory arrays CY arranged in intersection points of word lines WL0 to WLk and bit lines BL0 to BLi. Similarly to FIG. 26B, the •-shape indicates a chain memory array CY (set chain memory array DSCY) that does not record data but that can be assumed as “1” (Set state). Also, the ∘-shape is a chain memory array CY that records data “1” (Set state) or data “0” (Reset state).

In FIG. 29B, although it is not specifically limited, each of write areas WT-AREA0 to WT-AREAn includes chain memory arrays CY which are arranged in 66 rows×32 columns and which include •-shapes and ∘-shapes. Chain memory arrays CY in 3 rows×32 columns which arrays are indicated by the s-shapes are set chain memory arrays DSCY. Chain memory arrays CY in 63 rows×32 columns which arrays are indicated by the ∘-shapes are an erasure area ERS-AREA.

Also, to each of the write areas WT-AREA0 to WT-AREAn, a plurality of physical addresses (PAD0 to 3) can be assigned. That is, it is possible to write pieces of write data respectively corresponding to the physical addresses into one write area. For example, it is possible to associate 66 rows×8 columns to one physical address and to write a plurality of pieces of write data. Also, the erasure area ERS-AREA is an area where data “0” (Reset state) can be written after batch-erasure. The area includes ∘-shaped chain memory arrays CY in 63 rows×32 columns. In this embodiment, dummy chain memory array designation information XYDMC in an SSD configuration (SDCFG) is set to 0_3_0. Accordingly, on an inner side of each write area WT-AREA (in other words, in outer periphery of erasure area ERS-AREA), three rows of dummy chain memory arrays DCY are set. The set dummy chain memory arrays DCY are used as set chain memory arrays DSCY.

Also, each of the write areas WT-AREA0 to n includes the above-described main data area DArea (chain memory array CY in 61 row×32 column) and redundant data area RDATA (chain memory array CY in 2 row×32 column).

Although it is not specifically limited, in FIG. 29B, each write area WT-AREA includes chain memory arrays CY which are arranged in 66 rows×32 columns and which include •-shapes and ∘-shapes. The area includes an erasure area ERS-AREA (ERS-AREA0, ERS-AREA1, or the like) and a set chain memory array DSCY.

In this embodiment, it is also possible to assign a plurality of physical addresses to each write area WT-AREA. The erasure area ERS-AREA is an area where data “0” (Reset state) can be written after batch-erasure. The area includes ∘-shaped chain memory arrays CY in 63 rows×32 columns. Also, dummy chain memory array designation information XYDMC in SSD configuration (SDCFG) is set to 0_3_0. On an inner side of each write area WT-AREA, three rows of dummy chain memory arrays DCY are set and arranged. The arranged three rows of dummy chain memory arrays DCY are used as set chain memory arrays DSCY.

A writing operation on a non-volatile memory device NVM10 in a case where writing requests WQ00, WQ01, WQ02, and WQ03 are serially input into the information processing circuit MNGER in FIG. 2 by the information processing device CPU_CP in FIG. 1 will be described. Although it is not specifically limited, the information processing circuit MNGER associates one physical address for each size of 512-byte main data MDATA and 16-byte redundant data RDATA and performs writing into non-volatile memory devices NVM10 to NVM17. Here, the writing request WQ00 includes a logical address value LAD0, a writing instruction WRT, a sector count value SEC1, and 512-byte write data WDATA0. The writing request WQ01 includes a logical address value LAD1, a writing instruction WRT, a sector count value SEC1, and 512-byte write data WDATA1. Similarly, the writing request WQ02 includes a logical address value LAD2, a writing instruction WRT, a sector count value SEC1, and 512-byte write data WDATA2. The writing request WQ03 includes a logical address value LAD 3, a writing instruction WRT, a sector count value SEC1, and 512-byte write data WDATA3.

Logical address values LAD0, 1, 2, and 3 included in the writing requests WQ00, WQ01, WQ02, and WQ03 from the information processing device CPU_CP are stored into an address buffer ADDBUF and the write data WDATA0, 1, 2, and 3 is stored into the buffers BUF0 to BUF3 (FIG. 2). Next, the information processing circuit MNGER refers to a write physical address table NXPADTBL and determines physical addresses PAD0, 1, 2, and 3 respectively corresponding to the addresses LAD0, 1, 2, and 3 and a non-volatile memory device NVM10 to which data is written. Then, the information processing circuit MNGER issues a block erasing instruction BERS0 to the non-volatile memory device NVM10 through an arbitration circuit ARB and a memory control circuit NVCT0. The block erasing instruction BERS0 includes an erasure block address EBK0 and an erasure instruction ERS. By the erasure block address EBK0 in the block erasing instruction BERS, data of all memory cells included in all chain memory arrays CY in the erasure area ERS-AREA0 becomes “1” (Set state) (batch-erasure).

Then, the information processing circuit MNGER reads the write data WDATA0 from the buffer BUF0 (Step 401 in FIG. 29A), performs compression (Step 402 in FIG. 29A), and checks whether a data compression rate crate is equal to or lower than an allowable compression rate CpRate (Step 403 in FIG. 29A).

Here, in the write area WT-AREA illustrated in FIG. 29B, a storage capacity with respect to one physical address is 512 (64 row×8 column) chain memory arrays CY. It is assumed that an area of set chain memory arrays DSCY among that is 24 (3 row×8 column) chain memory arrays DCY. An allowable data write area (main data area DArea) to correspond to one physical address while preventing an influence of heat disturbance is 488 (61 row×8 column) chain memory arrays CY (512−24=488). Thus, an allowable compression rate CpRate in this case becomes 0.95 (=488/512).

Next, when the data compression rate crate is equal to or lower than the allowable compression rate CpRate, the information processing circuit MNGER generates, for the physical address PAD0 of the non-volatile memory device NVM10 which address corresponds to the address LAD0, redundant data RDATA0 including ECC data based on compressed data CWDATA0 that is compressed write data WDATA0 (Step 404 in FIG. 29A). Then, in order to write compressed data CWDATA0 and redundant data RDATA0, a writing instruction WT0 is issued. The writing instruction WT0 includes the physical address PAD0, a writing instruction WT, a sector count value SEC1, compressed data CWDATA0, and redundant data RDATA0. By the physical address PAD0 and the writing instruction WT in the writing instruction WT0, only data of “0” (Reset state) in the compressed data CWDATA0 is written into a main data area DArea and the redundant data RDATA0 is written into a redundant area RArea in a memory cell of a chain memory array CY corresponding to the physical address PAD0 of the memory device NVM10 (Step 405 in FIG. 29A).

Then, the information processing circuit MNGER reads write data WDATA1 corresponding to the physical address PAD1 from the buffer BUF1 and compresses the data in a similar procedure. Then, the information processing circuit MNGER writes only data of “0” (Reset state) in compressed data CWDATA1 into a memory cell of a chain memory array CY corresponding to the physical address PAD1 of the memory device NVM10.

Then, the information processing circuit MNGER reads the write data WDATA2 from the buffer BUF2 (Step 401), performs compression (Step 402), and creates compressed data CWDATA2. Here, for example, when it is determined that a data compression rate crate of the compressed data CWDATA2 is higher than an allowable data compression rate CpRate=0.95 (Step 403), an allowable compression rate CpRate corresponding to two physical addresses are newly calculated (Step 406 in FIG. 29A). A storage capacity corresponding to the two physical addresses is 1024 chain memory arrays CY. An area of set chain memory arrays DSCY among that is 48 chains. Thus, the number of chain memory cells in an allowable data write area (main data area DArea) that corresponds to the two physical addresses while preventing an influence of heat disturbance is 976 chain memory arrays CY. Thus, in this case, an allowable compression rate CpRate with respect to the two physical addresses is 0.95 (=976/1024).

Then, the information processing circuit MNGER reads write data WDATA3 from the buffer BUF3 (Step 401), performs compression (Step 402), and creates compressed data CWDATA3. A data compression rate crate for a combination of the compressed data CWDATA2 and the compressed data CWDATA3 is determined in Step 403. In this case, it is determined that the rate is equal to or lower than 0.95 of an allowable compression rate CpRate (Step 403) and redundant data RDATA2 and RDATA2 including ECC data is generated based on the compressed data CWDATA2 and CWDATA3 of the physical addresses PAD2 and PAD3 (Step 404 in FIG. 29A).

Then, only data of “0” (Reset state) in the compressed data CWDATA2 and CWDATA3 is written into a memory cell in a chain memory array CY in a main data area DArea corresponding to the physical addresses PAD2 and PAD3 of the memory device NVM10 and the redundant data RDATA2 and RDATA3 is written into a memory cell in a chain memory array CY of the redundant area RArea (Step 405 in FIG. 29A).

In such a manner, when a data compression rate crate of data corresponding to one physical address is equal to or lower than an allowable compression rate CpRate with respect to the data corresponding to one physical address, compressed data of the one physical address is written. When a data compression rate crate of data corresponding to one physical address is higher than an allowable compression rate CpRate with respect to the data corresponding to the one physical address, it is possible to compress the data in such a manner the data compression rate becomes equal to or lower than the allowable compression rate CpRate by collective compression of data corresponding to a plurality of physical addresses. When compressed data of a plurality of physical addresses is collectively written, an influence of heat disturbance is constantly prevented. Thus, it is possible to secure an area of set chain memory arrays DSCY and to write data. Thus, it is possible to write and hold data in the non-volatile memory NVM reliably while reducing an influence of the heat disturbance and to provide a highly reliable memory module.

FIG. 29C is a different writing flowchart in a case where the information processing circuit MNGER compresses data input by the information processing device CPU_CP and to write the data into a non-volatile memory device.

The writing flow illustrated in the drawing is similar to the writing flow illustrated in FIG. 29A. That is, Step 501 to Step 503, and Step 509 in FIG. 29C correspond to Step 401 to Step 403, and Step 405 in FIG. 29A. In the flow illustrated in FIG. 29C, when it is determined in Step 503 (corresponding to Step 403 in FIG. 29A) that a data compression rate crate is equal to or lower than an allowable compression rate CpRate, ECC data is generated in Step 504 based on compressed write data. With respect to the compressed write data, the number of bits that are “0” and the number of bits that are “1” are counted in Step 505. It is determined in Step 506 whether the counted number of bits that are “0” is larger than the counted number of bits that are “1.” When the number of bits that are “0” is larger than the number of bits that are “1,” Step 507 is subsequently executed. In other cases, Step 508 is executed.

In Step 507, each bit of the compressed write data is inverted. The inverted data is written into a write area WT-AREA designated by a physical address.

Also, when Step 508 is executed after the execution of Step 507, in Step 508, the data inverted in Step 507 is written into a main data area DArea in the write area WT-AREA designated by the physical address PAD. Also, the ECC data generated in Step 504 and a writing flag (WTFLG=2_1) indicating compression and inversion are written into a redundant area (RArea) corresponding to the write area WT-AREA designated by the physical address PAD. Also, in a case where Step 508 is executed without the execution of Step 507, in Step 508, the data inverted in Step 507 is written into the main data area DArea in the write area WT-AREA in the physical address PAD and the ECC data generated in Step 504 and a writing flag (WTFLG=2) indicating compression are written into the redundant area (RArea) corresponding to the write area WT-AREA designated by the physical address PAD.

In such a manner, the number of bits to which “0” is written (which is reset) can be reduced and speed of writing can be increased.

Also, to the ECC data generated in Step 504, Step 505 to Step 507 may be applied. In FIG. 29C, processing of when the number of bits of “0” is smaller than the number of bits of “1” in Step 506 is omitted. When the number of bits of “0” is small, the compressed write data is written into the write area WT-AREA without inversion.

### Seventh Embodiment

### Seventh Layout of Non-Volatile Memory Device

FIG. 31 is a schematic plan view illustrating a different example of one memory array ARY in a non-volatile memory device. In the drawing, a •-shape and a ∘-shape indicate chain memory arrays CY arranged in intersection points of word lines WL0 to WLk and bit lines BL0 to BLi. In this embodiment, dummy chain memory array designation information (XYDMC) in SSD configuration information (SDCFG) is set to 1_1_1. Accordingly, on an outer side of each of write areas WT-AREA (WT-AREA 0 to WT-AREA7), one row and one column of dummy chain memory arrays DCY are set. Since the dummy chain memory arrays are set on the outer side of the write area WT-AREA, a size of an erasure area that is erased by a batch-erasing operation and a size of each write area WT-AREA into which data is written (which is reset) are the same.

In this embodiment, each write area WT-AREA includes chain memory arrays (∘-shape) which are arranged in 8 rows×8 columns and which are a main data area DArea to store main data MDTA and chain memory arrays (∘-shape) which are arranged in 1 row×8 columns and which are a redundant data area RArea to store redundant data RDATA. Thus, the write area (erasure area) includes chain memory arrays in 9 rows×8 columns.

In this embodiment, a column and a row of the dummy chain memory arrays DCY are arranged on a right side and an upper side of each write area WT-AREA (in FIG. 31). Thus, as it is understood from FIG. 31, a write area WT-AREA (such as WT-AREA0) that is not adjacent to a write area WT-AREA is not surrounded by the dummy chain memory arrays DCY. Thus, it becomes possible to reduce the number of dummy chain memory arrays DCY. Even in this case, a decrease in reliability due to heat is not caused since there is no adjacent write area.

### First Modification Example

### Eighth Layout of Non-Volatile Memory Device

FIG. 32A is a schematic plan view illustrating a different example of one memory array ARY in a non-volatile memory device. In the drawing, a •-shape and a ∘-shape indicate chain memory arrays CY arranged in intersection points of word lines WL0 to WLk and bit lines BL0 to BLi. In this embodiment, dummy chain memory array designation information (XYDMC) in SSD configuration information (SDCFG) is set to 1_1_1. Accordingly, on an outer side of each of write areas WT-AREA (WT-AREA0 to WT-AREA7, WT-AREA8 to WT-AREA15, and WT-AREAn to WT-AREAn+7), one row and one column of dummy chain memory arrays DCY are set. Since the dummy chain memory arrays are set on the outer side of each write area WT-AREA, a size of an erasure area ERS-AREA (not illustrated) that is erased by a batch-erasing operation becomes the same with a size of each write area WT-AREA, into which data is written (which is reset), or becomes larger than the size of the write area for the integer number of times. In the drawing, each write area WT-AREA includes chain memory arrays CY (∘-shape) in 9 rows×64 columns. On an upper side and a right side of the write area WT-AREA, one row and one column of dummy chain memory arrays DCY are arranged.

Also, the write area WT-AREA includes chain memory arrays (∘-shape) which are arranged in 8 rows×64 columns and which are a main data area DArea to store main data MDTA and a redundant data area RArea which has 1 row×64 columns and which stores redundant data RDATA.

After batch-erasure (setting) of all chain memory arrays CY in a write area WT-AREA (such as WT-AREA0) is performed, random writing is performed on the chain memory arrays CY in the write area WT-AREA (main data area DArea+redundant data area RArea=(8×64)+(1×64)=576 byte). Alternatively, writing is sequentially performed in a unit less than 512 bytes (such as 72=(64+8) byte). In this embodiment, a unit (576 byte) that is larger than the unit of sequential writing is set as an erasure area. Thus, it is possible to reduce the number of dummy chain memory arrays surrounding the erasure area and to realize downsizing and reduction of a bit cost.

Note that the sequential writing is performed, for example, with chain memory arrays CY arranged in 9 rows×8 columns as one unit. In the drawing, this unit is surrounded by a narrow line. The sequential writing is performed by performance of writing in this unit from a left side to a right side in the drawing.

### Second Modification Example

### Ninth Layout of Non-Volatile Memory Device

FIG. 32B is a schematic plan view illustrating a different example of one memory array ARY in a non-volatile memory device. In the drawing, a •-shape and a ∘-shape indicate chain memory arrays CY arranged in intersection points of word lines WL0 to WLk and bit lines BL0 to BLi. In this embodiment, dummy chain memory array designation information (XYDMC) in SSD configuration information (SDCFG) is set to 1_1_1. Accordingly, on an outer side of each of write areas WT-AREA (WT-AREA0 to WT-AREA7, WT-AREA8 to WT-AREA15, and WT-AREAn to WT-AREAn+7), one row and one column of dummy chain memory arrays DCY are set. In the drawing, each write area WT-AREA includes chain memory arrays CY (∘-shape) in 9 rows×512 columns. On an upper side and a right side of this write area WT-AREA, one row and one column of dummy chain memory arrays DCY are arranged.

After batch-erasure (setting) of all chain memory arrays CY in a write area WT-AREA (such as WT-AREA0) is performed, writing is performed on the chain memory arrays CY in the write area WT-AREA (main data area DArea+redundant data area RArea=(8×512)+(1×512)=4608 byte).

In a case where the write area WT-AREA includes a plurality of physical addresses PAD0 to PADm with 576 (=512+64) that is a unit smaller than 4608 bytes as one physical address PAD, a control circuit MDLCT0 sequentially assigns the physical addresses PAD0 to PADm in the write area WT-AREA to logical addresses LAD (for example, one physical address has data size of 512 byte) that are randomly input into a control circuit MDLCT0 by an information processing device CPU_CP. Then, the control circuit MDLCT0 performs writing. For example, the writing is performed from a left side to a right side in the drawing.

Also, in a case where one write area WT-AREA corresponds to one physical address, the control circuit MDLCT0 assigns a physical address PAD in the write area WT-AREA to a logical address LAD (for example, one physical address has data size of 4096 byte) randomly input into the control circuit MDLCT0 by the information processing device CPU_CP. The control circuit MDLCT0 sequentially performs writing of chain memory arrays CY at the physical address PAD in a unit of 576 (=512+64) bytes. For example, the writing is performed from a left side to a right side in the drawing.

In this embodiment, a unit (such as 4608 byte) that is larger than a unit of sequential writing is set as an erasure area. Thus, it becomes possible to reduce the number of dummy chain memory arrays surrounding the erasure area and to realize downsizing and reduction of a bit cost.

### Third Modification Example

### Tenth Layout of Non-Volatile Memory Device

FIG. 33A is a schematic plan view illustrating a different example of one memory array ARY in a non-volatile memory device. In the drawing, a •-shape and a ∘-shape indicate chain memory arrays CY arranged in intersection points of word lines WL0 to WLk and bit lines BL0 to BLi. In this embodiment, dummy chain memory array designation information (XYDMC) in SSD configuration information (SDCFG) is set to 1_1_0. Accordingly, on an outer side of each of write areas WT-AREA (WT-AREA0 to WT-AREAn), one row of dummy chain memory arrays DCY are set. In the drawing, the write area WT-AREA includes chain memory arrays CY (∘-shape) in 9 rows×4096 columns. On an upper side of each write area WT-AREA, one row of dummy chain memory arrays DCY are arranged.

After batch-erasure (setting) of all chain memory arrays CY in a write area WT-AREA (such as WT-AREA0) is performed, writing is performed on the chain memory arrays CY in the write area WT-AREA (main data area DArea+redundant data area RArea=(8×4096)+(1×4096)=36864 byte).

Also, when the write area WT-AREA includes a plurality of physical addresses PAD0 to PADm with 576 (=512+64) or 4608 (=8×512+1×512), which is a unit smaller than 36864 bytes, as one physical address PAD, a control circuit MDLCT0 sequentially assigns the physical addresses PAD0 to PADm in the write area WT-AREA to logical addresses LAD (one physical address has data size of 512 byte or 4096 byte) randomly input into the control circuit MDLCT0 by an information processing device CPU_CP. Then, the control circuit MDLCT0 performs writing. For example, the writing is performed from a left side to a right side in the drawing.

Also, when one write area WT-AREA corresponds to one physical address, the control circuit MDLCT0 assigns the physical address PAD in the write area WT-AREA to a logical address LAD (for example, one physical address has data size of 32768 byte) randomly input into the control circuit MDLCT0 by the information processing device CPU_CP. Then, the control circuit MDLCT0 performs sequential writing of chain memory arrays CY at the physical address PAD in a unit of 576 (=512+64) bytes. For example, the writing is performed from a left side to a right side in the drawing.

In this embodiment, a unit (36864 byte) that is larger than a unit of sequential writing is set as an erasure area. Thus, it is possible to reduce the number of dummy chain memory arrays surrounding the erasure area and to realize downsizing and reduction of a bit cost. Also, in the drawing, since no adjacent write area is arranged on each of right and left sides, it is not necessary to provide dummy chain memory arrays DCY in a column and it becomes possible to realize further downsizing.

### Fourth Modification Example

### Eleventh Layout of Non-Volatile Memory Device

FIG. 33B is a schematic plan view illustrating a different example of one memory array ARY in a non-volatile memory device. In the drawing, a •-shape and a ∘-shape indicate chain memory arrays CY arranged in intersection points of word lines WL0 to WLk and bit lines BL0 to BLi. In this embodiment, dummy chain memory array designation information (XYDMC) in SSD configuration information (SDCFG) is set to 1_0_0. Accordingly, on an outer side of each of write areas WT-AREA (WT-AREA0 to WT-AREA7), one row of dummy chain memory arrays DCY are set. In the drawing, each write area WT-AREA includes chain memory arrays CY (∘-shape) in 4096 columns×8 rows. On an upper side of each write area WT-AREA, one row of dummy chain memory arrays DCY are arranged.

FIG. 33B is similar to FIG. 33A. In FIG. 33A, a redundant data area RArea to store redundant data includes chain memory arrays CY arranged in a row. On the other hand, in FIG. 33B, an area RArea to store redundant data includes chain memory arrays CY arranged in a plurality of columns.

After batch-erasure (setting) of all chain memory arrays CY in a write area WT-AREA (such as WT-AREA0) is performed, writing is performed on the chain memory arrays CY in the write area WT-AREA (main data area DArea+redundant data area RArea=(8×512)×8+(8×16)×8=4096×8+128×8=32768+1024=33792 byte).

Also, when each write area WT-AREA includes a plurality of physical addresses PAD0 to PADm with 528 (=512+16) or 4224 (=8×512+8×16), which is a unit smaller than 333792 bytes, as one physical address PAD, a control circuit MDLCT0 sequentially assigns the physical addresses PAD0 to PADm in the write area WT-AREA to logical addresses LAD (one physical address has data size of 512 byte or 4096 byte) randomly input into the control circuit MDLCT0 by an information processing device CPU_CP. Then, the control circuit MDLCT0 performs writing. For example, the writing is performed from a left side to a right side in the drawing.

Also, when one write area WT-AREA corresponds to one physical address, the control circuit MDLCT0 assigns a physical address PAD in the write area WT-AREA to a logical address LAD (for example, one physical address has data size of 32768 byte) randomly input into the control circuit MDLCT0 by the information processing device CPU_CP. Then, the control circuit MDLCT0 sequentially performs writing of chain memory arrays CY at the physical address PAD in a unit of 528 (=512+16) bytes. For example, the writing is performed from a left side to a right side in the drawing.

In this embodiment, a unit (333792 byte) that is larger than a unit of sequential writing is set as an erasure area. Thus, it is possible to reduce the number of dummy chain memory arrays surrounding the erasure area and to realize downsizing and reduction of a bit cost. Also, since no adjacent write area is arranged on each of right and left sides, it is not necessary to provide dummy chain memory arrays DCY in a column and it becomes possible to realize further downsizing.

In the above-described embodiment, each of the dummy chain memory arrays DCY is preferably set to a set state in previous. This can be set, for example, in initial setting. However, instead of the setting in the initial setting, the following may be performed. That is, until access to all physical addresses PAD in the non-volatile memory device is completed, for example, physically adjacent and continuous write areas WT-AREA and physically adjacent and continuous physical addresses PAD in the write areas WT-AREA are selected with respect to a logical address LAD input into the control circuit MDLCT0 by the information processing device CPU_CP. Then, in writing of data into the physical addresses PAD for the first time, a writing operation may be performed in such a manner that an erasing operation is serially executed in the write areas WT-AREA including a dummy chain memory array DCY. In this case, in and after second performance of the writing operation on the same physical addresses PAD, the erasing operation and the writing operation are performed in an area not including the dummy chain memory array DCY. In this case, the write area WT-AREA may be selected randomly.

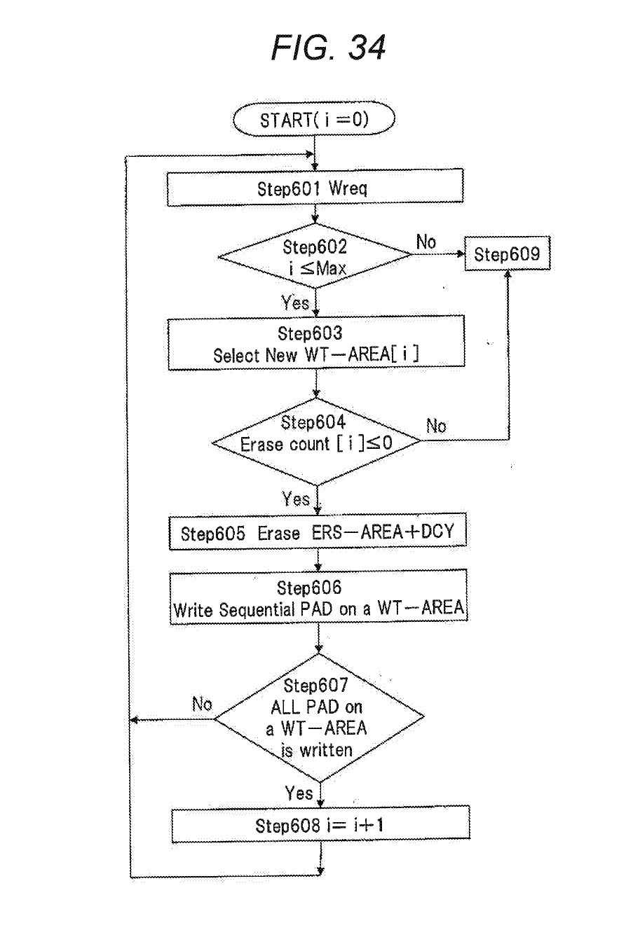

An example of a detail of the above writing method is illustrated in FIG. 34.

First, in Step 601, an input of a writing request into the information processing circuit MNGER in FIG. 2 from the information processing device CPU_CP in FIG. 1 is waited for. When a writing request WQ is input (Step 601), the information processing circuit MNGER generates redundant data RDATA, which includes ECC data, from write data (MDATA) in the writing request WQ (Step 601). Then, the information processing circuit MNGER checks whether a value of i of a write area WT-AREA [i] is equal to or smaller than a maximum value (Step 602). When the value of i is equal to or smaller than the maximum value, Step 603 is performed. In other cases, Step 609 is performed. The maximum value of the value i is determined by the number of write areas included in a maximum physical capacity of non-volatile memories NVM10 to 17 of a memory module NVMD0.

In Step 603, the write area WT-AREA [i] is selected. In Step 604, it is checked whether the number of times of erasure in an erasure area ERS-AREA in the write area WT-AREA [i] is equal or smaller than 0. When the number of times of erasure is equal to or smaller than 0, Step 605 is performed. In other cases, Step 609 is performed.

In Step 605, a chain memory array CY in the erasure area ERS-AREA in the writing area WT-AREA [i] and all memory cells in a dummy chain memory array DCY arranged on the outer side of the erasure area ERS-AREA is set to an erased state (Set state).

In Step 606, physical addresses PAD that are arranged in a physically adjacent manner in the write area WT-AREA [i] are serially selected. Written data (MDATA) is written into a main data area DArea included in the selected physical address PAD and redundant data RDATA is written into a redundant data area RArea.

In Step 607, it is checked whether writing is performed on all physical addresses PAD included in the write area WT-AREA [i]. When the writing is performed on all of the physical addresses PAD included in the write area WT-AREA [i], Step 608 is performed. In other cases, Step 601 is performed. In Step 608, a new value of i which is a value of i to which 1 is added is determined. Since values of i are serially determined, write areas WT-AREA arranged in a physically adjacent manner are selected. After Step 608 is over, Step 601 is performed.

In Step 609, a writing access to all write areas WT-AREA (physical address PAD) of the non-volatile memory devices NVM10 to 17 of the memory module NVMD0 is completed once and all memory cells of all dummy chain memory arrays DCY included in the non-volatile memory devices NVM10 to 17 become the erased state (Set state). Thus, as described in the above, in and after second performance of the writing operation, the erasing operation and the writing operation are performed on an area not including the dummy chain memory arrays DCY. In this case, the write area WT-AREA can be selected randomly.

In FIG. 33B, the write area WT-AREA0 includes physical addresses PAD0 to 7, the write area WT-AREA1 includes physical addresses PAD8 to 15, and the write area WT-AREAn includes physical addresses PADm to m+7.

In Step 603, the write area WT-AREA0 is selected. In Step 605, all memory cells in a chain memory array CY in an erasure area ERS-AREA in the write area WT-AREA0 and all memory cells in a dummy chain memory array DCY arranged in one row on an outer side of the erasure area ERS-AREA are set to the erased state (Set state). In a case of FIG. 33B, the write area WT-AREA and the erasure area ERS-AREA are the same area.

Next, in Step 606, writing is serially performed from the physical address PAD0 to PAD7 in the write area WT-AREA0. For example, the writing is performed from a left side to a right side in the drawing.

When writing into the physical addresses PAD0 to 7 in the write area WT-AREA0 is over, 1 is added to the value of i in Step 606 and i=1 (=0+1). Accordingly, for next writing, a write area WT-AREA1 that is adjacent to the write area WT-AREA0 is selected and a similar writing operation is repeated.

A case where the write area WT-AREA includes a plurality of physical addresses PAD has been described. However, it is obvious that a similar operation can be performed in a case where a write area WT-AREA includes only one physical address PAD.

By such a writing method, it is possible to bring a dummy chain memory array DCY into a set state during writing of data. Time of bringing a dummy chain memory array DCY into the set state is not necessary in initial setting. Thus, it is possible to reduce time of initial setting and to use the memory module NVMMD0 instantly.

### CONCLUSION

A major effect acquired by each of the above-described embodiments is as follows.

First, it is possible to simultaneously make memory cells in a plurality of chain memory arrays CY low resistive and to improve a data erasing rate. Second, since only data “0” is written into a memory cell after erasure of a chain memory array CY, writing speed can be increased. Third, a stable writing operation can be realized since a system of writing, after simultaneously writing one of a set state and a reset state once into all memory cells in a chain memory array CY (after erasure), the other state into a specific memory cell is used. Fourth, since there is a dummy chain memory array DCY between write areas WT-AREA, it is possible to write and hold data reliably in a write area WT-AREA without an influence of heat disturbance and to provide a highly reliable memory module. Fifth, it is possible to program, into an initial setting area in a non-volatile memory device, how to arrange a dummy chain memory array DCY. Thus, it is possible to flexibly correspond to levels of a function, performance, and reliability requested to a memory module NVMMD0.

Sixth, when the number of pieces of bit data “0” is larger than the number of pieces of bit data “1” in written data (DATA0), the number of pieces of bit data “0” constantly becomes equal to or smaller than ½ by inversion of each bit of the write data. Accordingly, it is possible to reduce an amount of written bit data “0” by half and to realize a memory module with low power and high speed. Seventh, since a set chain memory array DSCY can function as both of a buffer area that absorbs an influence of heat disturbance between write areas WT-AREA and a memory array that stores data “1,” it is possible to reduce an influence of heat disturbance and to write and hold data reliably in the write areas WT-AREA while preventing an increase in a penalty of a storage capacity of a non-volatile memory. Thus, it is possible to provide a highly reliable memory module. Eighth, it is possible to program, into an initial setting area in a non-volatile memory device, how to arrange a set chain memory array DSCY. Thus, it is possible to flexibly correspond to levels of a function, performance, and reliability requested to a memory module NVMMD0. Ninth, since it is possible to secure a set chain memory array DSCY by compression of data, it is possible to write and hold data reliably in a write area WT-AREA while reducing an influence of heat disturbance and to provide a highly reliable memory module. Tenth, as described with reference to FIG. 23B and the like, an information processing system with high performance can be realized since storage of a writing request into a buffer, previous preparation for writing, and a writing operation on a phase-change memory are processed in a pipeline manner.

In the above, the invention made by the inventors has been described based on embodiments. However, the present invention is not limited to the above embodiments and can be modified in various manners within the spirit and the scope thereof. For example, the above embodiments are described in detail in order to make it easy to understand the present invention. The present invention is not necessarily limited to what includes all described configurations. Also, it is possible to replace a part of a configuration of an embodiment with a configuration of a different embodiment and to add a configuration of a different embodiment to a configuration of an embodiment. Moreover, addition/deletion/replacement of a different configuration can be performed with respect to a part of a configuration of each embodiment. Also, in each of the embodiments, a description is mainly made with a phase-change memory as a representative. However, it is possible to apply the present invention in a similar manner and to acquire a similar effect as long as a memory is a resistive random access memory including a ReRAM and the like.

Also, in the embodiments, a description is made with a memory, which has a three-dimensional structure and in which a plurality of memory cells is arranged in a manner serially laminated in a height direction with respect to a semiconductor substrate, as a representative. However, it is possible to apply the present invention in a similar manner and to acquire a similar effect in a memory which has a two-dimensional structure and in which one memory cell is arranged in a height direction with respect to a semiconductor substrate.

### REFERENCE SIGNS LIST

ADCMDIF address-command interface circuit
ARB arbitration circuit
ARY memory array
BK memory bank
BL bit line
BSW bit line selection circuit
BUF buffer
CADLT column address latch
CH chain control line
CHDEC chain decoder
CHLT chain selection address latch
CL phase-change memory cell
COLDEC column decoder
PAD physical address
CPAD physical address
CPU_CP information processing device (processor)
CPVLD validity flag
CTLOG control circuit
CY chain memory array
D diode
DATCTL data control circuit
DBUF data buffer
DSW data selection circuit
DT data line
ENUM entry number
HDH_IF interface signal
HOST_IF interface circuit
IOBUF IO buffer
LAD logical address
LRNG logical address area
LPTBL address conversion table
LY memory-cell selection line
LYC layer number
LYN data write layer information
MAPREG map register
MDLCT control circuit
MNERC minimum number of times of erasure
MNGER information processing circuit
MNIPAD invalid physical offset address
MNVPAD valid physical offset address
MXERC maximum number of times of erasure
MXIPAD invalid physical offset address
MXVPAD valid physical offset address
NVCT memory control circuit
NVM non-volatile memory device
NVMMD memory module
NVREG erasure-size designation register
NXLYC layer number
NXPAD write physical address
NXPADTBL write physical address table
NXPERC number of times of erasure
NXPTBL write physical address table
NXPVLD validity flag
PSEGTBL physical segment table
PAD physical address
PADTBL physical address table
PERC number of times of erasure
PPAD physical offset address
PRNG physical address area
PVLD validity flag
R storage element
RADLT row address latch
RAM random access memory
RAMC memory control circuit
REF_CLK reference clock signal
REG register
ROWDEC row decoder
RSTSIG reset signal
SA sense amplifier
SGAD physical segment address
SL chain memory array selection line
STREG status register
SWB reading/writing control block
SYMD clock generating circuit
Tch chain selection transistor
Tcl memory-cell selection transistor
THMO temperature sensor
TNIPA total number of invalid physical addresses
TNVPA total number of valid physical addresses
WDR writing driver
WL word line
WV write data verification circuit

1. A semiconductor device comprising:
a non-volatile memory unit; and
a control circuit configured to assign a physical address to an input logical address and to access the physical address of the non-volatile memory unit, wherein
the non-volatile memory unit includes a plurality of first signal lines, a plurality of second signal lines that intersects with the plurality of first signal lines, and a plurality of memory cell groups arranged in intersection points of the plurality of first signal lines and the plurality of second signal lines,
each of the plurality of memory cell groups includes first to Nth (N is integer number equal to or larger than 2) memory cells, and first to Nth memory-cell selection lines that respectively select the first to Nth memory cells, and
the control circuit sets, as a first area, a plurality of memory cell groups arranged in a manner adjacent to each other, simultaneously writes a first logical level into N of the first to Nth memory cells in each of the plurality of memory cell groups in the first area, sets, as a second area, a memory cell group arranged in an adjacent manner in an outer periphery of the first area, and does not write the first logical level into the memory cell group in the second area.

2. The semiconductor device according to claim 1, wherein
the control circuit writes a second logical level that is different from the first logical level into the memory cells included in the first area after writing the first logical level into the first area.

3. The semiconductor device according to claim 1, wherein
the control circuit assumes that the first logical level is written into the memory cells in the memory cell group in the second area.

4. The semiconductor device according to claim 1, wherein
the first area has a data capacity equal to or larger than a data amount corresponding to one physical address managed by the control circuit.

5. The semiconductor device according to claim 1, wherein
the first area has a data capacity smaller than a data amount corresponding one physical address managed by the control circuit.

6. The semiconductor device according to claim 4, wherein
the control circuit compresses write data input from the outside and writes the compressed data, into the first area, as a second logical level that is different from the first logical level.

7. The semiconductor device according to claim 4, wherein
write data including a plurality of bits in the first logical level and a plurality of bits in a second logical level different from the first logical level is supplied to the semiconductor device, and
when the number of bits in the second logical level is larger than the number of bits in the first logical level in the write data, the control circuit inverts each bit of the write data and performs writing into the first area.

8. A semiconductor device comprising:
a non-volatile memory unit; and
a control circuit configured to assign a physical address to an input logical address and to access the physical address of the non-volatile memory unit, wherein
the non-volatile memory unit includes a plurality of word lines, a plurality of bit lines that intersects with the plurality of word lines, and a plurality of memory cell groups arranged in intersection points of the plurality of word lines and the plurality of bit lines,
each of the plurality of memory cell groups includes first to Nth memory cells connected to each other in series, and first to Nth memory-cell selection lines that respectively select the first to Nth memory cells,
each of the first to Nth memory cells includes a selection transistor including a gate electrode connected to one of the first to Nth memory-cell selection lines, and a resistive storage element connected to the selection transistor in parallel, and
the control circuit sets, as a first area, a plurality of memory cell groups arranged in a manner adjacent to each other, simultaneously writes a first logical level into N of the first to Nth memory cells in each of the plurality of memory cell groups in the first area, sets, as a second area, a memory cell group arranged in an adjacent manner in an outer periphery of the first area, and does not write the first logical level into the memory cell group in the second area.

9. The semiconductor device according to claim 8, wherein
the control circuit writes a second logical level that is different from the first logical level into the memory cell groups in the first area after writing the first logical level into the first area.

10. The semiconductor device according to claim 8, wherein
the control circuit assumes that the first logical level is written into the memory cell group in the second area.

11. The semiconductor device according to claim 8, wherein
the first area has a data capacity equal to or larger than a data amount corresponding to one physical address managed by the control circuit.

12. The semiconductor device according to claim 8, wherein
the first area has a data capacity smaller than a data amount corresponding to one physical address managed by the control circuit.

13. The semiconductor device according to claim 11, wherein
the first to Nth memory cells are memory cells that are connected to each other in series and that are serially laminated in a vertical direction of a semiconductor substrate.

14. The semiconductor device according to claim 11, wherein
the control circuit compresses write data input from the outside and writes the compressed data, into the first area, as a second logical level that is different from the first logical level.

15. The semiconductor device according to claim 11, wherein
write data including a plurality of bits in the first logical level and a plurality of bits in a second logical level different from the first logical level is supplied to the semiconductor device, and
when the number of bits in the second logical level is larger than the number of bits in the first logical level in the write data, the control circuit inverts each bit of the write data and performs writing into the first area.

16. A semiconductor device comprising:
a non-volatile memory unit; and
a control circuit configured to assign a physical address to an input logical address and to access the physical address of the non-volatile memory unit,
wherein the non-volatile memory unit includes a plurality of first signal lines, a plurality of second signal lines that intersects with the plurality of first signal lines, and a plurality of memory cell groups arranged in intersection points of the plurality of first signal lines and the plurality of second signal lines,
each of the plurality of memory cell groups includes first to Nth (N is integer number equal to or larger than 2) memory cells, and first to Nth memory-cell selection lines that respectively select the first to Nth memory cells, and
the control circuit sets, as a first area, a plurality of memory cell groups arranged in a manner adjacent to each other, sets, as a second area, a memory cell group arranged in an adjacent manner in an outer periphery of the first area, and simultaneously writes a first logical level into N of the first to Nth memory cells in each of the plurality of memory cell groups in the first area and the second area.

17. The semiconductor device according to claim 16, wherein
the control circuit writes a second logical level different from the first logical level into the memory cells included in the first area after writing the first logical level into the first area.

18. The semiconductor device according to claim 16, wherein
the first area has a data capacity equal to or larger than a data amount corresponding to one physical address managed by the control circuit.

19. The semiconductor device according to claim 16, wherein
the first area has a data capacity smaller than a data amount corresponding to one physical address managed by the control circuit.

20. The semiconductor device according to claim 18, wherein
the control circuit compresses write data input from the outside and writes the compressed data, into the first area, as a second logical level that is different from the first logical level.

21. The semiconductor device according to claim 18, wherein
write data including a plurality of bits in the first logical level and a plurality of bits in a second logical level different from the first logical level is supplied to the semiconductor device, and
when the number of bits in the second logical level is larger than the number of bits in the first logical level in the write data, the control circuit inverts each bit of the write data and performs writing into the first area.
